(19) United States
(12) Patent Application Publication
(10) Pub. No.: US 2025/0194381 A1
(43) Pub. Date: Jun. 12, 2025

(54) DISPLAY DEVICE

(71) Applicant: LG Display Co., Ltd., Seoul (KR)

(72) Inventors: OhYoung LEE, Paju-si (KR); HeeYoung KWACK, Paju-si (KR); TaeHo KIM, Paju-si (KR)

(21) Appl. No.: 18/970,493

(22) Filed: Dec. 5, 2024

(30) Foreign Application Priority Data
Dec. 6, 2023 (KR) 10-2023-0175828
Nov. 11, 2024 (KR) 10-2024-0158859

(51) Int. Cl. H10K 59/80

(52) U.S. Cl. CPC H10K 59/873

(57) ABSTRACT

Embodiments of the disclosure relate to a display device and, more specifically, may provide a display device capable of effectively preventing external moisture from penetrating into a display area through a camera hole by including the display area including a light emitting element, the camera hole positioned in the display area, and a first non-display area positioned between the display area and the camera hole and including a moisture-preventing structure positioned in the first non-display area.

### CROSS-REFERENCE TO RELATED APPLICATION

This application claims priority to Korean Patent Application No. 10-2023-0175828, filed on Dec. 6, 2023, and Korean Patent Application No. 10-2024-0158859, filed on Nov. 11, 2024, each of which is hereby incorporated by reference in its entirety.

### BACKGROUND

### Technical Field

Embodiments of the disclosure relate to display devices.

### Description of the Related Art

With the development of technology, the display device may provide a capture function and various detection functions in addition to an image display function. To this end, the display device includes an optical electronic device (also referred to as a light receiving device or sensor), such as a camera and a detection sensor.

Since the optical electronic device receives light from the front of the display device, it should be installed where light reception is easy. Accordingly, the camera (camera lens) and the detection sensor may be exposed on the front surface of the display device. Thus, the bezel of the display panel is widened or a notch is formed in the display area of the display panel, and a camera or a detection sensor is installed there.

When the bezel is broadened or a notch is formed in the front surface of the display panel, the display area for displaying images on the display panel may be reduced.

### BRIEF SUMMARY

In the field of display technology, techniques are being researched to equip optical electronic devices such as cameras and detection sensors without reducing the area of the display area of the display panel. Accordingly, the inventors of the disclosure have provided embodiments of a display device in which an optical electronic device is capable of normally receiving light even when positioned inside the display area, not in the bezel area which is around the display area. In such a display device, however, the portion where the optical electronic device is positioned is vulnerable to moisture penetration from the outside. Accordingly, the inventors of the disclosure have further provided various embodiments of a display device capable of preventing moisture penetration from the outside of the display device while positioning the optical electronic device inside the display area.

Embodiments of the disclosure may provide a display device including a camera hole positioned in the display area and a first non-display area positioned between the display area and the camera hole and including a moisture-preventing structure disposed in the first non-display area.

Embodiments of the disclosure may provide a display device capable of effectively preventing moisture penetration from the outside of the display device by including a moisture-preventing structure.

Embodiments of the disclosure may provide a display device including a substrate, a dam, a disconnected portion, a plurality of insulation films, and a moisture-preventing structure. The substrate may include a display area, a camera hole, and a first non-display area. A plurality of light emitting elements including a light emitting layer may be positioned in the display area. The camera hole may be positioned in the display area. The first non-display area may be positioned between the display area and the camera hole. The dam may be positioned in the first non-display area. The disconnected portion may be positioned in the first non-display area. The plurality of insulation films may be disposed on the substrate and be positioned under the plurality of light emitting elements. The moisture-preventing structure may be disposed in the first non-display area. The moisture-preventing structure may include an undercut area of one of the plurality of insulation films.

Embodiments of the disclosure may provide a display device including a display area and a non-display area adjacent to the display area, a camera hole adjacent to the non-display area, the camera hole spaced apart from the display area from a plan view, a light emitting element disposed to overlap with the display area from a plan view, a dam structure in the non-display area; and a first moisture-preventing structure adjacent to the dam structure, the first moisture-preventing structure including a plurality of metal layers.

In the display device according to embodiments of the disclosure, the display device may further include an auxiliary metal layer disposed below the plurality of metal layers of the first moisture-preventing structure.

According to embodiments of the disclosure, there may be provided a display device capable of preventing defects due to moisture penetration from the outside of the display device by including a moisture-preventing structure disposed in a first non-display area.

According to embodiments of the disclosure, there may be provided a display device capable of low-power driving by preventing defects in light emitting elements or reduction in the lifespan of light emitting elements due to moisture penetration from the outside of the display device.

### DESCRIPTION OF THE SEVERAL VIEWS OF THE DRAWINGS

The above and other objects, features, and advantages of the disclosure will be more clearly understood from the following detailed description, taken in conjunction with the accompanying drawings, in which:

FIG. 1 is an exemplary plan view illustrating a display device according to embodiments of the disclosure;

FIG. 2 is an exemplary view illustrating a system configuration of a display device according to embodiments of the disclosure;

FIG. 3 is an exemplary configuration view of a display device and an equivalent circuit diagram of a subpixel according to embodiments of the disclosure;

FIG. 4 is an enlarged view of area A of FIG. 1;

FIGS. 5, 6, and 7 are exemplary cross-sectional views illustrating a display device according to embodiments of the disclosure;

FIGS. 8 and 9 are exemplary cross-sectional views illustrating a moisture-preventing structure of a display device as illustrated in FIGS. 5, 6, and 7;

FIGS. 10 and 11 are exemplary cross-sectional views illustrating a display device according to embodiments of the disclosure;

FIG. 12 is an exemplary cross-sectional view illustrating a moisture-preventing structure of a display device as illustrated in FIGS. 10 and 11;

FIG. 13 is an exemplary cross-sectional view illustrating a display device according to embodiments of the disclosure;

FIG. 14 is an exemplary cross-sectional view illustrating the moisture-preventing structure of FIG. 13;

FIGS. 15, 16, and 17 are exemplary cross-sectional views illustrating a display device according to embodiments of the disclosure;

FIGS. 18, 19, 20, 21, 22, 23, 24, 25, 26, 27, 28, and 29 are exemplary cross-sectional views illustrating a moisture-preventing structure of a display device as illustrated in FIGS. 15, 16, and 17;

FIG. 30 is an exemplary cross-sectional view illustrating a display device according to exemplary embodiments of the disclosure; and

FIGS. 31, 32, 33, 34, 35, and 36 are exemplary cross-sectional views illustrating a moisture-preventing structure of a display device as illustrated in FIG. 30.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including,” “having,” “containing,” “constituting” “make up of,” and “formed of” used herein are generally intended to allow other components to be added unless the terms are used with the term “only.” As used herein, singular forms are intended to include plural forms unless the context clearly indicates otherwise.

Terms, such as “first,” “second,” “A,” “B,” “(A),” or “(B)” may be used herein to describe elements of the disclosure. Each of these terms is not used to define essence, order, sequence, or number of elements, etc., but is used merely to distinguish the corresponding element from other elements.

When it is mentioned that a first element “is connected or coupled to,” “contacts or overlaps,” etc., a second element, it should be interpreted that, not only can the first element “be directly connected or coupled to” or “directly contact or overlap” the second element, but a third element can also be “interposed” between the first and second elements, or the first and second elements can “be connected or coupled to,” “contact or overlap,”, etc., each other via a fourth element. Here, the second element may be included in at least one of two or more elements that “are connected or coupled to,” “contact or overlap,” etc., each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

In addition, when any dimensions, relative sizes, etc., are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

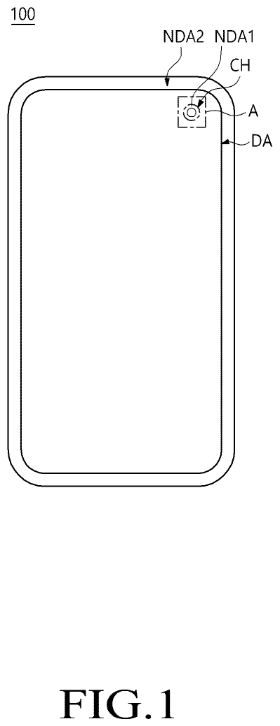

FIG. 1 is a plan view illustrating a display device 100 according to embodiments of the disclosure.

Referring to FIG. 1, a display device 100 may include a display area DA and a non-display area NDA. The non-display area NDA may include a second non-display area NDA2 surrounding the display area DA. The display area DA is an area that displays an image, and a plurality of light emitting elements may be positioned in the display area DA. The second non-display area NDA2 may be a bezel area positioned outside the display area DA of the display device 100. In the second non-display area NDA2, driving circuits, such as data driving circuits and gate driving circuits, for driving a plurality of light emitting elements positioned in the display area DA may be positioned, and signal lines, such as data lines and gate lines, may be positioned.

The display device 100 may include a display area DA, a camera hole CH positioned in the display area DA and a first non-display area NDA1 positioned between the display area DA and the camera hole CH. Various optical electronic devices provided in the display device 100 may be positioned in the camera hole CH. For example, a camera may be positioned under the substrate of the display device 100 and may be positioned to overlap the camera hole CH from a plan view. In the display device 100 according to embodiments of the disclosure, as the camera hole CH is positioned in the display area DA, the area of the second non-display area NDA2 which is the bezel area may be reduced, and the display area DA may be increased or maximized.

The camera hole CH may be a single hole as illustrated in FIG. 1 but, without limitations thereto, the camera hole CH may be disposed in various manners. For example, one or two holes may be disposed inside the display area DA, and a camera may be disposed in the first hole, and a distance sensor, a face recognition sensor, or another camera may be disposed in the second hole.

The first non-display area NDA1 may surround the camera hole CH. For example, the first non-display area NDA1 may be positioned in the peripheral portion of the camera hole CH and may surround the whole or portion of the peripheral portion of the camera hole CH. Signal lines for transferring signals to light emitting elements positioned in the display area DA may be positioned in the first non-display area NDA1. The first non-display area NDA1 may be referred to as a bezel area of the camera hole CH and may be referred to as, e.g., a variable bezel area.

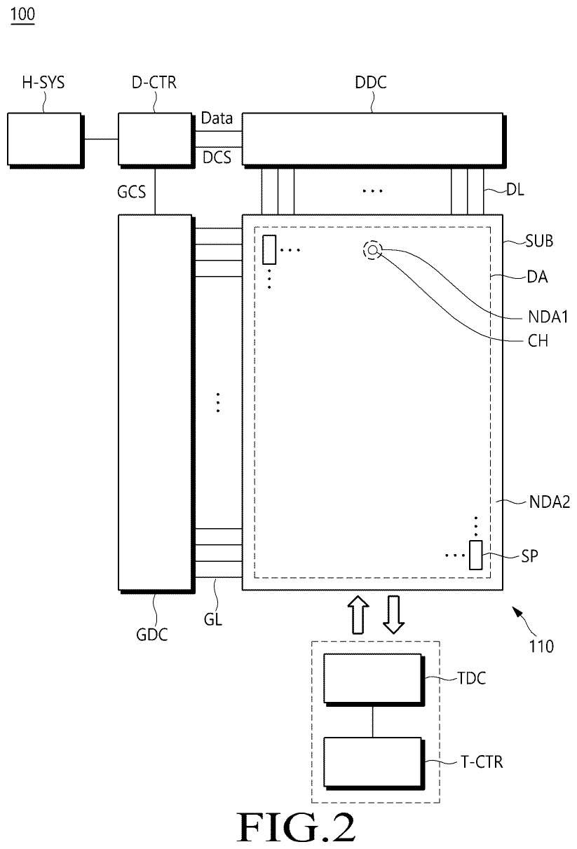

FIG. 2 is a view illustrating a system configuration of a display device 100 according to embodiments of the disclosure. What is identical or similar to those described with reference to FIG. 1 is omitted from the following description or briefly described below.

Referring to FIG. 2, the display device 100 may include a display panel 110 and a display driving circuit as components for displaying an image.

The display driving circuits are circuits for driving the display panel 110 and may include a data driving circuit DDC, a gate driving circuit GDC, and a display controller D-CTR.

The display panel 110 may include a display area DA where an image is displayed and a second non-display area NDA2 where no image is displayed. The second non-display area NDA2 may be an outer area of the display area DA and be referred to as a bezel area. The whole or part of the second non-display area NDA2 may be an area visible from the front surface of the display device 100 or an area that is bent and not visible from the front surface of the display device 100.

The display panel 110 may include a camera hole CH positioned in the display area DA and a first non-display area NDA1 positioned between the display area DA and the camera hole CH.

The display panel 110 may include a substrate SUB and a plurality of subpixels SP disposed on the substrate SUB. The display panel 110 may further include various types of signal lines to drive the plurality of subpixels SP.

The display device 100 according to embodiments of the disclosure may be a liquid crystal display device or a self-emission display device in which the display panel 110 emits light by itself. When the display device 100 according to the embodiments of the disclosure is a self-emission display device, each of the plurality of subpixels SP may include a light emitting element. For example, the display device 100 according to embodiments of the disclosure may be an organic light emitting diode display in which the light emitting element is implemented as an organic light emitting diode (OLED). As another example, the display device 100 according to embodiments of the disclosure may be an inorganic light emitting display device in which the light emitting element is implemented as an inorganic material-based light emitting diode. As another example, the display device 100 according to embodiments of the disclosure may be a quantum dot display device in which the light emitting element is implemented as a quantum dot which is self-emission semiconductor crystal.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors.

For example, various types of signal lines may include a plurality of data lines DL transferring data signals (also referred to as data voltages or image signals) and a plurality of gate lines GL transferring gate signals (also referred to as scan signals).

The plurality of data lines DL and the plurality of gate lines GL may cross each other. Each of the plurality of data lines DL may be disposed while extending in a first direction. Each of the plurality of gate lines GL may be disposed while extending in a second direction. Here, the first direction may be a column direction and the second direction may be a row direction. The first direction may be the row direction, and the second direction may be the column direction.

The data driving circuit DDC is a circuit for driving the plurality of data lines DL, and may output data signals to the plurality of data lines DL. The gate driving circuit GDC is a circuit for driving the plurality of gate lines GL, and may output gate signals to the plurality of gate lines GL.

The display controller D-CTR is a device for controlling the data driving circuit DDC and the gate driving circuit GDC and may control driving timings for the plurality of data lines DL and driving timings for the plurality of gate lines GL.

The display controller D-CTR may supply a data driving control signal DCS to the data driving circuit DDC to control the data driving circuit GDC and may supply a gate driving control signal GCS to the gate driving circuit GDC to control the gate driving circuit GDC.

The display controller D-CTR may receive input image data from the host system H-SYS and supply digital image data Data to the data driving circuit DDC based on the input image data.

The data driving circuit DDC may receive digital image data Data from the display controller D-CTR and may convert the received digital image data Data into analog data signals and output the analog data signals to the plurality of data lines DL.

The gate driving circuit GDC may receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

For example, the data driving circuit DDC may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110.

The gate driving circuit GDC may be connected with the display panel 110 by a tape automated bonding (TAB) method or connected to a bonding pad of the self-emission display panel 110 by a COG or chip on panel (COP) method or may be connected with the display panel 110 according to a COF method. The gate driving circuit GDC may be formed in a gate in panel (GIP) type, in the second non-display area NDA2 of the display panel 110. The gate driving circuit GDC may be disposed on the substrate or may be connected to the substrate. In other words, the gate driving circuit GDC that is of a GIP type may be disposed in the second non-display area NDA2 of the substrate. The gate driving circuit GDC that is of a chip-on-glass (COG) type or chip-on-film (COF) type may be connected to the substrate.

Meanwhile, at least one of the data driving circuit DDC and the gate driving circuit GDC may be disposed in the display area DA of the display panel 110. For example, at least one of the data driving circuit DDC and the gate driving circuit GDC may be disposed not to overlap the subpixels SP or to overlap all or some of the subpixels SP.

The data driving circuit DDC may be connected with one side (e.g., an upper or lower side) of the display panel 110. Depending on the driving scheme or the panel design scheme, the data driving circuit DDC may be connected with both sides (e.g., upper and lower sides) of the self-emission display panel 110, or two or more of the four sides of the self-emission display panel 110.

The gate driving circuit GDC may be connected to one side (e.g., a left or right side) of the display panel 110. Depending on the driving scheme or the panel design scheme, the gate driving circuit GDC may be connected with both sides (e.g., left and right sides) of the display panel 110, or two or more of the four sides of the display panel 110.

The display controller D-CTR may be implemented as a separate component from the data driving circuit DDC, or the display controller D-CTR and the data driving circuit DDC may be integrated into an integrated circuit (IC).

The display controller D-CTR may be a timing controller used in typical display technology, a control device that may perform other control functions as well as the functions of the timing controller, or a control device other than the timing controller, or may be a circuit in the control device. The display controller D-CTR may be implemented as various circuits or electronic components, such as an integrated circuit (IC), a field programmable gate array (FPGA), an application specific integrated circuit (ASIC), or a processor.

The display controller D-CTR may be mounted on a printed circuit board or a flexible printed circuit and may be electrically connected with the data driving circuit DDC and the gate driving circuit GDC through the printed circuit board or the flexible printed circuit.

The display controller D-CTR may transmit/receive signals to/from the data driving circuit DDC according to one or more predetermined interfaces. The predetermined interface may include, e.g., a low voltage differential signaling (LVDS) interface, an embedded clock point-point interface (EPI) interface, and a serial peripheral interface (SPI).

To provide a touch sensing function as well as an image display function, the display device 100 according to embodiments of the disclosure may include a touch sensor and a touch sensing circuit that senses the touch sensor to detect whether a touch occurs by a touch object, such as a finger or pen, or the position of the touch.

The touch sensing circuit may include a touch driving circuit TDC that drives and senses the touch sensor and generates and outputs touch sensing data and a touch controller T-CTR that may detect an occurrence of a touch or the position of the touch using touch sensing data.

The touch sensor may include a plurality of touch electrodes. The touch sensor may further include a plurality of touch lines for electrically connecting the plurality of touch electrodes and the touch driving circuit TDC.

The touch sensor in the form of a touch panel may exist outside the display panel 110, or the touch sensor may exist inside the display panel 110. When the touch panel, in the form of a touch panel, exists outside the display panel 110, the touch panel is referred to as an external type. When the touch sensor is of the external type, the touch panel and the display panel 110 may be separately manufactured or may be combined during an assembly process. The external-type touch panel may include a touch panel substrate and a plurality of touch electrodes on the touch panel substrate.

When the touch sensor is present inside the display panel 110, the touch sensor may be formed on the substrate SUB, together with signal lines and electrodes related to display driving, during the manufacturing process of the display panel 110.

The touch driving circuit TDC may supply a touch driving signal to at least one of the plurality of touch electrodes and may sense at least one of the plurality of touch electrodes to generate touch sensing data.

The touch sensing circuit may perform touch sensing in a self-capacitance sensing scheme or a mutual-capacitance sensing scheme.

When the touch sensing circuit performs touch sensing in the self-capacitance sensing scheme, the touch sensing circuit may perform touch sensing based on capacitance between each touch electrode and the touch object (e.g., finger or pen). According to the self-capacitance sensing scheme, each of the plurality of touch electrodes may serve both as a driving touch electrode and as a sensing touch electrode. The touch driving circuit TDC may drive all or some of the plurality of touch electrodes and sense all or some of the plurality of touch electrodes.

When the touch sensing circuit performs touch sensing in the mutual-capacitance sensing scheme, the touch sensing circuit may perform touch sensing based on capacitance between the touch electrodes. According to the mutual-capacitance sensing scheme, the plurality of touch electrodes are divided into driving touch electrodes and sensing touch electrodes. The touch driving circuit TDC may drive the driving touch electrodes and sense the sensing touch electrodes.

The touch driving circuit TDC and the touch controller T-CTR included in the touch sensing circuit may be implemented as separate devices or as a single device. The touch driving circuit TDC and the data driving circuit DDC may be implemented as separate devices or as a single device.

The display device 100 may further include a power supply circuit for supplying various types of power to the display driver integrated circuit and/or the touch sensing circuit.

The display device 100 according to embodiments of the disclosure may be a mobile terminal, such as a smart phone or a tablet, or a monitor or television (TV) in various sizes but, without limited thereto, may be a display in various types and various sizes capable of displaying information or images.

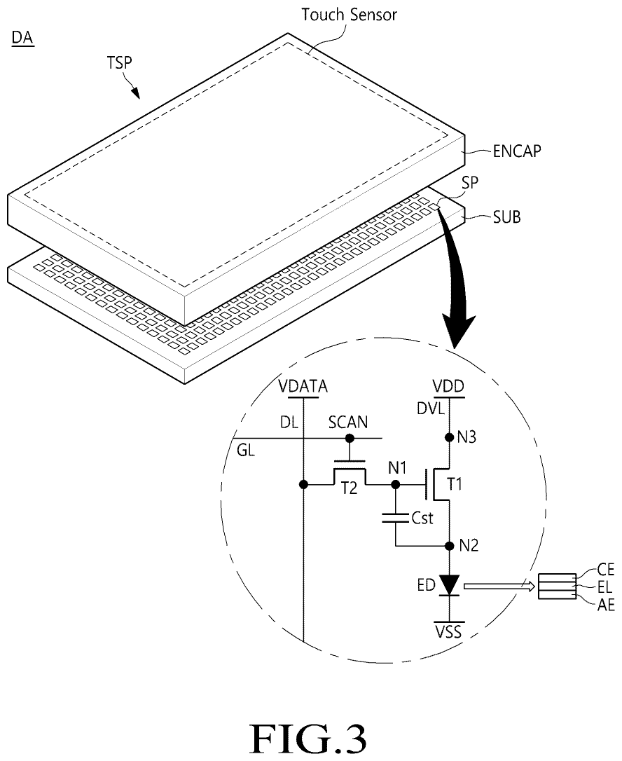

FIG. 3 is a configuration view of a display device and an equivalent circuit diagram of a subpixel according to embodiments of the disclosure. What is identical or similar to those described with reference to FIGS. 1 and 2 is omitted from the following description or briefly described below.

Referring to FIG. 3, a plurality of subpixels SP may be disposed in the display area DA of the display device. A plurality of subpixels SP may be disposed in the display area DA, but may not be disposed in the first non-display area and the camera hole.

Each of the plurality of subpixels SP may include a light emitting element ED and a subpixel circuit unit configured to drive the light emitting element ED.

The subpixel circuit unit may include a driving transistor T1 for driving the light emitting element ED, a scan transistor T2 for transferring the data voltage VDATA to the first node N1 of the driving transistor T1, and a storage capacitor Cst for maintaining a constant voltage during one frame.

The driving transistor T1 may include the first node N1 to which the data voltage may be applied, a second node N2 electrically connected with the light emitting element ED, and a third node N3 to which a driving voltage VDD is applied from a driving voltage line DVL. The first node N1 in the driving transistor T1 may be a gate node, the second node N2 may be a source node or a drain node, and the third node N3 may be the drain node or the source node. For convenience of description, described below is an example in which the first node N1 in the driving transistor T1 is a gate node, the second node N2 is a source node, and the third node N3 is a drain node.

The light emitting element ED may include an anode electrode AE, a light emitting layer EL, and a cathode electrode CE. The anode electrode AE may be a pixel electrode disposed in each subpixel SP and be electrically connected to the second node N2 of the driving transistor T1 of each subpixel SP. The cathode electrode CE may be a common electrode commonly disposed in the plurality of subpixels SP, and a base voltage VSS may be applied thereto.

For example, the anode electrode AE may be a pixel electrode, and the cathode electrode CE may be a common electrode. Conversely, the anode electrode AE may be a common electrode, and the cathode electrode CE may be a pixel electrode. Hereinafter, for convenience of description, it is assumed that the anode electrode AE is a pixel electrode and the cathode electrode CE is a common electrode.

The light emitting element ED may have a predetermined emission area. The emission area of the light emitting element ED may be defined as an area where the anode electrode AE, the light emitting layer EL, and the cathode electrode CE overlap.

For example, the light emitting element ED may be an organic light emitting diode (OLED), an inorganic light emitting diode, or a quantum dot light emitting element. When the light emitting element ED is an organic light emitting diode, the light emitting layer EL of the light emitting element ED may include an organic light emitting layer EL including an organic material.

The scan transistor T2 may be on/off controlled by a scan signal SCAN, which is a gate signal, applied via the gate line GL and be electrically connected between the first node N1 of the driving transistor T1 and the data line DL.

The storage capacitor Cst may be electrically connected between the first node N1 and second node N2 of the driving transistor T1.

The subpixel circuit unit may have a 2T (transistor) 1C (capacitor) structure which includes two of the driving transistor T1 and the scan transistor T2 and one capacitor Cst as shown in FIG. 3 and, in some cases, each subpixel SP may further include one or more transistors or one or more capacitors.

The capacitor Cst may be an external capacitor intentionally designed to be outside the driving transistor T1, but not a parasite capacitor (e.g., Cgs or Cgd) which is an internal capacitor that may be present between the first node N1 and the second node N2 of the driving transistor T1. Each of the driving transistor T1 and the scan transistor T2 may be an n-type transistor or a p-type transistor.

Since the circuit elements (particularly, the light emitting element ED implemented as an organic light emitting diode (OLED) containing an organic material) in each subpixel SP are vulnerable to external moisture or oxygen, an encapsulation layer ENCAP may be disposed on the display panel 110 to prevent penetration of external moisture or oxygen into the circuit elements (particularly, the light emitting element ED). The encapsulation layer ENCAP may be disposed to cover the light emitting elements ED.

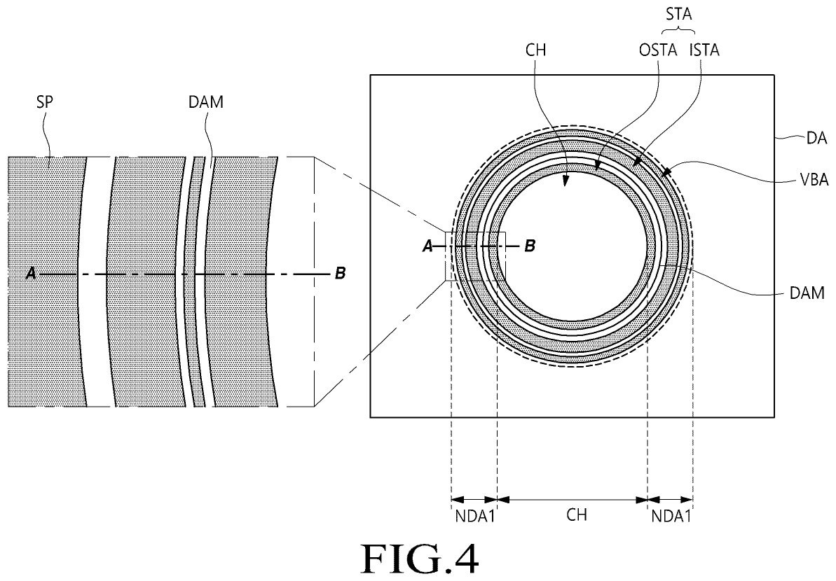

FIG. 4 is an enlarged view of area A of FIG. 1. Area A of FIG. 1 is an area in the display area DA, and may be an area including the camera hole CH and a peripheral area thereof. What is identical or similar to those described with reference to FIGS. 1 to 3 is omitted from the following description or briefly described below.

Referring to FIG. 4, the camera hole CH may be positioned in the display area DA. For example, the camera hole CH may be in the form of an island positioned in the display area DA, and the display area DA may surround the camera hole CH.

The first non-display area NDA1 may surround the camera hole CH. For example, the first non-display area NDA1 may be positioned between the display area DA and the camera hole CH. The first non-display area NDA1 is a non-display area positioned in the display area DA and may be a non-display area positioned around the camera hole CH.

The dam DAM (also referred to as a dam structure DAM) may be positioned in the first non-display area NDA1. The dam DAM may refer to a structure for controlling the flow of one of a plurality of insulation films included in the display device. For example, the dam DAM may be a structure for controlling the flow of an organic insulation film positioned on the light emitting elements positioned on the substrate. More specifically, the insulation film may be an organic layer that is a portion of an encapsulation layer encapsulating the plurality of light emitting elements. FIG. 4 illustrates embodiments in which there is only one dam DAM in the first non-display area NDA1, but the disclosure is not limited thereto, and embodiments in which two or more dams are positioned in the first non-display area NDA1 are also included in the embodiments of the disclosure.

The dam DAM may be positioned to surround the camera hole CH. For example, the dam DAM may have a closed curve shape that completely surrounds the camera hole CH. As the dam DAM is positioned to surround the camera hole CH, it is possible to effectively control the flow of the organic layer, which is a portion of the encapsulation layer, at the boundary of the peripheral portion of the camera hole CH.

The disconnected portion area STA may be positioned in the first non-display area NDA1. The disconnected portion area STA may refer to an area in which a plurality of disconnected portions is positioned. The disconnected portion is a structure for blocking external moisture from penetrating into the display area DA through the camera hole CH, and may refer to a structure for blocking a penetration path of moisture by cutting the cathode electrode CE formed by entirely depositing on the organic layer of the light emitting element and/or the substrate SUB.

The disconnected portion area STA may include an inner disconnected portion area ISTA and an outer disconnected portion area OSTA. The inner disconnected portion area ISTA may be a disconnected portion area positioned inside the dam DAM with respect to the display area DA. The inner disconnected portion area ISTA may be an area in which a plurality of disconnected portions positioned inside the dam DAM are positioned with respect to the display area DA. The outer disconnected portion area OSTA may be a disconnected portion area positioned outside the dam DAM with respect to the display area DA. The outer disconnected portion area OSTA may be an area in which a plurality of disconnected portions positioned outside the dam DAM are positioned with respect to the display area DA.

The moisture-preventing structure may be positioned in the disconnected portion area STA. As the moisture-preventing structure is positioned in the disconnected portion area STA, it is possible to effectively prevent external moisture from penetrating into the light emitting element positioned in the display area DA through the camera hole CH. The moisture-preventing structure may be positioned in the outer disconnected portion area OSTA and/or the inner disconnected portion area ISTA. In the disclosure, the moisture-preventing structure positioned in the outer disconnected portion area OSTA may be referred to as an outer moisture-preventing structure, and the moisture-preventing structure positioned in the inner disconnected portion area ISTA may be referred to as an inner moisture-preventing structure.

The area of the first non-display area NDA1 surrounding the inner disconnected portion area ISTA and positioned adjacent to the display area DA may be referred to as a variable bezel area VBA. Signal lines for transferring signals to the plurality of light emitting elements positioned in the display area DA may be positioned in the variable bezel area VBA.

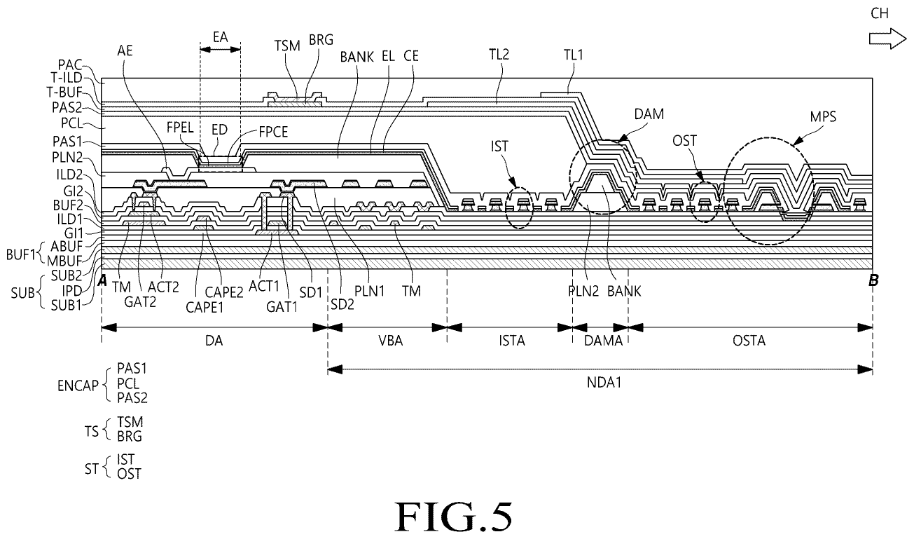

FIG. 5 is a cross-sectional view illustrating a display device according to embodiments of the disclosure. More specifically, FIG. 5 is a cross-sectional view of portion A-B of FIG. 4. What is identical or similar to those described with reference to FIGS. 1 to 4 is omitted from the following description or briefly described below.

Referring to FIG. 5, when viewed in a vertical structure, the display device may include a transistor forming part, a light emitting element forming part, and an encapsulation part.

The transistor forming part may include a substrate SUB, a first buffer layer BUF1 on the substrate SUB, and various transistors, a storage capacitor, and various electrodes or signal lines formed on the first buffer layer BUF.

The substrate SUB may include an insulation material. For example, the substrate SUB may include glass or plastic. The substrate SUB may have a single-layer structure or a multi-layer structure. For example, the substrate SUB may have a multi-layer structure. The substrate SUB may include a first substrate SUB1 and a second substrate SUB2. An intermediate film IPD may be present between the first and second substrates SUB1 and SUB2. The first substrate SUB1 and the second substrate SUB2 may include the same material. For example, the first substrate SUB1 and the second substrate SUB2 may be polyimide (PI) substrates. The interlayer film IPD may be a single-layer or multi-layer inorganic film of silicon nitride (SiNx) or silicon oxide (SiOx). as the interlayer film IPD is disposed between the first substrate SUB1 and the second substrate SUB2, moisture components may be blocked from penetrating into the transistor through the first substrate SUB1 thereunder, enhancing the reliability of the display device.

The first buffer layer BUF1 may be a single film or multi-film structure. When the first buffer layer BUF1 is formed in a multi-film structure, the first buffer layer BUF1 may include a multi-buffer layer MBUF and an active buffer layer ABUF.

Various transistors, a storage capacitor, and various electrodes or signal lines may be formed on the first buffer layer BUF1. For example, the transistors formed on the first buffer layer BUF1 are formed of the same material and on the same layer. Alternatively, the transistors formed on the first buffer layer BUF1 may be formed of different materials and positioned in different layers.

A first active layer ACT1 may be positioned on the first buffer layer BUF1. The first active layer ACT1 is a layer that constitutes the transistor and may include a channel area that overlaps the first gate electrode GAT1, a first source connection area positioned on one side of the channel area, and a first drain connection area positioned on the other side. The first active layer ACT1 may refer to the active layer of the transistor or a semiconductor layer formed of the same material. Accordingly, the first active layer ACT1 may configure the transistor or another circuit element and a signal line.

A first gate insulation film GI1 may be disposed on the first active layer ACT1. A first gate electrode GAT1 may be positioned on the first gate insulation film GI1. The first gate electrode GAT1 may refer to the gate electrode of the transistor or a metal layer formed of the same material. Accordingly, the first gate electrode GAT1 may constitute the transistor or another circuit element and a signal line. The first gate electrode GAT1 may include a conductive material. For example, the first gate electrode GAT1 may include a single layer or multiple layers of any one of molybdenum (Mo), copper (Cu), titanium (Ti), aluminum (Al), chromium (Cr), gold (Au), nickel (Ni), neodymium (Nd), and tungsten (W), or an alloy thereof, but is not limited thereto. For example, the first gate electrode GAT1 may be formed of a Mo/Ti double layer.

A first interlayer insulation film ILD1 may be positioned on the first gate electrode GAT1. The first interlayer insulation layer ILD1 may be formed of a single layer of silicon nitride (SiNx) or silicon oxide (SiOx) or multiple layers thereof, but is not limited thereto.

A second buffer layer BUF2 may be disposed on the first interlayer insulation film ILD1. The second buffer layer BUF2 may be formed of a single layer of silicon nitride (SiNx) or silicon oxide (SiOx) or multiple layers thereof, but is not limited thereto.

A second active layer ACT2 may be positioned on the second buffer layer BUF2. The second active layer ACT2 may refer to the active layer of the transistor or a semiconductor layer formed of the same material. Accordingly, the second active layer ACT2 may configure the transistor or another circuit element and a signal line.

A second gate insulation film GI2 may be positioned on the second active layer ACT2. The second gate insulation layer GI2 may be formed of a single layer of silicon nitride (SiNx) or silicon oxide (SiOx) or multiple layers thereof, but is not limited thereto.

A second gate electrode GAT2 may be positioned on the second gate insulation film GI2. The second gate electrode GAT2 may refer to the gate electrode of the transistor or a metal layer formed of the same material. Accordingly, the second gate electrode GAT2 may constitute the transistor or another circuit element and a signal line. The second gate electrode GAT2 may include a conductive material. For example, the second gate electrode GAT2 may include a single layer or multiple layers of any one of molybdenum (Mo), copper (Cu), titanium (Ti), aluminum (Al), chromium (Cr), gold (Au), nickel (Ni), neodymium (Nd), and tungsten (W), or an alloy thereof, but is not limited thereto. For example, the second gate electrode GAT2 may be formed of a Mo/Ti double layer.

A second interlayer insulation film ILD2 may be positioned on the second gate electrode GAT2. The first source-drain electrode SD1 may be positioned on the second interlayer insulation film ILD2. The first source-drain electrode SD1 may refer to the source-drain electrode of the transistor or a metal layer formed of the same material. Accordingly, the first source-drain electrode SD1 may constitute the transistor or another circuit element and a signal line. The first source-drain electrode SD1 may include a conductive material. For example, the first source-drain electrode SD1 may include a single layer or multiple layers of any one of molybdenum (Mo), copper (Cu), titanium (Ti), aluminum (Al), chromium (Cr), gold (Au), nickel (Ni), neodymium (Nd), and tungsten (W), or an alloy thereof, but is not limited thereto. For example, the first source-drain electrode SD1 may be formed of a Ti/Al/Ti triple layer.

A first planarization layer PLN1 may be positioned on the first source-drain electrode SD1.

A second source-drain electrode SD2 may be disposed on the first planarization layer PLN1. The second source-drain electrode SD2 may refer to an electrode for electrically connecting the first source-drain electrode SD1 and the light emitting element ED, or may refer to a metal layer formed of the same material, Accordingly, the second source-drain electrode SD2 may constitute an electrode that electrically connects the transistor and the light emitting element, or constitute another circuit element and a signal line. The second source-drain electrode SD2 may include a conductive material. For example, the second source-drain electrode SD2 may include a single layer or multiple layers of any one of molybdenum (Mo), copper (Cu), titanium (Ti), aluminum (Al), chromium (Cr), gold (Au), nickel (Ni), neodymium (Nd), and tungsten (W), or an alloy thereof, but is not limited thereto. For example, the second source-drain electrode SD2 may be formed of a Ti/Al/Ti triple layer.

Referring to FIG. 5, the storage capacitor Cst may be formed by a first capacitor electrode CAPE1 and a second capacitor electrode CAPE2. In some cases, the storage capacitor Cst may be formed by three or more capacitor electrodes, or may have a form in which two or more capacitors are connected in parallel.

Each of the first capacitor electrode CAPE1 and the second capacitor electrode CAPE2 may be disposed on various metal layers disposed in the display panel 110. For example, the first capacitor electrode CAPE1 may include the same first gate metal as the first gate electrode GAT1 on the first gate insulation layer GI1, and may be disposed in the first gate metal layer. For example, the second capacitor electrode CAPE2 may include the same metal as the metal pattern TM on the first interlayer insulation layer ILD1 and may be disposed in the metal pattern layer.

Referring to FIG. 5, a metal pattern TM may be further included. For example, the metal pattern TM may be disposed between the first interlayer insulation layer ILD1 and the second buffer layer BUF2. For example, the metal pattern TM may include the same metal as the second capacitor electrode CAPE2 on the first interlayer insulation layer ILD1 and may be disposed in the metal pattern layer. The metal pattern TM may include a conductive material. For example, the metal pattern TM may include a single layer or multiple layers of any one of molybdenum (Mo), copper (Cu), titanium (Ti), aluminum (Al), chromium (Cr), gold (Au), nickel (Ni), neodymium (Nd), and tungsten (W), or an alloy thereof, but is not limited thereto. For example, the metal pattern TM may be formed of a Mo single layer, a MoTi alloy single layer, or a Mo/Ti double layer. The metal pattern TM may be disposed in the display area DA and/or the non-display area NDA. The metal pattern TM may be used as a shield metal.

A second planarization layer PLN2 may be positioned on the second source-drain electrode SD2.

An anode electrode AE may be positioned on the second planarization layer PLN2. The anode electrode AE may be a pixel electrode. The anode electrode AE may constitute the light emitting element ED. Although not shown in FIG. 5, a cathode electrode CE may be positioned on the light emitting layer EL. In this example, the anode electrode AE may be a pixel electrode and the cathode electrode may be a common electrode. The cathode electrode, which is a common electrode, may be deposited over the entire display area DA.

A bank BANK may be positioned on the anode electrode AE. The bank BANK may be disposed while covering a portion of the anode electrode AE. A portion of the bank BANK corresponding to the light emitting area EA of the subpixel may be opened.

A portion of the anode electrode AE may be exposed through an opening (open portion) of the bank BANK. A light emitting layer EL may be positioned on a side surface of the bank BANK and the opening (open portion) of the bank BANK. The whole or part of the light emitting layer EL may be positioned between adjacent banks BANK.

In the opening of the bank BANK, the light emitting layer EL may contact the anode electrode AE. A cathode electrode may be disposed on the light emitting layer EL. The light emitting element ED may be formed by the anode electrode AE, the light emitting layer EL, and the cathode electrode CE. The light emitting layer EL may include an organic film.

An encapsulation layer ENCAP may be disposed on the above-described light emitting element ED. The encapsulation layer ENCAP may have a single-layer structure or a multi-layer structure. For example, as illustrated in FIG. 5, the encapsulation layer ENCAP may include a first encapsulation layer PAS1, a second encapsulation layer PCL, and a third encapsulation layer PAS2.

For example, the first encapsulation layer PAS1 and the third encapsulation layer PAS2 may be inorganic films, and the second encapsulation layer PCL may be an organic layer. Among the first encapsulation layer PAS1, the second encapsulation layer PCL, and the third encapsulation layer PAS2, the second encapsulation layer PCL may be the thickest. Accordingly, the second encapsulation layer PCL may serve as a planarization layer. The first encapsulation layer PAS1 is also referred to as a first inorganic encapsulation layer. The second encapsulation layer PCL is also referred to as an organic encapsulation layer, and the third encapsulation layer PAS2 is also referred to as a second inorganic encapsulation layer.

The first encapsulation layer PAS1 may be disposed on the cathode electrode and be disposed closest to the light emitting element ED. The first encapsulation layer PAS1 may be formed of an inorganic insulating material capable of low-temperature deposition. For example, the first encapsulation layer PAS1 may be formed of silicon nitride (SiNx), silicon oxide (SiOx), silicon oxynitride (SiON), or aluminum oxide (Al₂O₃). Since the first encapsulation layer PAS1 is deposited in a low temperature atmosphere, the first encapsulation layer PAS1 may prevent damage to the light emitting layer EL including an organic material vulnerable to a high temperature atmosphere during the deposition process.

The second encapsulation layer PCL may have a smaller area than the first encapsulation layer PAS1. In this case, the second encapsulation layer PCL may be formed to expose two opposite ends of the first encapsulation layer PAS1. The second encapsulation layer PCL serves as a buffer for relieving stress between layers due to bending of the display device 100 and may also serve to enhance planarization performance. For example, the second encapsulation layer PCL may be an acrylic resin, an epoxy resin, polyimide, polyethylene, or silicon oxycarbon (SiOC) and be formed of an organic insulating material. For example, the second encapsulation layer PCL may be formed through an inkjet scheme.

The third encapsulation layer PAS2 may be formed on the substrate SUB, where the second encapsulation layer PCL is formed, to cover the respective top surfaces and side surfaces of the second encapsulation layer PCL and the first encapsulation layer PAS1. The third encapsulation layer PAS2 may minimize or block external moisture or oxygen from penetrating into the first encapsulation layer PAS1 and the second encapsulation layer PCL. For example, the third encapsulation layer PAS2 is formed of an inorganic insulating material, such as silicon nitride (SiNx), silicon oxide (SiOx), silicon oxynitride (SiON), or aluminum oxide (Al₂O₃).

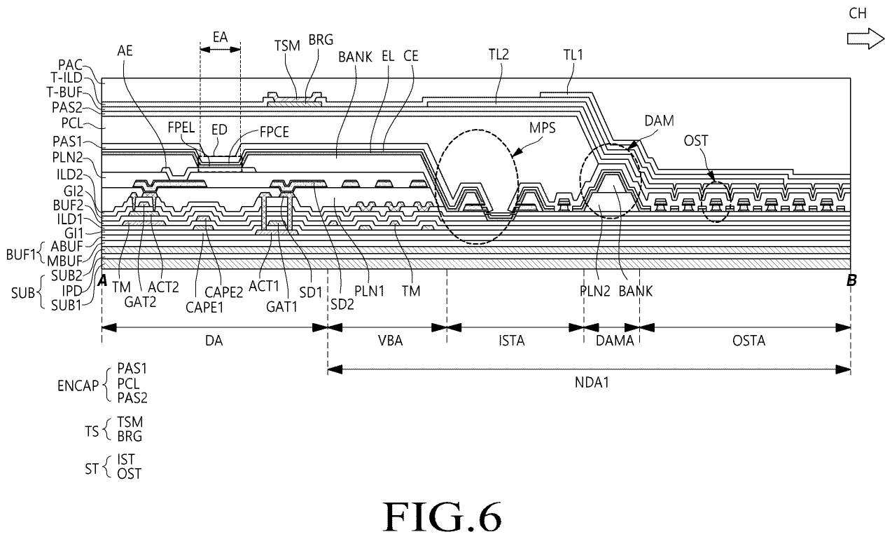

Referring to FIG. 5, the light emitting element ED overlaps with the display area DA from a plan view. The light emitting element ED includes the cathode electrode CE, the anode electrode AE, and the light emitting layer EL. The light emitting layer EL may have various portions. For example, the light emitting layer EL includes a first portion FPEL, a second portion SPEL, and a third portion TPEL. The first, second, and third portions of the light emitting layer EL are spaced apart from each other. It may also be said that the first, second, third portions of the light emitting layer EL are disconnected from each other. For example, the first portion FPEL of the light emitting layer EL overlaps with the display area DA from a plan view. This is also shown in FIGS. 6, 7, 10, 11, and 13.

Similarly, the cathode electrode CE may have various portions. For example, the cathode electrode CE includes a first portion FPCE, a second portion SPCE, and a third portion TPCE. The first, second, and third portions of the cathode electrode CE are spaced apart from each other. It may also be said that the first, second, third portions of the cathode electrode CE are disconnected from each other. For example, the first portion FPCE of the cathode electrode CE overlaps with the display area DA from a plan view. This is also shown in FIGS. 6, 7, 10, 11, and 13.

Referring to FIG. 5, when the touch sensor TS is of a type embedded in the display panel, the touch sensor TS may be disposed on the encapsulation layer ENCAP. The structure of the touch sensor TS is described below in detail.

A touch buffer film T-BUF may be disposed on the encapsulation layer ENCAP. A touch sensor TS may be disposed on the touch buffer film T-BUF.

The touch sensor TS may include touch sensor metals TSM and a bridge metal BRG positioned on different layers.

A touch interlayer insulation film T-ILD may be disposed between the touch sensor metals TSM and the bridge metal BRG.

For example, the touch sensor metals TSM may include a first touch sensor metal TSM, a second touch sensor metal TSM, and a third touch sensor metal TSM that are disposed adjacent to each other. The third touch sensor metal TSM is disposed between the first touch sensor metal TSM and the second touch sensor metal TSM and, when the first touch sensor metal TSM and the second touch sensor metal TSM are electrically connected to each other, the first touch sensor metal TSM and the second touch sensor metal TSM may be electrically connected to each other through the bridge metal BRG positioned on a different layer. The bridge metal BRG may be insulated from the third touch sensor metal TSM by the touch interlayer insulation film T-ILD.

When the touch sensor TS is formed on the display panel, moisture may be generated from the chemical solution (e.g., developer or etchant) used in the process. By disposing the touch sensor TS on the touch buffer layer T-BUF, it is possible to prevent a chemical solution or moisture from penetrating into the light emitting layer EL including an organic material during the manufacturing process of the touch sensor TS. Thus, the touch buffer film T-BUF may prevent damage to the light emitting layer EL vulnerable to chemicals or moisture.

The touch buffer film T-BUF is formed of an organic insulation material with a low permittivity of 1 to 3 and formed at a low temperature which is not more than a predetermined temperature (e.g., 100° C.) to prevent damage to the light emitting layer EL containing the organic material vulnerable to high temperature. For example, the touch buffer film T-BUF may be formed of an acrylic-based, epoxy-based, or siloxane-based material. As the display device is bent, the encapsulation layer ENCAP may be damaged, and the touch sensor metal TSM positioned on the touch buffer layer T-BUF may be broken. Even when the display device 100 is bent, the touch buffer layer T-BUF formed of an organic insulating material and having planarization capability may prevent damage to the encapsulation layer ENCAP and/or breakage of the touch sensor metals TSM and bridge metal BRG constituting the touch sensor TS.

Referring to FIG. 5, a touch line TL1 or TL2 that electrically connects the touch electrode TE and the touch pad may be disposed. The touch line TL1 or TL2 may be formed of at least one of the sensor metal TSM and the bridge metal BRG.

When the display panel 110 is of a type in which the touch sensor is embedded, the touch line TL1 or TL2 may extend along the outer inclined surface of the encapsulation layer ENCAP and may extend beyond the upper portion of the dam DAM to the non-display area NDA.

A protection layer PAC may be disposed while covering the touch sensor TS. The protection layer PAC may be an organic insulation film.

The display device may include a plurality of insulation films positioned on the substrate SUB and positioned under the plurality of light emitting elements ED. In the disclosure, the plurality of insulation films positioned on the substrate SUB and positioned under the plurality of light emitting elements ED may refer to the first buffer layer BUF1 to the second planarization layer PLN2 and the insulation films positioned therebetween.

The display device may include a moisture-preventing structure MPS. The moisture-preventing structure MPS may be disposed in the first non-display area NDA1. In the embodiments illustrated in FIG. 5, the moisture-preventing structure MPS may be positioned in the outer disconnected portion area OSTA. In the disclosure, the moisture-preventing structure MPS positioned in the outer disconnected portion area OSTA may be referred to as an outer moisture-preventing structure.

The moisture-preventing structure MPS may include an undercut area of at least one of a plurality of insulation films. The moisture-preventing structure MPS of the display device according to the embodiments illustrated in FIG. 5 may include an undercut area positioned in the inorganic insulation film positioned under the plurality of light emitting elements ED and disposed on the substrate SUB. The undercut area being positioned in the inorganic insulation film may mean that the undercut area is formed by etching the inorganic insulation film. For example, the above-described inorganic insulation film described above may be one or more of a multi-buffer layer MBUF, an active buffer layer ABUF, a first gate insulation film GI1, a first interlayer insulation film ILD1, a second buffer layer BUF2, a second gate insulation film GI2, and a second interlayer insulation film ILD2. The display device according to an embodiment illustrated in FIG. 5 includes the moisture-preventing structure MPS in which the active buffer layer ABUF, the first gate insulation film GI1, the first interlayer insulation film ILD1, the second buffer layer BUF2, the second gate insulation film GI2, and the second interlayer insulation film ILD2 include the undercut area UCA.

The first non-display area NDA1 may include a variable bezel area VBA, an inner disconnected portion area ISTA, a dam area DAMA, and an outer disconnected portion area OSTA. The dam area DAMA may be an area in which the dam DAM for controlling the flow of the second encapsulation layer PCL is positioned. Accordingly, the dam DAM may be positioned in the first non-display area NDA1. The dam DAM may include one or more insulation films and may include, e.g., a second planarization layer PLN2 and a bank BANK positioned on the second planarization layer PLN2.

The disconnected portion ST may be positioned in the first non-display area NDA1. As the disconnected portion ST is positioned in the first non-display area NDA1, it is possible to prevent external moisture from penetrating into the display area DA through the camera hole CH. The disconnected portion ST may refer to a structure for blocking the moisture permeation path by cutting the light emitting layer EL and the cathode electrode CE formed by being entirely deposited in the whole of the display area DA and the first non-display area NDA1 of the display device. The disconnected portion ST may refer to a structure in which the light emitting layer EL and the cathode electrode CE are disconnected by a step formed by the second source-drain electrode SD2. For example, the disconnected portion ST may include a second source-drain electrode SD2 and a light emitting layer EL, and may further include a cathode electrode CE. In this example, the second source-drain electrode SD2 may have a triple layer structure including a first layer, a second layer positioned on the first layer, and a third layer positioned on the second layer, and may have a structure in which the second layer is recessed between the first layer and the third layer.

The disconnected portion ST may include an inner disconnected portion IST and an outer disconnected portion OST. The inner disconnected portion IST may be positioned between the display area DA and the dam DAM. In other words, the inner disconnected portion IST may refer to a disconnected portion positioned in the inner disconnected portion area ISTA. The outer disconnected portion OST may be positioned between the dam DAM and the camera hole CH. In other words, the outer disconnected portion OST may refer to a disconnected portion positioned in the outer disconnected portion area OSTA. As the disconnected portions ST is provided inside and outside the dam DAM, it is possible to more effectively prevent external moisture from penetrating into the display area DA through the camera hole CH.

The variable bezel area VBA may be positioned in the first non-display area NDA1 and may be positioned between the display area DA and the inner disconnected portion area ISTA. Signal lines for transferring signals to a plurality of light emitting elements positioned in the display area DA may be positioned in the variable bezel area VBA. For example, the first gate electrode GAT1, the second gate electrode GAT2, the first source-drain electrode SD1, and the second source-drain electrode SD2 may be positioned in the variable bezel area VBA. More specifically, a plurality of gate lines may be positioned in the variable bezel area VBA.

FIG. 6 is a cross-sectional view illustrating a display device 100 according to embodiments of the disclosure. More specifically, FIG. 6 is a cross-sectional view of portion A-B of FIG. 4.

Hereinafter, in describing the embodiments illustrated in FIG. 6, what is not particularly described otherwise may be the same as those described above with reference to FIGS. 1 to 5.

The display device according to the embodiments illustrated in FIG. 6 includes an inner moisture-preventing structure, unlike the display device according to the embodiments illustrated in FIG. 5, which includes an outer moisture-preventing structure. In other words, the moisture-preventing structure MPS of the display device according to the embodiments illustrated in FIG. 6 is an inner moisture-preventing structure positioned in the inner disconnected portion area ISTA.

The display device according to embodiments of the disclosure may include two or more moisture-preventing structures.

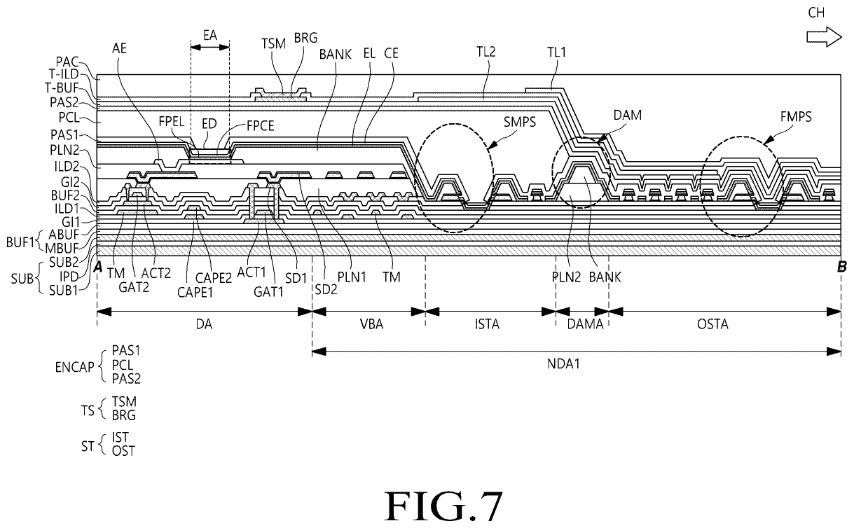

FIG. 7 is a cross-sectional view illustrating a display device 100 according to embodiments of the disclosure. More specifically, FIG. 7 is a cross-sectional view of portion A-B of FIG. 4.

Hereinafter, in describing the embodiments illustrated in FIG. 7, what is not particularly described otherwise may be the same as those described above with reference to FIGS. 1 to 6.

Unlike the display device according to the embodiments illustrated in FIG. 5, which does not include the inner moisture-preventing structure but includes the outer moisture-preventing structure, the display device according to the embodiments illustrated in FIG. 7 includes the outer moisture-preventing structure and the inner moisture-preventing structure. In other words, the display device according to the embodiments illustrated in FIG. 7 may include one or more moisture-preventing structures MPS which may include an inner moisture-preventing structure positioned in the inner disconnected portion area ISTA and an outer moisture-preventing structure positioned in the outer disconnected portion area OSTA.

In the display device according to embodiments of the disclosure, the light emitting layer EL may be positioned to extend from the display area DA to the boundary of the camera hole CH. In other words, the light emitting layer EL may be formed by being entirely deposited on the entire area of the display area DA. The light emitting layer EL may be disconnected by the moisture-preventing structure MPS. As the light emitting layer EL is disconnected at the moisture-preventing structure MPS, it is possible to prevent external moisture entering through the camera hole CH from penetrating into the display area DA through the light emitting layer EL.

The moisture-preventing structure MPS may include an undercut area UCA. The undercut area UCA may be formed in the inorganic insulation film disposed on the substrate SUB and positioned under the plurality of light emitting elements ED.

Referring to FIG. 7, the moisture-preventing structure MPS includes a first moisture-preventing structure FMPS and a second moisture-preventing structure SMPS. As shown, the first moisture-preventing structure FMPS is disposed between the dam structure DAM and the camera hole CH from a plan view. The dam structure DAM is between the first moisture-preventing structure FMPS and the second moisture-preventing structure SMPS from a plan view. In addition, various structures for preventing moisture permeation can be provided between the first moisture-preventing structure FMPS and the dam structure DAM. Various structures for preventing moisture permeation can also be provided between the second moisture-preventing structure FMPS and the dam structure DAM.

As described above, the display device according to the embodiments of the disclosure may include one or more moisture-preventing structures MPS disposed in the first non-display area. Hereinafter, a moisture-preventing structure MPS that may be included in embodiments of the disclosure is described in more detail.

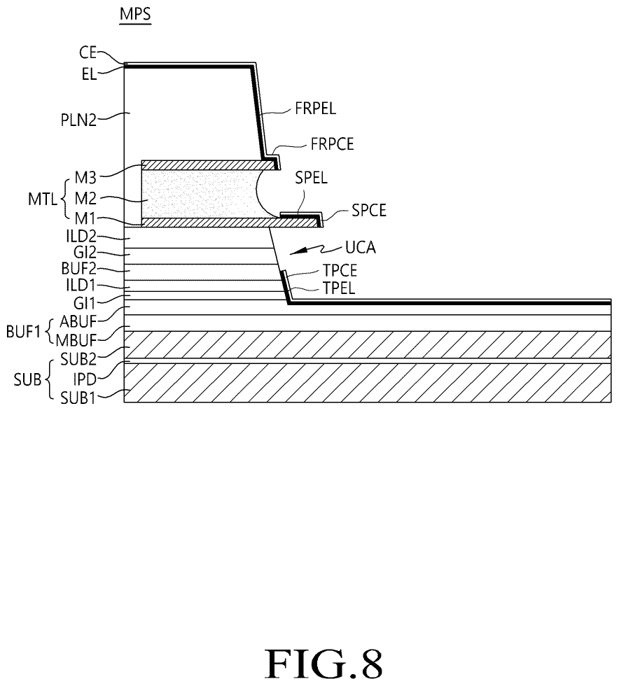

FIG. 8 is a cross-sectional view illustrating a moisture-preventing structure MPS of a display device according to embodiments of the disclosure. Hereinafter, in describing the display device according to the embodiments illustrated in FIG. 8, what is not particularly described otherwise may be the same as those described above with reference to FIGS. 1 to 7.

Referring to FIG. 8, the moisture-preventing structure MPS may include an undercut area UCA of at least one of a plurality of insulation films. In the embodiments illustrated in FIG. 8, the undercut area UCA may be formed in the active buffer layer ABUF to the second interlayer insulation film ILD2. The light emitting layer EL may be disconnected at the undercut area UCA.

The moisture-preventing structure MPS may include a metal layer MTL positioned on the undercut area UCA. The metal layer MTL may be, e.g., a second source-drain electrode. The light emitting layer EL may be disconnected at a side surface of the metal layer MTL.

The metal layer MTL may be formed of, e.g., a triple layer. When the metal layer MTL is a triple layer, the metal layer MTL may include a first layer M1, a second layer M2 positioned on the first layer M1, and a third layer M3 positioned on the second layer M2.

The first layer M1 and the third layer M3 may be metal layers of the same material, and the second layer M2 may be a metal layer of a material different from the first layer M1 and the third layer M3. For example, the first layer M1 and the third layer M3 may include titanium (Ti), and the second layer M2 may include aluminum (Al). For example, the metal layer MTL may have a multilayer structure having a Ti/Al/Ti structure. As such materials are selected for the first layer M1 to the third layer M3, the second layer M2 may be formed of a material having better conductivity, and the first layer M1 and the third layer M3 may be formed of materials capable of protection during the manufacturing process.

The second layer M2 may have a shape further recessed than the first layer M1 and the third layer M3. In other words, the second layer M2 may be more etched than the first layer M1 and the third layer M3, and thus may have a shape further recessed than the first layer M1 and the third layer M3. Accordingly, the first layer M1 and the third layer M3 may protrude further than the second layer M2. Further, the first layer M1 may have a shape further protruding than the third layer M3. Here, being recessed or protruding means being recessed or protruding in a direction parallel to the substrate SUB, and may mean being recessed or protruding with respect to the undercut area UCA. As the first layer M1, the second layer M2, and the third layer M3 have the above-described shapes, the light emitting layer EL may be effectively disconnected by the moisture-preventing structure MPS. In particular, the light emitting layer EL may be disconnected at least twice by the moisture-preventing structure MPS. For example, the light emitting layer EL may be disconnected at the undercut area UCA and may be disconnected at a side surface of the metal layer MTL. More specifically, the light emitting layer EL may be disconnected between the first layer M1 and the second layer M2. Further, the light emitting layer EL may be disconnected between the second layer M2 and the third layer M3. Further, the light emitting layer EL may be disconnected between the first layer M1 and the third layer M3.

The second layer M2 may have a shape in which an interface with the first layer M1 protrudes more than an interface with the third layer M3. This shape may be formed by further etching the second layer M2 than the first layer M1 and the third layer M3.

The undercut area UCA may mean an area undercut with respect to the metal layer MTL. In particular, it may refer to an area undercut under the first layer M1.

The moisture-preventing structure MPS illustrated in FIG. 8 may be formed as follows.

First, a plurality of insulation films may be formed on the substrate SUB. The plurality of insulation films may be one or more of a multi-buffer layer MBUF, an active buffer layer ABUF, a first gate insulation film GI1, a first interlayer insulation film ILD1, a second buffer layer BUF2, a second gate insulation film GI2, and a second interlayer insulation film ILD2. A metal layer MTL may be patterned on the plurality of insulation films. The metal layer MTL may be disposed in the order of the first layer M1, the second layer M2, and the third layer M3.

A second planarization layer PLN2 may be formed to cover a portion of the metal layer MTL. In this case, the exposed second layer M2 of the metal layer MTL may be partially etched while developing the second planarization layer PLN2.

After the anode electrode material is deposited on the second planarization layer PLN2, the anode electrode may be formed by performing a wet etching process. In this case, while the wet etching process is performed, the exposed second layer M2 of the metal layer MTL may be further etched.

A dry etching process may be performed to pattern some of the plurality of insulation films. In the process of performing the dry etching process, some insulation films disposed under the metal layer MTL may be etched inwards under the metal layer MTL to form an undercut area UCA. For example, the second interlayer insulation film ILD2, the second gate insulation film GI2, the second buffer layer BUF2, the first interlayer insulation film ILD1, the first gate insulation film GI1, and the active buffer layer ABUF disposed under the metal layer MTL may be etched inwards under the metal layer MTL to form an undercut area UCA.

A bank BANK may be formed to cover a portion of the anode electrode AE. In this case, the exposed second layer M2 of the metal layer MTL may be further etched while developing the bank BANK. Through the dry etching process, the wet etching process, and the developing process, the metal layer MTL may have the structure in which the second layer M2 is recessed between the first layer M1 and the third layer M3, and an undercut area UCA may be formed under the metal layer MTL.

The light emitting layer EL and the cathode electrode CE may be sequentially formed. In this case, the light emitting layer EL may be disconnected at the side surface of the metal layer MTL and the undercut area UCA.

Referring to FIG. 8, the light emitting layer EL has various portions. As described previously, the light emitting layer EL includes a first portion FPEL, a second portion SPEL, and a third portion TPEL. The light emitting layer EL may further include a fourth portion FRPEL. As shown, the first, second, third, and fourth portions of the light emitting layer EL are spaced apart from each other. It may also be said that the first, second, third, and fourth portions of the light emitting layer EL are disconnected from each other.

Here, the second portion SPEL of the light emitting layer EL is on the first metal layer M1. The first metal layer M1 extends in a first direction (e.g., lateral direction) further than a portion of the insulation films to form an undercut area UCA. For example, the first metal layer M1 extends further than a portion of the insulation films such as ILD2, GI2, BUF2, ILD1, GI1 to form the undercut area UCA.

The third portion TPEL of the light emitting layer EL is disposed at a location adjacent to the undercut area UCA. For example, the third portion TPEL of the light emitting layer covers the side surfaces of insulation films such as BUF2, ILD1, GI1, BUF1. While the third portion TPEL of the light emitting layer EL is spaced apart from the second portion SPEL of the light emitting layer EL, the third portion TPEL and the second portion SPEL overlaps with each other from a plan view.

The fourth portion FRPEL of the light emitting layer EL is on the metal layer MTL. The third metal layer M3 extends in the first direction (e.g., lateral direction) further than a portion of the second metal layer M2. To be specific, the fourth portion FRPEL of the light emitting layer EL is on the extended portion of the third metal layer M3. While it can be said that both the fourth portion FRPEL of the light emitting layer EL and the second portion SPEL of the light emitting layer EL are on the first metal layer M1, the fourth portion FRPEL of the light emitting layer EL is directly on the third metal layer M3 and the second portion SPEL of the light emitting layer EL is directly on the first metal layer M1.

Similarly, the cathode electrode CE has various portions. As described previously, the cathode electrode CE includes a first portion FPCE, a second portion SPCE, and a third portion TPCE. The cathode electrode CE may further include a fourth portion FRPCE. As shown, the first, second, third, and fourth portions of the cathode electrode CE are spaced apart from each other. It may also be said that the first, second, third, and fourth portions of the cathode electrode CE are disconnected from each other.

Here, the second portion SPCE of the cathode electrode CE is on the first metal layer M1. To be specific, the second portion SPCE of the cathode electrode CE is on the second portion SPEL of the light emitting layer EL.

The third portion TPCE of the cathode electrode CE is disposed at a location adjacent to the undercut area UCA. To be specific, the third portion TPCE of the cathode electrode CE is on the third portion TPEL of the light emitting layer EL. While the third portion TPCE of the cathode electrode CE is spaced apart from the second portion SPCE of the cathode electrode CE, the third portion TPCE and the second portion SPCE overlaps with each other from a plan view.

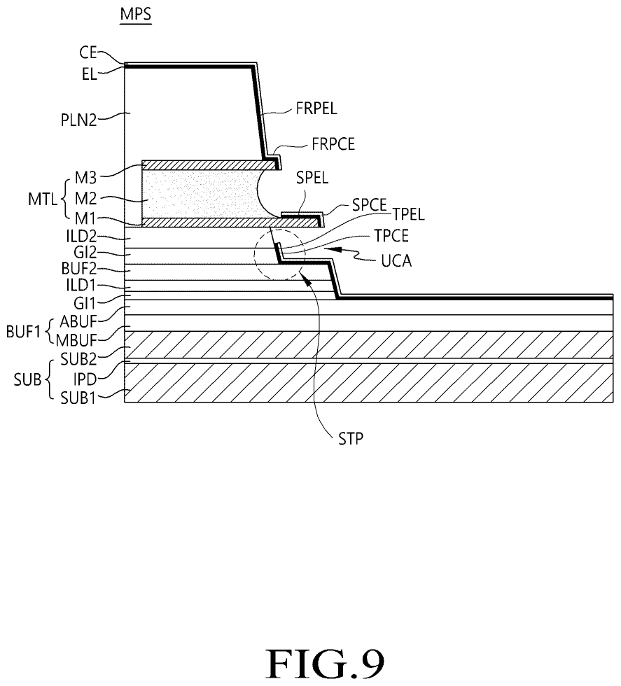

The fourth portion FRPCE of the cathode electrode CE is on the metal layer MTL. To be specific, the fourth portion FRPCE of the cathode electrode CE is on the fourth portion FRPEL of the light emitting layer EL. Both the fourth portion FRPCE of the cathode electrode CE and the fourth portion FRPEL of the light emitting layer EL are spaced apart from the second metal layer M2. It can be said that both the fourth portion FRPCE of the cathode electrode CE and the second portion SPCE of the cathode electrode CE are on the first metal layer M1. Further, the fourth portion FRPCE of the cathode electrode CE is in direct contact with the fourth portion FRPEL of the light emitting layer EL and the second portion SPCE of the cathode electrode CE is in direct contact with the second portion SPEL of the light emitting layer EL. These features are also shown in FIG. 9 and will not be repeatedly described.

FIG. 9 is a cross-sectional view illustrating a moisture-preventing structure of a display device according to embodiments of the disclosure. Hereinafter, in describing the display device according to the embodiments illustrated in FIG. 9, what is not particularly described otherwise may be the same as those described above with reference to FIGS. 1 to 8.

Referring to FIG. 9, the moisture-preventing structure MPS may include an undercut area UCA of at least one of a plurality of insulation films. In the embodiments illustrated in FIG. 9, the undercut area UCA may be formed in the second buffer layer BUF2 to the second interlayer insulation film ILD2. The light emitting layer EL may be disconnected at the undercut area UCA.

The moisture-preventing structure MPS illustrated in FIG. 9 may be different from the moisture-preventing structure MPS illustrated in FIG. 8 in terms of the shape of the undercut area UCA. In the moisture-preventing structure MPS illustrated in FIG. 9, the undercut area UCA may include a step portion STP.

The step portion STP may refer to a step formed as some insulation films are not etched inwards under the metal layer MTL in the undercut area UCA. For example, when the second interlayer insulation film ILD2 and the second gate insulation film GI2 are etched inwards under the metal layer MTL, and the second buffer layer BUF2, the first interlayer insulation film ILD1, and the first gate insulation film GI1 are not etched inwards under the metal layer MTL, the step portion STP may include the second buffer layer BUF2, the first interlayer insulation film ILD1, and the first gate insulation film GI1.

In some embodiments, the third portion TPEL of the light emitting layer EL is disposed over the step portion STP and covers the side surfaces of GI2, BUF2, ILD2, and covers the top surfaces of BUF2. Further, the third portion TPEL of the light emitting layer EL covers the side surfaces of BUF2, ILD1, GI1.

The moisture-preventing structure MPS illustrated in FIG. 9 may be formed as follows.

First, a plurality of insulation films may be formed on the substrate SUB. The plurality of insulation films may be one or more of a multi-buffer layer MBUF, an active buffer layer ABUF, a first gate insulation film GI1, a first interlayer insulation film ILD1, a second buffer layer BUF2, a second gate insulation film GI2, and a second interlayer insulation film ILD2. Some of the plurality of insulation films may be etched adjacent to an area in which the moisture-preventing structure MPS is to be formed later. For example, the second gate insulation film GI2 and the second interlayer insulation film ILD2 may be etched to correspond to an area to be formed by patterning the metal layer MTL later, thereby exposing the second buffer layer BUF2. In this case, the exposed second buffer layer BUF2 may also be partially etched. Specifically, when a mask having an opening is positioned on the plurality of insulation films and a dry etching process is performed, the second gate insulation film GI2 and the second interlayer insulation film ILD2 may be etched to expose the second buffer layer BUF2. This etching process may be referred to as a primary dry etching process. The opening formed in the mask may be formed at a position corresponding to an area in which the metal layer MTL is to be patterned later.

A metal layer MTL may be patterned on the plurality of insulation films. The metal layer MTL may be disposed in the order of the first layer M1, the second layer M2, and the third layer M3.

A second planarization layer PLN2 may be formed to cover a portion of the metal layer MTL. In this case, the exposed second layer M2 of the metal layer MTL may be partially etched while developing the second planarization layer PLN2.

After the anode electrode material is deposited on the second planarization layer PLN2, the anode electrode may be formed by performing a wet etching process. In this case, while the wet etching process is performed, the exposed second layer M2 of the metal layer MTL may be further etched.

A dry etching process may be performed to pattern some of the plurality of insulation films. While the dry etching process is performed, some insulation films disposed under the metal layer MTL may be etched inward under the metal layer MTL to form an undercut area UCA, and some exposed insulation films may be etched. This etching process may be referred to as a second dry etching process. While the second dry etching process is performed, isotropic conditions of the dry etching process may be used. For example, when the second dry etching process is performed using the metal layer MTL as a mask, the second interlayer insulation film ILD2 and the second gate insulation film GI2 disposed under the metal layer MTL may be etched inwards under the metal layer MTL to form an undercut area UCA. At the same time, the second buffer layer BUF2, the first interlayer insulation film ILD1, and the first gate insulation film GI1 may be etched toward the substrate SUB to form a step shape. In this case, the active buffer layer ABUF may also be partially etched toward the substrate SUB.

In other words, when the process of etching the plurality of insulation films disposed in the area in which the moisture-preventing structure MPS is positioned is divided into the first dry etching process and the second dry etching process, the undercut area UCA and the step portion STP may be simultaneously formed under the metal layer MTL.

A bank BANK may be formed to cover a portion of the anode electrode AE. In this case, the exposed second layer M2 of the metal layer MTL may be further etched while developing the bank BANK. Through the dry etching process, the wet etching process, and the developing process, the metal layer MTL may have the structure in which the second layer M2 is recessed between the first layer M1 and the third layer M3, and the undercut area UCA and the step portion STP may be formed under the metal layer MTL.

The light emitting layer EL and the cathode electrode CE may be sequentially formed. In this case, the light emitting layer EL may be disconnected at the side surface of the metal layer MTL and the undercut area UCA.

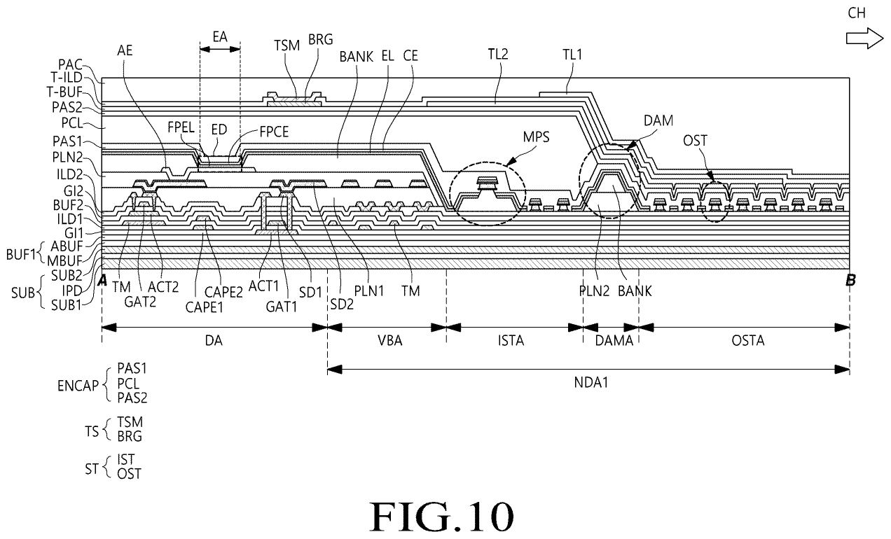

FIG. 10 is a cross-sectional view illustrating a display device 100 according to embodiments of the disclosure. More specifically, FIG. 10 is a cross-sectional view of portion A-B of FIG. 4.

Hereinafter, in describing the embodiments illustrated in FIG. 10, what is not particularly described otherwise may be the same as those described above with reference to FIGS. 1 to 9.

The display device according to the embodiments illustrated in FIG. 10 may include an undercut area UCA of an organic insulation film, unlike the display device according to the embodiments illustrated in FIGS. 5 to 7, in which the moisture-preventing structure MPS includes an undercut area UCA of the inorganic insulation film. More specifically, the moisture-preventing structure MPS of the display device according to the embodiments illustrated in FIG. 10 may include an inner moisture-preventing structure and may include an undercut area UCA of the organic insulation film.

The moisture-preventing structure MPS may include an undercut area UCA. The undercut area UCA may be formed in the organic insulation film disposed on the substrate SUB and positioned under the plurality of light emitting elements ED.

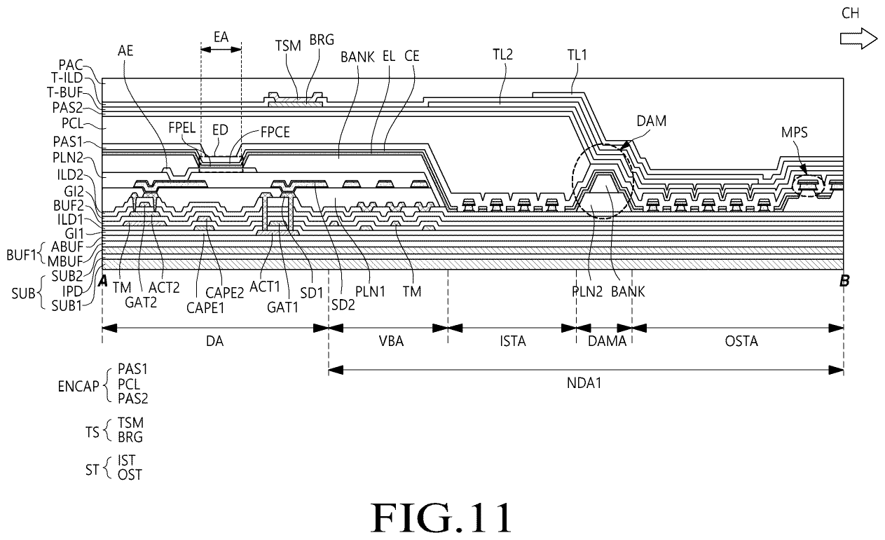

FIG. 11 is a cross-sectional view illustrating a display device 100 according to embodiments of the disclosure. More specifically, FIG. 11 is a cross-sectional view of portion A-B of FIG. 4.

Hereinafter, in describing the embodiments illustrated in FIG. 11, what is not particularly described otherwise may be the same as those described above with reference to FIGS. 1 to 10.

Unlike the display device according to the embodiments illustrated in FIG. 10, which includes an inner moisture-preventing structure and does not include an outer moisture-preventing structure, the display device according to the embodiments illustrated in FIG. 11 may include an outer moisture-preventing structure and may not include an inner moisture-preventing structure. Further, the display device according to the embodiments illustrated in FIG. 11 may include an undercut area UCA of the organic insulation film, similarly to the display device according to the embodiments illustrated in FIG. 10.

The moisture-preventing structure MPS may include an undercut area UCA. The undercut area UCA may be formed in the organic insulation film disposed on the substrate SUB and positioned under the plurality of light emitting elements ED.

Embodiments illustrated in FIGS. 10 and 11 may provide a display device including a moisture-preventing structure MPS including a so-called undercut area UCA of organic insulation film. Further, the embodiments illustrated in FIG. 10 include an inner moisture-preventing structure, and the embodiments illustrated in FIG. 11 include an outer moisture-preventing structure. However, embodiments of the disclosure are not limited to these display devices, and embodiments including an inner moisture-preventing structure and/or an outer moisture-preventing structure and the moisture-preventing structures MPS including an undercut area UCA of an organic insulation film are also included in the embodiments of the disclosure.

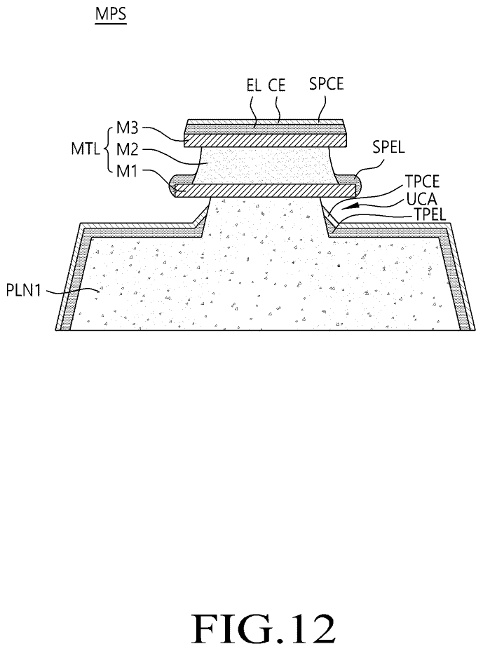

FIG. 12 is a cross-sectional view illustrating a moisture-preventing structure MPS of a display device 100 as illustrated in FIGS. 10 and 11. Hereinafter, in describing the display device according to the embodiments illustrated in FIG. 12, what is not particularly described otherwise may be the same as those described above with reference to FIGS. 1 to 11.

The moisture-preventing structure MPS may include an undercut area UCA. The undercut area UCA may be formed in the organic insulation film disposed on the substrate SUB and positioned under the plurality of light emitting elements. The undercut area UCA being formed in the organic insulation film may mean that at least one organic insulation film is etched to form an undercut area UCA. The organic insulation film where the undercut area UCA is formed may be one or more of, e.g., the first planarization layer PLN1 and the second planarization layer PLN2. FIG. 12 illustrates embodiments in which the moisture-preventing structure MPS includes a first planarization layer PLN1 and an undercut area UCA is formed in the first planarization layer PLN1, but embodiments of the disclosure are not limited thereto. For example, embodiments of the disclosure may include embodiments in which the moisture-preventing structure may include one or more of the first planarization layer PLN1 and the second planarization layer PLN2, and an undercut area UCA is formed in one or more of the first planarization layer PLN1 and the second planarization layer PLN2.

The moisture-preventing structure MPS may include a metal layer MTL positioned on the undercut area UCA. The metal layer MTL may be, e.g., a second source-drain electrode. The light emitting layer EL may be disconnected at a side surface of the metal layer MTL.

The metal layer MTL may be formed of, e.g., a triple layer. When the metal layer MTL is a triple layer, the metal layer MTL may include a first layer M1, a second layer M2 positioned on the first layer M1, and a third layer M3 positioned on the second layer M2.

The second layer M2 may have a shape further recessed than the first layer M1 and the third layer M3. In other words, the second layer M2 may be more etched than the first layer M1 and the third layer M3, and thus may have a shape further recessed than the first layer M1 and the third layer M3. Accordingly, the first layer M1 and the third layer M3 may protrude further than the second layer M2. Here, being recessed or protruding means being recessed or protruding in a direction parallel to the substrate SUB, and may mean being recessed or protruding with respect to the undercut area UCA. As the first layer M1, the second layer M2, and the third layer M3 have the above-described shapes, the light emitting layer EL may be effectively disconnected by the moisture-preventing structure MPS. In particular, the light emitting layer EL may be disconnected at least twice by the moisture-preventing structure MPS. For example, the light emitting layer EL may be disconnected at the undercut area UCA and may be disconnected at a side surface of the metal layer MTL. More specifically, the light emitting layer EL may be disconnected between the first layer M1 and the second layer M2.

The second layer M2 may have a shape in which an interface with the first layer M1 protrudes more than an interface with the third layer M3. This shape may be formed by further etching the second layer M2 than the first layer M1 and the third layer M3.

The undercut area UCA may mean an area undercut with respect to the metal layer MTL. In particular, it may refer to an area undercut under the first layer M1.

Referring to FIG. 12, the light emitting layer EL can have various portions. Here, the light emitting layer EL includes a first portion FPEL, a second portion SPEL, and a third portion TPEL. The first portion FPEL overlaps with the display area DA from a plan view. As shown, the first, second, third portions of the light emitting layer EL are spaced apart from each other. It may also be said that the first, second, third portions of the light emitting layer EL are disconnected from each other.

Here, the second portion SPEL of the light emitting layer EL is on the first metal layer M1. The first metal layer M1 extends in a first direction (e.g., lateral direction) further than a portion of the insulation films PLN1 to form an undercut area UCA. For example, the first metal layer M1 extends further than a portion of the insulation film PLN1 to form the undercut area UCA.

The third portion TPEL of the light emitting layer EL is disposed at a location adjacent to the undercut area UCA. In particular, the third portion TPEL of the light emitting layer EL is disposed below the second portion SPEL of the light emitting layer EL. For example, the third portion TPEL of the light emitting layer covers the various surfaces (e.g., side surfaces and top surfaces) of insulation film PLN1. While the third portion TPEL of the light emitting layer EL is spaced apart from the second portion SPEL of the light emitting layer EL, the third portion TPEL and the second portion SPEL overlaps with each other from a plan view.

Similarly, the cathode electrode CE has various portions. Here, the cathode electrode CE includes a first portion FPCE, a second portion SPCE, and a third portion TPCE. The first portion FPCE of the cathode electrode CE overlaps with the display area DA from a plan view. As shown, the first, second, third portions of the cathode electrode CE are spaced apart from each other. It may also be said that the first, second, third portions of the cathode electrode CE are disconnected from each other.

Here, the second portion SPCE of the cathode electrode CE is on the first metal layer M1. To be specific, the second portion SPCE of the cathode electrode CE is on the second portion SPEL of the light emitting layer EL and on the third metal layer M3. As shown in FIG. 12, the second portion SPCE of the cathode electrode CE is not in direct contact with the second portion SPEL of the light emitting layer EL.

The third portion TPCE of the cathode electrode CE is disposed at a location adjacent to the undercut area UCA. To be specific, the third portion TPCE of the cathode electrode CE is on the third portion TPEL of the light emitting layer EL. While the third portion TPCE of the cathode electrode CE is spaced apart from the second portion SPCE of the cathode electrode CE, the third portion TPCE and the second portion SPCE overlaps with each other from a plan view.

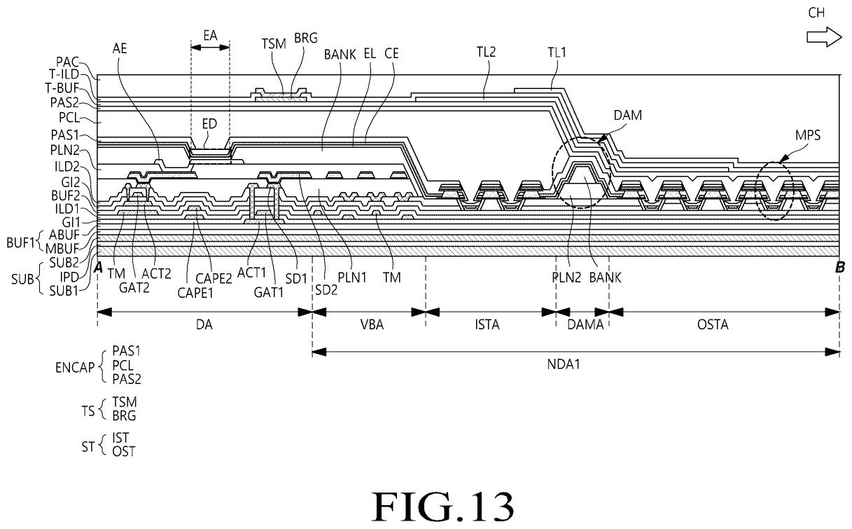

FIG. 13 is a cross-sectional view illustrating a display device according to embodiments of the disclosure. More specifically, FIG. 13 is a cross-sectional view of portion A-B of FIG. 4.

Hereinafter, in describing the display device illustrated in FIG. 13, what is not particularly described otherwise may be the same as the display device described above with reference to FIGS. 1 to 12.

The display device according to the embodiments illustrated in FIG. 13 is different from the display device illustrated in FIGS. 5 to 7 in that the disconnected portion is not positioned in the outer disconnected portion area OSTA and the inner disconnected portion area ISTA, and the moisture-preventing structure MPS is entirely positioned in the outer disconnected portion area OSTA and the inner disconnected portion area ISTA. Further, the structure of the moisture-preventing structure MPS is also different from the display device illustrated in FIGS. 5 to 7. Although FIG. 10 illustrates an embodiment in which no disconnected portion is positioned in the outer disconnected portion area OSTA and the inner disconnected portion area ISTA, an embodiment in which one or more moisture-preventing structures MPS as illustrated in FIG. 10 are included in the first non-display area, and the disconnected portion ST illustrated in FIGS. 5 to 7 may also be included in the embodiments of the disclosure.

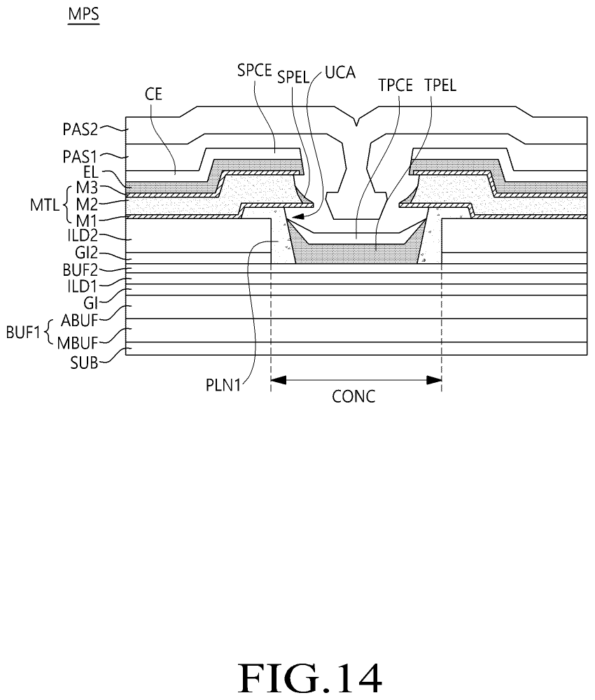

FIG. 14 is a cross-sectional view illustrating the moisture-preventing structure MPS illustrated in FIG. 13. Hereinafter, in describing the moisture-preventing structure MPS illustrated in FIG. 14, what is not particularly described otherwise may be the same as the moisture-preventing structure described above with reference to FIGS. 1 to 13.

Referring to FIG. 14, the moisture-preventing structure MPS may include an undercut area UCA. The undercut area UCA may be positioned in the organic insulation film disposed on the substrate UCA and positioned under the plurality of light emitting elements. The undercut area UCA being positioned in the organic insulation film may mean that at least one organic insulation film is etched to form an undercut area UCA. The organic insulation film where the undercut area UCA is formed may be one or more of, e.g., the first planarization layer PLN1 and the second planarization layer PLN2. FIG. 14 illustrates embodiments in which the moisture-preventing structure MPS includes a first planarization layer PLN1 and an undercut area UCA is formed in the first planarization layer PLN1, but embodiments of the disclosure are not limited thereto. For example, embodiments of the disclosure may include embodiments in which the moisture-preventing structure may include one or more of the first planarization layer PLN1 and the second planarization layer PLN2, and an undercut area UCA is formed in one or more of the first planarization layer PLN1 and the second planarization layer PLN2.

The moisture-preventing structure MPS may include a concave portion CONC of at least one of a plurality of insulation films. For example, the concave portion CONC may be positioned in the inorganic insulation film disposed on the substrate SUB and positioned under the plurality of light emitting elements. The concave portion CONC being positioned in the inorganic insulation film may mean that at least one of the inorganic insulation films is etched to form a concave portion CONC. The inorganic insulation film may be an inorganic insulation film positioned on the substrate SUB and positioned under the light emitting element. For example, the inorganic insulation film may be one or more of the first buffer layer BUF1 and the second interlayer insulation film ILD2 and the insulation films positioned between the two layers. FIG. 14 illustrates an embodiment in which the second gate insulation film GI2 to the second interlayer insulation film ILD2 include a concave portion CONC, but embodiments of the disclosure are not limited to these embodiments.

The undercut area UCA of the organic insulation film may be positioned in the concave portion CONC. A portion of the inorganic insulation film may be exposed by the undercut area UCA of the organic insulation film. For example, the second buffer layer BUF2 may be exposed by the undercut area UCA of the organic insulation film, and the light emitting layer EL may be positioned on the exposed second buffer layer BUF2.

The moisture-preventing structure MPS may include a metal layer MTL positioned on the undercut area UCA. The metal layer MTL may be, e.g., a second source-drain electrode. The light emitting layer EL may be disconnected at a side surface of the metal layer MTL.

The metal layer MTL may be formed of, e.g., a triple layer. When the metal layer MTL is a triple layer, the metal layer MTL may include a first layer M1, a second layer M2 positioned on the first layer M1, and a third layer M3 positioned on the second layer M2.

The second layer M2 may have a shape further recessed than the first layer M1 and the third layer M3. In other words, the second layer M2 may be more etched than the first layer M1 and the third layer M3, and thus may have a shape further recessed than the first layer M1 and the third layer M3. Accordingly, the first layer M1 and the third layer M3 may protrude further than the second layer M2. Here, being recessed or protruding means being recessed or protruding in a direction parallel to the substrate SUB, and may mean being recessed or protruding with respect to the undercut area UCA. As the first layer M1, the second layer M2, and the third layer M3 have the above-described shapes, the light emitting layer EL may be effectively disconnected by the moisture-preventing structure MPS. In particular, the light emitting layer EL may be disconnected at least twice by the moisture-preventing structure MPS. For example, the light emitting layer EL may be disconnected at the undercut area UCA and may be disconnected at a side surface of the metal layer MTL. More specifically, the light emitting layer EL may be disconnected between the first layer M1 and the second layer M2.

The second layer M2 may have a shape in which an interface with the first layer M1 protrudes more than an interface with the third layer M3. This shape may be formed by further etching the second layer M2 than the first layer M1 and the third layer M3.

The moisture-preventing structure MPS illustrated in FIG. 14 may be formed as follows.

First, a plurality of insulation films may be formed on the substrate SUB. The plurality of insulation films may be one or more of a multi-buffer layer MBUF, an active buffer layer ABUF, a first gate insulation film GI1, a first interlayer insulation film ILD1, a second buffer layer BUF2, a second gate insulation film GI2, and a second interlayer insulation film ILD2. A dry etching process may be performed to form the concave portion CONC in the plurality of insulation films. For example, the concave portion CONC may be formed by etching the second interlayer insulation film ILD2 and the second gate insulation film GI2. The concave portion CONC may be formed by further etching the insulation film formed under the second gate insulation film GI2.

A planarization layer may be formed on the concave portion CONC and the second interlayer insulation film ILD2. The planarization layer may be an organic insulation film. The planarization layer may be exposed and developed using a halftone mask to fill the concave portion CONC with the planarization layer, which is an organic insulation film. The planarization layer may be a first planarization layer PLN1 or a second planarization layer PLN2. The halftone mask may include a fulltone area and a halftone area. For example, in forming the moisture-preventing structure MPS illustrated in FIG. 14, the planarization layer may be the first planarization layer PLN1. Further, the halftone mask may include a halftone area formed in an area corresponding to the concave portion CONC.

A metal layer MTL may be patterned on the first planarization layer PLN1 and the plurality of insulation films. The metal layer MTL may be disposed in the order of the first layer M1, the second layer M2, and the third layer M3. The exposed second layer M2 of the metal layer MTL may be partially etched by performing a dry etching process on the metal layer MTL.

A second planarization layer PLN2 and a bank BANK each may be formed on a plurality of insulation films. An ashing process may be performed so that the second planarization layer PLN2 may be formed, and a developing process may be performed so that a bank BANK may be formed.

A portion of the first planarization layer PLN1 formed in the concave portion CONC may be etched through an ashing process and a developing process to form an undercut area UCA. For example, the first planarization layer PLN1 may be etched so that an undercut area UCA is formed inwards under the metal layer MTL and the second buffer layer BUF2 is exposed.

Through the dry etching process, the ashing process, and the developing process, the metal layer MTL may have a structure in which the second layer M2 is recessed between the first layer M1 and the third layer M3, and the undercut area UCA may be formed under the metal layer MTL in the concave portion CONC.

The light emitting layer EL and the cathode electrode CE may be sequentially formed. In this case, the light emitting layer EL may be disconnected at the side surface of the metal layer MTL and the undercut area UCA.

A first encapsulation layer PAS1 and a second encapsulation layer PAS2 may be formed on the light emitting layer EL and the cathode electrode CE.

Referring to FIG. 14, the light emitting layer EL can have various portions. Here, the light emitting layer EL includes a first portion FPEL, a second portion SPEL, and a third portion TPEL. The first portion FPEL overlaps with the display area DA from a plan view. As shown, the first, second, third portions of the light emitting layer EL are spaced apart from each other. It may also be said that the first, second, third portions of the light emitting layer EL are disconnected from each other.

Here, the second portion SPEL of the light emitting layer EL is on the first metal layer M1. The first metal layer M1 extends in a first direction (e.g., lateral direction) further than a portion of the insulation films such as ILD2, GI2 to form an undercut area UCA. For example, the first metal layer M1 extends further than a portion of the insulation film ILD2, GI2 to form the undercut area UCA.

The third portion TPEL of the light emitting layer EL is disposed at a location adjacent to the undercut area UCA. In particular, the third portion TPEL of the light emitting layer EL is disposed below the second portion SPEL of the light emitting layer EL. For example, the third portion TPEL of the light emitting layer EL sits on the concave portion CONC. While the third portion TPEL of the light emitting layer EL is spaced apart from the second portion SPEL of the light emitting layer EL, the third portion TPEL and the second portion SPEL overlaps with each other from a plan view.

Similarly, the cathode electrode CE has various portions. Here, the cathode electrode CE includes a first portion FPCE, a second portion SPCE, and a third portion TPCE. The first portion FPCE of the cathode electrode CE overlaps with the display area DA from a plan view. As shown, the first, second, third portions of the cathode electrode CE are spaced apart from each other. It may also be said that the first, second, third portions of the cathode electrode CE are disconnected from each other.

Here, the second portion SPCE of the cathode electrode CE is on the first metal layer M1. To be specific, the second portion SPCE of the cathode electrode CE is on a portion of the light emitting layer EL that is spaced apart from the second portion SPEL of the light emitting layer EL. The second portion SPCE of the cathode electrode CE is also on the third metal layer M3. As shown in FIG. 14, the second portion SPCE of the cathode electrode CE is not in direct contact with the second portion SPEL of the light emitting layer EL.

The third portion TPCE of the cathode electrode CE is disposed at a location adjacent to the undercut area UCA. To be specific, the third portion TPCE of the cathode electrode CE is on the third portion TPEL of the light emitting layer EL. While the third portion TPCE of the cathode electrode CE is spaced apart from the second portion SPCE of the cathode electrode CE, the third portion TPCE and the second portion SPCE overlaps with each other from a plan view.

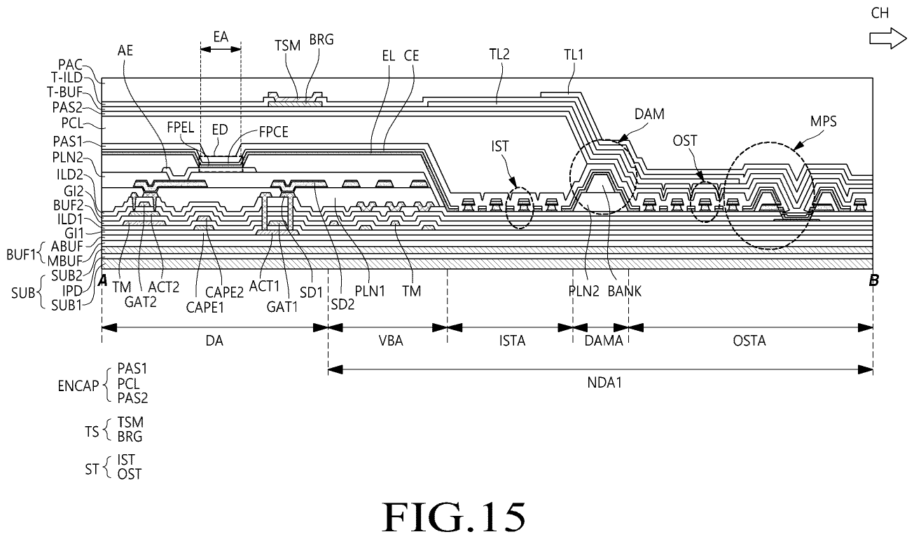

FIG. 15 is an exemplary cross-sectional view of a display device 100 according to embodiments of the disclosure. More specifically, FIG. 15 is an exemplary cross-sectional view of part A-B of FIG. 4. Hereinafter, in describing the embodiments illustrated in FIG. 15, what is not particularly described otherwise may be the same as those described above with reference to FIGS. 1 to 14.

Referring to FIG. 15, the display device 100 may include a moisture-preventing structure MPS. The moisture-preventing structure MPS may be disposed in the outer disconnected portion area OSTA. For example, the moisture-preventing structure MPS may be disposed between the camera hole CH and the dam structure DAM. The moisture-preventing structure MPS illustrated in FIG. 15 may be an outer moisture-preventing structure.

The moisture-preventing structure MPS may include at least one undercut area UCA among a plurality of insulation films. The moisture-preventing structure MPS may include an undercut area positioned in the inorganic insulation film positioned under the plurality of light emitting elements ED. The display device 100 illustrated in FIG. 15 may have the same configuration as that of the display device 100 illustrated in FIG. 5 except that the auxiliary metal layer AML is disposed between the inorganic insulation films in which the moisture-preventing structure MPS is positioned in the undercut area UCA.

Referring to FIG. 15, the moisture-preventing structure MPS may include an auxiliary metal layer AML in or under the undercut area UCA. The auxiliary metal layer AML may serve as an etch stop layer ESL in a process of etching metal layers when forming the moisture-preventing structure MPS. In the description of the disclosure, the auxiliary metal layer AML and the etch stop layer ESL may have the same meaning.

The auxiliary metal layer AML may include a metallic material. For example, the auxiliary metal layer AML may include a single layer or multiple layers of any one of molybdenum (Mo), copper (Cu), titanium (Ti), aluminum (Al), chromium (Cr), gold (Au), nickel (Ni), neodymium (Nd), and tungsten (W), or an alloy thereof, but is not limited thereto. The auxiliary metal layer AML may include the same material as the first gate electrode GAT1, the second gate electrode GAT2, or the metal pattern TM. For example, the auxiliary metal layer AML may be formed of a Mo/Ti double layer or a single layer of Mo.

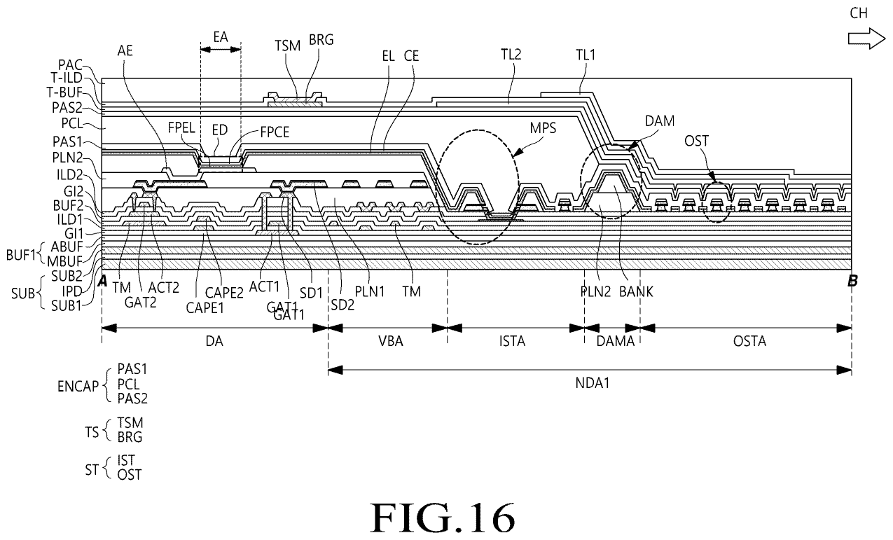

FIG. 16 is an exemplary cross-sectional view of a display device 100 according to embodiments of the disclosure. More specifically, FIG. 16 is an exemplary cross-sectional view of part A-B of FIG. 4. Hereinafter, in describing the embodiments illustrated in FIG. 16, what is not particularly described otherwise may be the same as those described above with reference to FIGS. 1 to 15.

Referring to FIG. 16, the display device 100 may include a moisture-preventing structure MPS. The moisture-preventing structure MPS may be disposed in the inner disconnected portion area ISTA. For example, the moisture-preventing structure MPS may be disposed between the display area DA and the dam structure DAM. The moisture-preventing structure MPS illustrated in FIG. 16 may be an inner moisture-preventing structure.

The display device 100 illustrated in FIG. 16 may have the same configuration as the display device 100 illustrated in FIG. 6, except that the auxiliary metal layer AML is disposed between the inorganic insulation films in which the moisture-preventing structure MPS is positioned in the undercut area UCA.

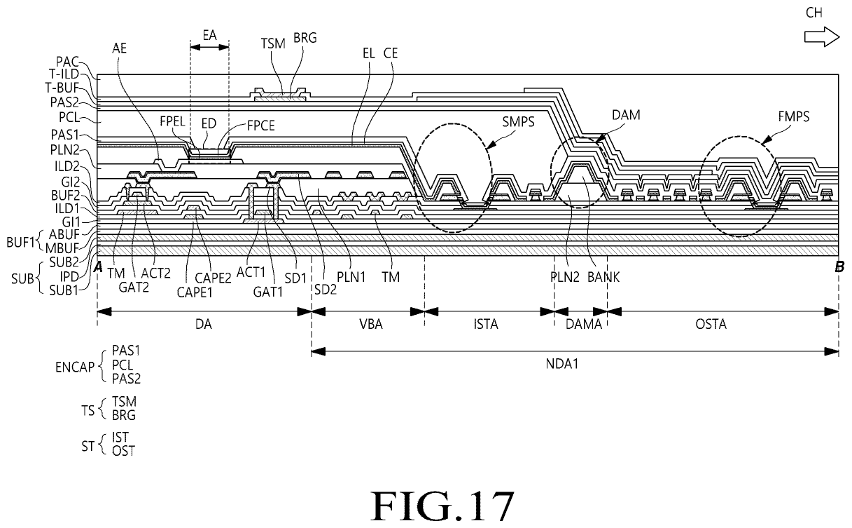

FIG. 17 is an exemplary cross-sectional view of a display device 100 according to embodiments of the disclosure. More specifically, FIG. 17 is an exemplary cross-sectional view of part A-B of FIG. 4. Hereinafter, in describing the embodiments illustrated in FIG. 17, what is not particularly described otherwise may be the same as those described above with reference to FIGS. 1 to 16.

Referring to FIG. 17, the display device 100 may include two or more moisture-preventing structures MPS. The moisture-preventing structure MPS may be disposed in the outer disconnected portion area OSTA and the inner disconnected portion area ISTA. For example, the moisture-preventing structure MPS may be disposed between the display area DA and the dam structure DAM while being disposed between the camera hole CH and the dam structure DAM on a plane. The moisture-preventing structure MPS illustrated in FIG. 17 may be an outer moisture-preventing structure and an inner moisture-preventing structure. The outer moisture-preventing structure may also be referred to as a first moisture-preventing structure FMPS, and the inner moisture-preventing structure may also be referred to as a second moisture-preventing structure SMPS.

Referring to FIG. 17, the first moisture-preventing structure FMPS may be disposed between the camera hole CH and the dam structure DAM on a plane. The dam structure DAM may be disposed between the first moisture-preventing structure FMPS and the second moisture-preventing structure SMPS. The second moisture-preventing structure SMPS may be disposed between the display area DA and the dam structure DAM on a plane.

The display device 100 illustrated in FIG. 17 may have the same configuration as the display device 100 illustrated in FIG. 7, except that the auxiliary metal layer AML is disposed between the inorganic insulation films in which the moisture-preventing structure MPS is positioned in the undercut area UCA.

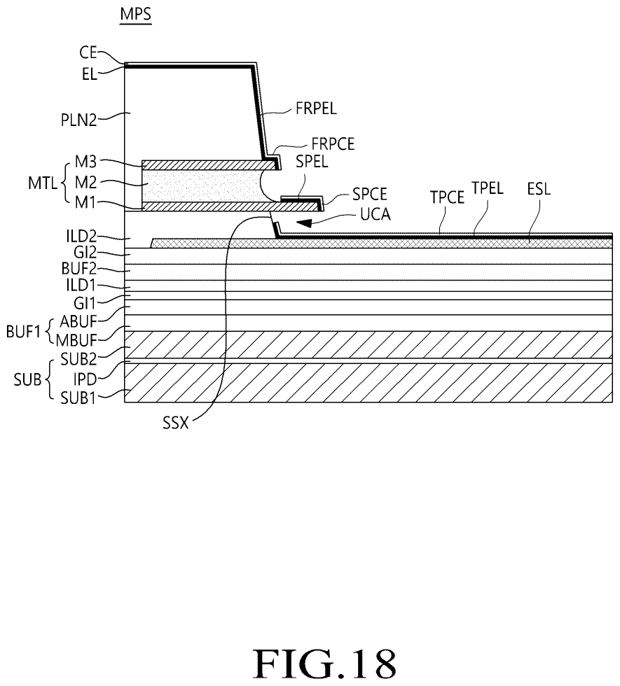

FIG. 18 is an exemplary cross-sectional view of the moisture-preventing structure MPS illustrated in FIGS. 15 to 17. Hereinafter, in describing the embodiments illustrated in FIG. 18, what is not particularly described otherwise may be the same as those described above with reference to FIGS. 1 to 17.

Referring to FIG. 18, the moisture-preventing structure MPS may include at least one undercut area UCA among the plurality of insulation films. In the embodiments illustrated in FIG. 18, the undercut area UCA may be formed between the first buffer layer BUF1 and the second interlayer insulation film ILD2. The light emitting layer EL may be disconnected at the undercut area UCA. The plurality of insulation films illustrated in FIG. 18 may have the same configuration as the plurality of insulation films illustrated in FIG. 8, and thus are not repeatedly described.

The moisture-preventing structure MPS may include a metal layer MTL positioned on the undercut area UCA. The metal layer MTL may have, e.g., the same structure as the second source-drain electrode. The light emitting layer EL may be disconnected at a side surface of the metal layer MTL. The metal layer MTL illustrated in FIG. 18 may have the same configuration as the metal layer MTL illustrated in FIG. 8, and thus are not repeatedly described.

The moisture-preventing structure MPS may include an etch stop layer ESL positioned in or under the undercut area UCA. The etch stop layer ESL may also be referred to as an auxiliary metal layer AML. Referring to FIG. 18, the etch stop layer ESL may be disposed between the plurality of insulation films positioned under the metal layer MTL. For example, the etch stop layer ESL may be disposed between the second gate insulation film GI2 and the second interlayer insulation film ILD2 positioned under the metal layer MTL. The etch stop layer ESL may be disposed to further extend in a first direction (e.g., a lateral direction) than some of the insulation films forming the undercut area UCA. For example, the etch stop layer ESL may be disposed to extend further than a portion of the insulation film such as the second interlayer insulation film ILD2, on the second gate insulation film GI2.

The etch stop layer ESL may include a metallic material. For example, the etch stop layer ESL may include a single layer or multiple layers of any one of molybdenum (Mo), copper (Cu), titanium (Ti), aluminum (Al), chromium (Cr), gold (Au), nickel (Ni), neodymium (Nd), and tungsten (W), or an alloy thereof, but is not limited thereto. For example, the etch stop layer ESL may include the same material as the second gate electrode GAT2. For example, the etch stop layer ESL may be formed of a Mo/Ti double layer or a Mo single layer.

The etch stop layer ESL may prevent some insulation films, disposed thereunder, from being over-etched in the etching process of patterning the plurality of insulation films or patterning the metallic metal such as the anode electrode AE or the metal layer MTL in the process of forming the moisture-preventing structure MPS. For example, in the embodiments illustrated in FIG. 18, the undercut area UCA may be formed in a structure in which a portion of the second interlayer insulation film ILD2 disposed on the etch stop layer ESL is etched, but the etch stop layer ESL is not etched.

Referring to FIG. 18, the light emitting layer EL may have several portions. As described above, the light emitting layer EL may include a first portion FPEL, a second portion SPEL, and a third portion TPEL. The light emitting layer EL may further include a fourth portion FRPEL. As shown, the first portion FPEL, the second portion SPEL, the third portion TPEL, and the fourth portion FRPEL of the light emitting layer EL may be spaced apart from each other. In other words, the first portion FPEL, the second portion SPEL, the third portion TPEL, and the fourth portion FRPEL of the light emitting layer EL may be separated from each other.

Here, the second portion SPEL of the light emitting layer EL may be positioned on the first layer M1 of the metal layer MTL. The first layer M1 of the metal layer MTL may further extend in a first direction (e.g., a lateral direction) than some of the insulation films to form the undercut area UCA. For example, the first layer M1 of the metal layer MTL may extend further than a portion of the insulation film such as the second interlayer insulation film ILD2 to form the undercut area UCA.

The third portion TPEL of the light emitting layer EL may be disposed at a position adjacent to the undercut area UCA. For example, the third portion TPEL of the light emitting layer EL may cover the upper surface of the etch stop layer ESL while covering the side surface SSX of the insulation film including the second interlayer insulation film ILD2. The third portion TPEL of the light emitting layer EL may be spaced apart from the second portion SPEL of the light emitting layer EL, and the third portion TPEL of the light emitting layer EL and the second portion SPEL of the light emitting layer EL may overlap each other on a plane. That is, when seen from a plan view, the third portion TPEL of the light emitting layer EL and the second portion SPEL of the light emitting layer EL overlap each other.

The fourth portion FRPEL of the light emitting layer EL may be positioned on the metal layer MTL. The third layer M3 of the metal layer MTL may further extend in a first direction (e.g., a lateral direction) than a portion of the second layer M2 of the metal layer MTL. For example, the fourth portion FRPEL of the light emitting layer EL may be positioned on an extended portion of the third layer M3 of the metal layer MTL. Both the fourth portion FRPEL of the light emitting layer EL and the second portion SPEL of the light emitting layer EL may be positioned on the first layer M1 of the metal layer MTL, but the fourth portion FRPEL of the light emitting layer EL is directly positioned on the third layer M3 of the metal layer MTL, and the second portion SPEL of the light emitting layer EL is directly positioned on the first layer M1 of the metal layer MTL.

Further, the cathode electrode CE may have several portions. As described above, the cathode electrode CE may include a first portion FPCE, a second portion SPCE, and a third portion TPCE. The cathode electrode CE may further include a fourth portion FRPCE. As shown, the first portion FPCE, the second portion SPCE, the third portion TPCE, and the fourth portion FRPCE of the cathode electrode CE may be spaced apart from each other. Further, it may be said that the first portion FPCE, the second portion SPCE, the third portion TPCE, and the fourth portion FRPCE of the cathode electrode CE are separated from each other.

Here, the second portion SPCE of the cathode electrode CE may be positioned on the first layer M1 of the metal layer MTL. For example, the second portion SPCE of the cathode electrode CE may be positioned on the second portion SPEL of the light emitting layer EL.

The third portion TPCE of the cathode electrode CE may be disposed at a position adjacent to the undercut area UCA. For example, the third portion TPCE of the cathode electrode CE may be positioned on the third portion TPEL of the light emitting layer EL. While the third portion TPCE of the cathode electrode CE is spaced apart from the second portion SPCE of the cathode electrode CE, the third portion TPCE of the cathode electrode CE and the second portion SPCE of the cathode electrode CE may overlap each other on a plane. That is, when seen from a plan view, third portion TPCE of the cathode electrode CE and the second portion SPCE of the cathode electrode CE overlap each other.

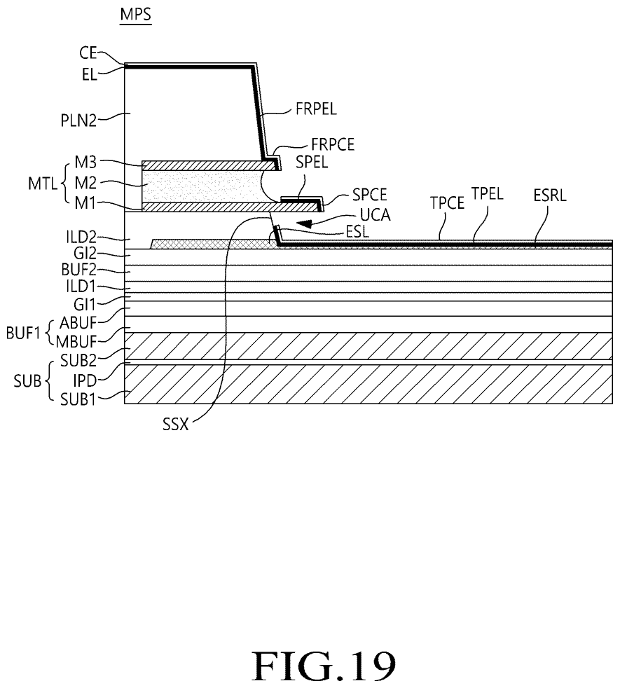

The fourth portion FRPCE of the cathode electrode CE may be positioned on the metal layer MTL. For example, the fourth portion FRPCE of the cathode electrode CE may be positioned on the fourth portion FRPEL of the light emitting layer EL. Both the fourth portion FRPCE of the cathode electrode CE and the fourth portion FRPEL of the light emitting layer EL may be spaced apart from the second layer M2 of the metal layer MTL. Both the fourth portion FRPCE of the cathode electrode CE and the second portion SPCE of the cathode electrode CE may be positioned on the first layer M1 of the metal layer MTL. Further, the fourth portion FRPCE of the cathode electrode CE may be in direct contact with the fourth portion FRPEL of the light emitting layer EL, and the second portion SPCE of the cathode electrode CE may be in direct contact with the second portion SPEL of the light emitting layer EL. Such a configuration is also illustrated in FIGS. 19 to 23, and the same configuration is not repeatedly described.

FIG. 19 is an exemplary cross-sectional view of the moisture-preventing structure MPS illustrated in FIGS. 15 to 17. Hereinafter, in describing the embodiments illustrated in FIG. 19, what is not particularly described otherwise may be the same as those described above with reference to FIGS. 1 to 18.

Referring to FIG. 19, the moisture-preventing structure MPS may include a plurality of insulation films, an undercut area UCA, a metal layer MTL, and an etch stop layer ESL. The plurality of insulation films, the undercut area UCA, and the metal layer MTL illustrated in FIG. 19 may have the same configuration as the plurality of insulation films, the undercut area UCA, and the metal layer MTL illustrated in FIG. 18, and thus are not described repeatedly.

Referring to FIG. 19, the etch stop layer ESL may be disposed between the second gate insulation film GI2 and the second interlayer insulation film ILD2 disposed under the metal layer MTL. The etch stop layer ESL is disposed to extend further in a first direction (e.g., a lateral direction) than some of the insulation films forming the undercut area UCA, but the extended portion may have a relatively small thickness. In other words, in the portion further extending than some of the insulation films, an upper portion of the etch stop layer ESL may be etched in the etching process to form an etch stop residual film ESRL. The etch stop layer ESL may include the same material as the second gate electrode GAT2. For example, the etch stop layer ESL may be formed of a Mo/Ti double layer or a Mo single layer, and the etch stop residual film ESRL may be a Ti residual film of the Mo/Ti double layer or a Mo residual film of the Mo single layer.

The third portion TPEL of the light emitting layer EL may be disposed at a position adjacent to the undercut area UCA. For example, the third portion TPEL of the light emitting layer EL may cover the side surface SSX of the insulation film including the second interlayer insulation film ILD2, while covering the side surface of the etch stop layer ESL and the upper surface of the etch stop residual film ESRL. The third portion TPEL of the light emitting layer EL may be spaced apart from the second portion SPEL of the light emitting layer EL, and the third portion TPEL of the light emitting layer EL and the second portion SPEL of the light emitting layer EL may overlap each other on a plane. That is, the third portion TPEL of the light emitting layer EL and the second portion SPEL of the light emitting layer EL may overlap each other from a plan view.

The third portion TPCE of the cathode electrode CE may be disposed at a position adjacent to the undercut area UCA. For example, the third portion TPCE of the cathode electrode CE may be positioned on the third portion TPEL of the light emitting layer EL. While the third portion TPCE of the cathode electrode CE is spaced apart from the second portion SPCE of the cathode electrode CE, the third portion TPCE of the cathode electrode CE and the second portion SPCE of the cathode electrode CE may overlap each other on a plane. That is, the third portion TPCE of the cathode electrode CE and the second portion SPCE of the cathode electrode CE may overlap each other from a plan view.

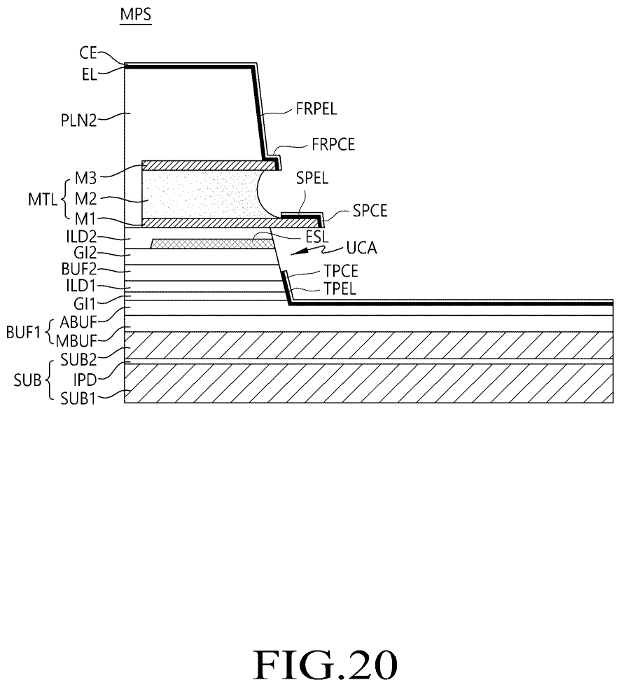

FIG. 20 is an exemplary cross-sectional view of the moisture-preventing structure MPS illustrated in FIGS. 15 to 17. Hereinafter, in describing the embodiments illustrated in FIG. 20, what is not particularly described otherwise may be the same as those described above with reference to FIGS. 1 to 19.

Referring to FIG. 20, the moisture-preventing structure MPS may include a plurality of insulation films, an undercut area UCA, a metal layer MTL, and an etch stop layer ESL. The plurality of insulation films and the metal layer MTL illustrated in FIG. 20 may have the same configuration as the plurality of insulation films and the metal layer MTL illustrated in FIG. 18, and thus are not repeatedly described.

Referring to FIG. 20, the undercut area UCA may be formed in an area including insulation films including an active buffer layer ABUF to a second interlayer insulation film ILD2 and an etch stop layer ESL. For example, the etch stop layer ESL may be disposed between the second gate insulation film GI2 and the second interlayer insulation film ILD2 positioned under the metal layer MTL. The etch stop layer ESL may include the same material as the second gate electrode GAT2. For example, the etch stop layer ESL may be formed of a Mo/Ti double layer or a Mo single layer. The light emitting layer EL may be disconnected at the undercut area UCA. Unlike the etch stop layer ESL illustrated in FIG. 18 or 19, the etch stop layer ESL may not extend in a first direction (e.g., a lateral direction) and may be disposed between the insulation films. In other words, in the etching process, the etch stop layer ESL may be over-etched to be etched and removed together with insulation films disposed under the etch stop layer ESL.

Referring to FIG. 20, the third portion TPEL of the light emitting layer EL may be disposed at a position adjacent to the undercut area UCA. For example, the third portion TPEL of the light emitting layer EL may cover side surfaces of insulation films including the second buffer layer BUF2, the first interlayer insulation film ILD1, the first gate insulation film GI1, and the first buffer layer BUF1. The third portion TPEL of the light emitting layer EL may be spaced apart from the second portion SPEL of the light emitting layer EL, and the third portion TPEL of the light emitting layer EL and the second portion SPEL of the light emitting layer EL may overlap each other on a plane.

The third portion TPCE of the cathode electrode CE may be disposed at a position adjacent to the undercut area UCA. For example, the third portion TPCE of the cathode electrode CE may be positioned on the third portion TPEL of the light emitting layer EL. While the third portion TPCE of the cathode electrode CE is spaced apart from the second portion SPCE of the cathode electrode CE, the third portion TPCE of the cathode electrode CE and the second portion SPCE of the cathode electrode CE may overlap each other on a plane.

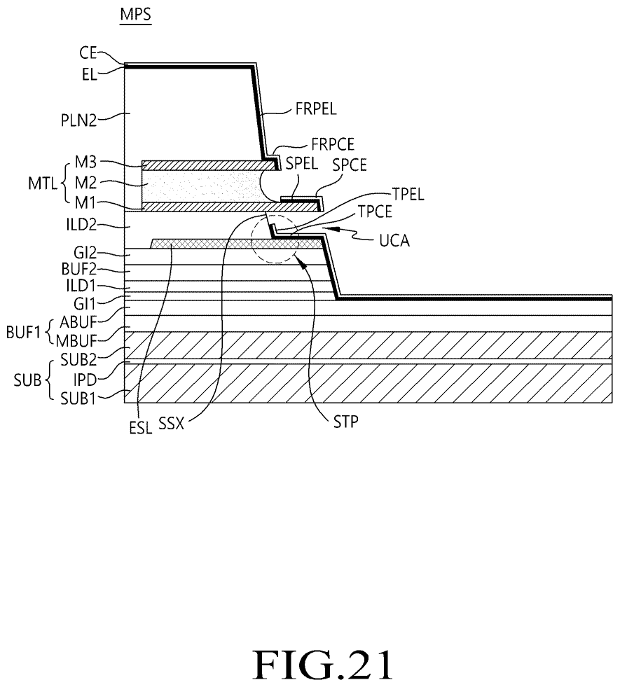

FIG. 21 is an exemplary cross-sectional view of the moisture-preventing structure MPS illustrated in FIGS. 15 to 17. Hereinafter, in describing the embodiments illustrated in FIG. 21, what is not particularly described otherwise may be the same as those described above with reference to FIGS. 1 to 20.

Referring to FIG. 21, the moisture-preventing structure MPS may include an undercut area UCA of at least one of the plurality of insulation films. In the embodiments illustrated in FIG. 21, the undercut area UCA may be formed on the second gate insulation film GI2 to the second interlayer insulation film ILD2. The light emitting layer EL may be disconnected at the undercut area UCA. The plurality of insulation films illustrated in FIG. 21 may have the same configuration as the plurality of insulation films illustrated in FIG. 18, and thus are not repeatedly described.

The moisture-preventing structure MPS illustrated in FIG. 21 may be different from the moisture-preventing structure MPS illustrated in FIG. 18 in terms of the shape of the undercut area UCA. In the moisture-preventing structure MPS illustrated in FIG. 21, the undercut area UCA may include a step portion STP.

The step portion STP may mean a step formed as some insulation films and the etch stop layer ESL are not etched inward of the lower portion of the metal layer MTL in the undercut area UCA. For example, when the second interlayer insulation film ILD2 is etched inward of the lower portion of the metal layer MTL, and an insulation film such as the second gate insulation film GI2, the second buffer layer BUF2, the first interlayer insulation film ILD1, and the first gate insulation film GI1, and the etch stop layer ESL are not etched inward of the lower portion of the metal layer MTL, the step portion STP may include the etch stop layer ESL, the second gate insulation film GI2, the second buffer layer BUF2, the first interlayer insulation film ILD1, and the first gate insulation film GI1.

The etch stop layer ESL may include the same material as the second gate electrode GAT2. For example, the etch stop layer ESL may be formed of a Mo/Ti double layer or a Mo single layer.

Referring to FIG. 21, the third portion TPEL of the light emitting layer EL is disposed on the step portion STP, and may cover a side surface SSX of the second interlayer insulation film ILD2, an upper surface and a side surface of the etch stop layer ESL, and may cover side surfaces of the second gate insulation film GI2, the second buffer layer BUF2, and the first interlayer insulation film ILD1. The third portion TPEL of the light emitting layer EL may be spaced apart from the second portion SPEL of the light emitting layer EL, and the third portion TPEL of the light emitting layer EL and the second portion SPEL of the light emitting layer EL may overlap each other on a plane.

The third portion TPCE of the cathode electrode CE may be positioned on the third portion TPEL of the light emitting layer EL. While the third portion TPCE of the cathode electrode CE is spaced apart from the second portion SPCE of the cathode electrode CE, the third portion TPCE of the cathode electrode CE and the second portion SPCE of the cathode electrode CE may overlap each other on a plane.

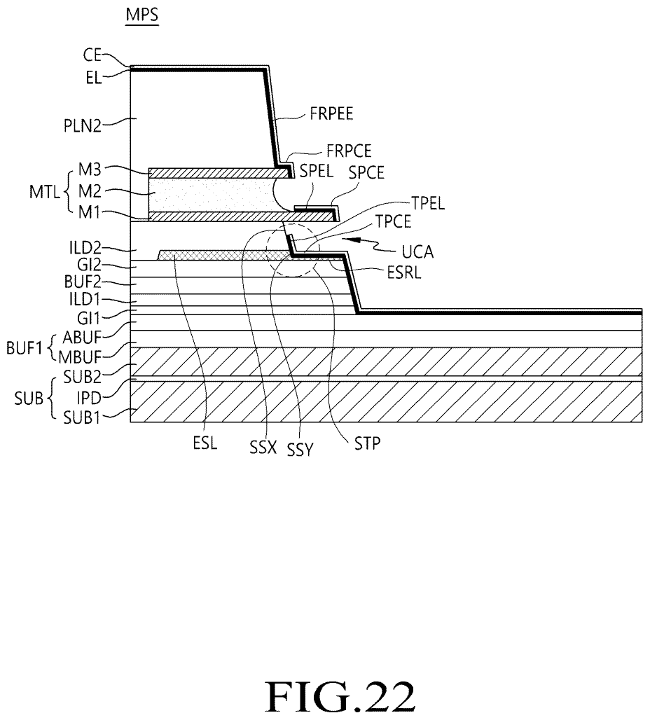

FIG. 22 is an exemplary cross-sectional view of the moisture-preventing structure MPS illustrated in FIGS. 15 to 17. Hereinafter, in describing the embodiments illustrated in FIG. 22, what is not particularly described otherwise may be the same as those described above with reference to FIGS. 1 to 21.

Referring to FIG. 22, the moisture-preventing structure MPS may include a plurality of insulation films, an undercut area UCA, a metal layer MTL, a step portion STP, and an etch stop layer ESL. The plurality of insulation films, the undercut area UCA, and the metal layer MTL illustrated in FIG. 22 may have the same configuration as the plurality of insulation films, the undercut area UCA, and the metal layer MTL illustrated in FIG. 21, and thus are not described repeatedly.

Referring to FIG. 22, the etch stop layer ESL is disposed to extend further in a first direction (e.g., a lateral direction) than some of the insulation films forming the undercut area UCA on the step portion STP, but the extended part may have a relatively small thickness. In other words, in the portion further extending than some of the insulation films, an upper portion of the etch stop layer ESL may be etched in the etching process to form an etch stop residual film ESRL. The etch stop layer ESL may include the same material as the second gate electrode GAT2. For example, the etch stop layer ESL may be formed of a Mo/Ti double layer or a Mo single layer, and the etch stop residual film ESRL may be a Ti residual film of the Mo/Ti double layer or a Mo residual film of the Mo single layer.

Referring to FIG. 22, the third portion TPEL of the light emitting layer EL may be disposed on the step portion STP to cover side surface SSX of the second interlayer insulation film ILD2 and the side surface SSY of the etch stop layer ESL, and to cover an upper surface and a side surface of the etch stop residual film ESRL. The third portion TPEL of the light emitting layer EL may be spaced apart from the second portion SPEL of the light emitting layer EL, and the third portion TPEL of the light emitting layer EL and the second portion SPEL of the light emitting layer EL may overlap each other on a plane.

The third portion TPCE of the cathode electrode CE may be positioned on the third portion TPEL of the light emitting layer EL. While the third portion TPCE of the cathode electrode CE is spaced apart from the second portion SPCE of the cathode electrode CE, the third portion TPCE of the cathode electrode CE and the second portion SPCE of the cathode electrode CE may overlap each other on a plane.

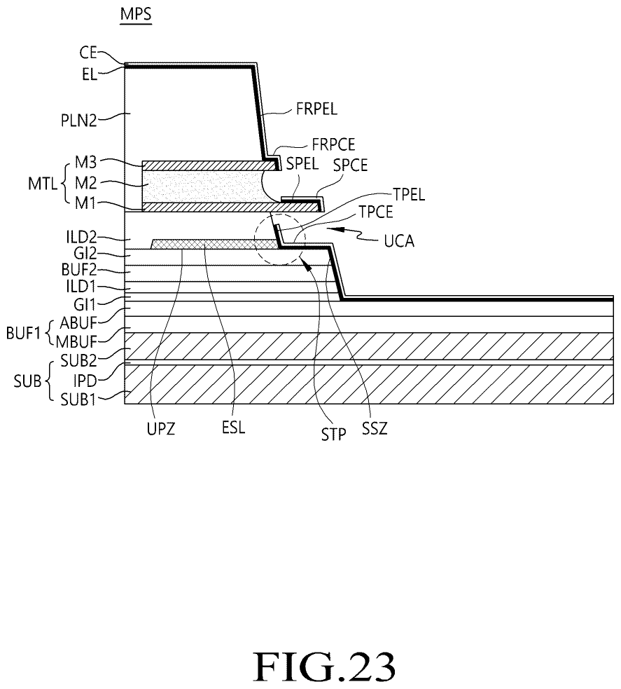

FIG. 23 is an exemplary cross-sectional view of the moisture-preventing structure MPS illustrated in FIGS. 15 to 17. Hereinafter, in describing the embodiments illustrated in FIG. 23, what is not particularly described otherwise may be the same as those described above with reference to FIGS. 1 to 22.

Referring to FIG. 23, the moisture-preventing structure MPS may include a plurality of insulation films, an undercut area UCA, a metal layer MTL, a step portion STP, and an etch stop layer ESL. The plurality of insulation films, the undercut area UCA, and the metal layer MTL illustrated in FIG. 23 may have the same configuration as the plurality of insulation films and the metal layer MTL illustrated in FIG. 21, and thus are not described repeatedly.

Referring to FIG. 23, the undercut area UCA may be formed in an area including the insulation films including the second gate insulation film GI2 and the second interlayer insulation film ILD2 and the etch stop layer ESL. For example, the etch stop layer ESL may be disposed between the second gate insulation film GI2 and the second interlayer insulation film ILD2 positioned under the metal layer MTL. The etch stop layer ESL may include the same material as the second gate electrode GAT2. For example, the etch stop layer ESL may be formed of a Mo/Ti double layer or a Mo single layer. The light emitting layer EL may be disconnected at the undercut area UCA. Unlike the etch stop layer ESL illustrated in FIG. 21 or FIG. 22, the etch stop layer ESL may not extend in a first direction (e.g., a lateral direction) on the step portion STP and may be disposed between the insulation films. In other words, in the etching process, the etch stop layer ESL may be over-etched to be partially etched and removed.

Referring to FIG. 23, the third portion TPEL of the light emitting layer EL may be disposed on the step portion STP to cover side surfaces SSX, SSY of the second interlayer insulation film ILD2 and the etch stop layer ESL, and to cover an upper surface UPZ and a side surface SSZ of the second gate insulation film GI2. The third portion TPEL of the light emitting layer EL may be spaced apart from the second portion SPEL of the light emitting layer EL, and the third portion TPEL of the light emitting layer EL and the second portion SPEL of the light emitting layer EL may overlap each other on a plane.

The third portion TPCE of the cathode electrode CE may be positioned on the third portion TPEL of the light emitting layer EL. While the third portion TPCE of the cathode electrode CE is spaced apart from the second portion SPCE of the cathode electrode CE, the third portion TPCE of the cathode electrode CE and the second portion SPCE of the cathode electrode CE may overlap each other on a plane.

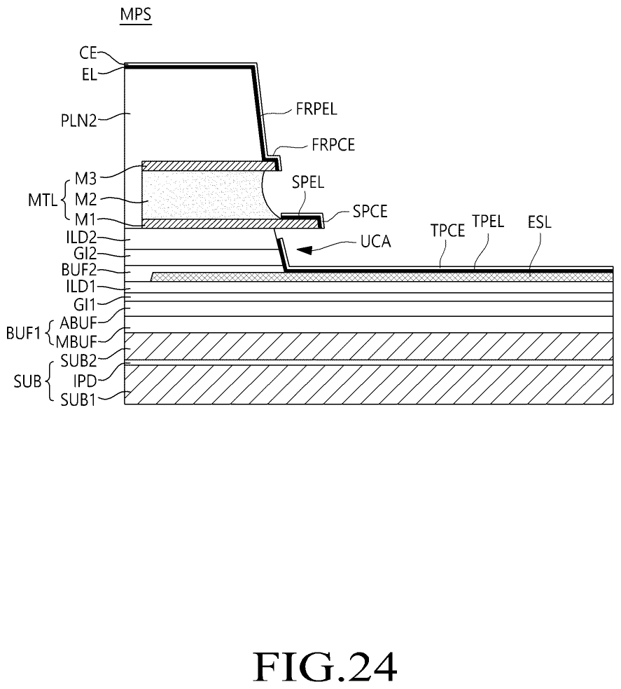

FIG. 24 is an exemplary cross-sectional view of the moisture-preventing structure MPS illustrated in FIGS. 15 to 17. Hereinafter, in describing the embodiments illustrated in FIG. 24, what is not particularly described otherwise may be the same as those described above with reference to FIGS. 1 to 23.

Referring to FIG. 24, the moisture-preventing structure MPS may include an undercut area UCA of at least one of the plurality of insulation films. In the embodiments illustrated in FIG. 24, the undercut area UCA may be formed between the first buffer layer BUF1 and the second interlayer insulation film ILD2. The light emitting layer EL may be disconnected at the undercut area UCA. The plurality of insulation films illustrated in FIG. 24 may have the same configuration as the plurality of insulation films illustrated in FIG. 18, and thus are not repeatedly described.

The moisture-preventing structure MPS may include a metal layer MTL positioned on the undercut area UCA. The metal layer MTL may have, e.g., the same structure as the second source-drain electrode. The light emitting layer EL may be disconnected at a side surface of the metal layer MTL. The metal layer MTL illustrated in FIG. 24 may have the same configuration as the metal layer MTL illustrated in FIG. 18, and thus is not repeatedly described.

The moisture-preventing structure MPS may include an etch stop layer ESL positioned in or under the undercut area UCA. The etch stop layer ESL may also be referred to as an auxiliary metal layer AML. Referring to FIG. 24, the etch stop layer ESL may be disposed between the plurality of insulation films positioned under the metal layer MTL. For example, the etch stop layer ESL may be disposed between the first interlayer insulation film ILD1 and the second buffer layer BUF2 positioned under the metal layer MTL. The etch stop layer ESL may be disposed to further extend in a first direction (e.g., a lateral direction) than some of the insulation films forming the undercut area UCA. For example, the etch stop layer ESL may be disposed on the first interlayer insulation film ILD1 to extend further than a portion of insulation films such as the second buffer layer BUF2, the second gate insulation film GI2, and the second interlayer insulation film ILD2.

The etch stop layer ESL may include a metallic material. For example, the etch stop layer ESL may include a single layer or multiple layers of any one of molybdenum (Mo), copper (Cu), titanium (Ti), aluminum (Al), chromium (Cr), gold (Au), nickel (Ni), neodymium (Nd), and tungsten (W), or an alloy thereof, but is not limited thereto. For example, the etch stop layer ESL may include the same material as the metal pattern TM. For example, the etch stop layer ESL may be formed of a Mo/Ti double layer or a Mo single layer.

The etch stop layer ESL may prevent some insulation films, disposed thereunder, from being over-etched in the etching process of patterning the plurality of insulation films or patterning the metallic metal such as the anode electrode AE or the metal layer MTL in the process of forming the moisture-preventing structure MPS. For example, in the embodiments illustrated in FIG. 24, the undercut area UCA may be formed in a structure in which a portion of the second buffer layer BUF2, the second gate insulation film GI2, and the second interlayer insulation film ILD2 disposed on the etch stop layer ESL is etched, but the etch stop layer ESL is not etched.

Referring to FIG. 24, the light emitting layer EL may have several portions. As described above, the light emitting layer EL may include a first portion FPEL, a second portion SPEL, and a third portion TPEL. The light emitting layer EL may further include a fourth portion FRPEL. As shown, the first portion FPEL, the second portion SPEL, the third portion TPEL, and the fourth portion FRPEL of the light emitting layer EL may be spaced apart from each other. The first portion FPEL, the second portion SPEL, the third portion TPEL, and the fourth portion FRPEL of the light emitting layer EL may be separated from each other.

Here, the second portion SPEL of the light emitting layer EL may be positioned on the first layer M1 of the metal layer MTL. The first layer M1 of the metal layer MTL may further extend in a first direction (e.g., a lateral direction) than some of the insulation films to form the undercut area UCA. For example, the first layer M1 of the metal layer MTL may extend further than a portion of the insulation films such as the second buffer layer BUF2, the second gate insulation film GI2, and the second interlayer insulation film ILD2 to form the undercut area UCA.

The third portion TPEL of the light emitting layer EL may be disposed at a position adjacent to the undercut area UCA. For example, the third portion TPEL of the light emitting layer EL may cover the upper surface of the etch stop layer ESL while covering the side surface of the insulation film including the second interlayer insulation film ILD2, the second gate insulation film GI2, and the second buffer layer BUF2. The third portion TPEL of the light emitting layer EL may be spaced apart from the second portion SPEL of the light emitting layer EL, and the third portion TPEL of the light emitting layer EL and the second portion SPEL of the light emitting layer EL may overlap each other on a plane.

The fourth portion FRPEL of the light emitting layer EL may be positioned on the metal layer MTL. The third layer M3 of the metal layer MTL may further extend in a first direction (e.g., a lateral direction) than a portion of the second layer M2 of the metal layer MTL. For example, the fourth portion FRPEL of the light emitting layer EL may be positioned on an extended portion of the third layer M3 of the metal layer MTL. Both the fourth portion FRPEL of the light emitting layer EL and the second portion SPEL of the light emitting layer EL may be positioned on the first layer M1 of the metal layer MTL, but the fourth portion FRPEL of the light emitting layer EL is directly positioned on the third layer M3 of the metal layer MTL, and the second portion SPEL of the light emitting layer EL is directly positioned on the first layer M1 of the metal layer MTL.

Further, the cathode electrode CE may have several portions. As described above, the cathode electrode CE may include a first portion FPCE, a second portion SPCE, and a third portion TPCE. The cathode electrode CE may further include a fourth portion FRPCE. As shown, the first portion FPCE, the second portion SPCE, the third portion TPCE, and the fourth portion FRPCE of the cathode electrode CE may be spaced apart from each other. Further, it may be said that the first portion FPCE, the second portion SPCE, the third portion TPCE, and the fourth portion FRPCE of the cathode electrode CE are separated from each other.

Here, the second portion SPCE of the cathode electrode CE may be positioned on the first layer M1 of the metal layer MTL. For example, the second portion SPCE of the cathode electrode CE may be positioned on the second portion SPEL of the light emitting layer EL.

The third portion TPCE of the cathode electrode CE may be disposed at a position adjacent to the undercut area UCA. For example, the third portion TPCE of the cathode electrode CE may be positioned on the third portion TPEL of the light emitting layer EL. While the third portion TPCE of the cathode electrode CE is spaced apart from the second portion SPCE of the cathode electrode CE, the third portion TPCE of the cathode electrode CE and the second portion SPCE of the cathode electrode CE may overlap each other on a plane.

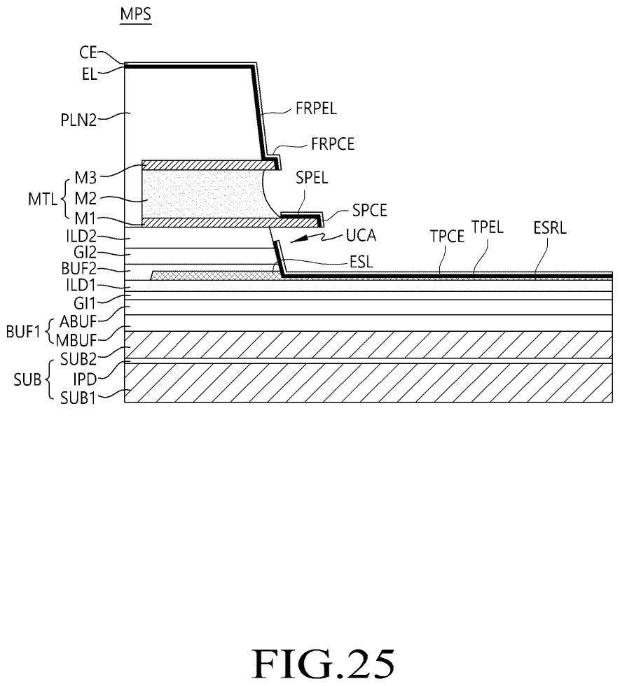

The fourth portion FRPCE of the cathode electrode CE may be positioned on the metal layer MTL. For example, the fourth portion FRPCE of the cathode electrode CE may be positioned on the fourth portion FRPEL of the light emitting layer EL. Both the fourth portion FRPCE of the cathode electrode CE and the fourth portion FRPEL of the light emitting layer EL may be spaced apart from the second layer M2 of the metal layer MTL. Both the fourth portion FRPCE of the cathode electrode CE and the second portion SPCE of the cathode electrode CE may be positioned on the first layer M1 of the metal layer MTL. Further, the fourth portion FRPCE of the cathode electrode CE may be in direct contact with the fourth portion FRPEL of the light emitting layer EL, and the second portion SPCE of the cathode electrode CE may be in direct contact with the second portion SPEL of the light emitting layer EL. Such a configuration is also illustrated in FIGS. 25 to 29, and the same configuration is not repeatedly described.

FIG. 25 is an exemplary cross-sectional view of the moisture-preventing structure MPS illustrated in FIGS. 15 to 17. Hereinafter, in describing the embodiments illustrated in FIG. 25, what is not particularly described otherwise may be the same as those described above with reference to FIGS. 1 to 24.

Referring to FIG. 25, the moisture-preventing structure MPS may include a plurality of insulation films, an undercut area UCA, a metal layer MTL, and an etch stop layer ESL. The plurality of insulation films, the undercut area UCA, and the metal layer MTL illustrated in FIG. 25 may have the same configuration as the plurality of insulation films, the undercut area UCA, and the metal layer MTL illustrated in FIG. 24, and thus are not described repeatedly.

Referring to FIG. 25, the etch stop layer ESL may be disposed between the first interlayer insulation film ILD1 and the second buffer layer BUF2 positioned under the metal layer MTL. The etch stop layer ESL is disposed to extend further in a first direction (e.g., a lateral direction) than some of the insulation films forming the undercut area UCA, but the extended portion may have a relatively small thickness. In other words, in the portion further extending than some of the insulation films, an upper portion of the etch stop layer ESL may be etched in the etching process to form an etch stop residual film ESRL. The etch stop layer ESL may include the same material as the metal pattern TM. For example, the etch stop layer ESL may be formed of a Mo/Ti double layer or a Mo single layer, and the etch stop residual film ESRL may be a Ti residual film of the Mo/Ti double layer or a Mo residual film of the Mo single layer.

The third portion TPEL of the light emitting layer EL may be disposed at a position adjacent to the undercut area UCA. For example, the third portion TPEL of the light emitting layer EL may cover the side surface of the etch stop layer ESL and the upper surface of the etch stop residual film ESRL while covering the side surface of the insulation film including the second interlayer insulation film ILD2, the second gate insulation film GI2, and the second buffer layer BUF2. The third portion TPEL of the light emitting layer EL may be spaced apart from the second portion SPEL of the light emitting layer EL, and the third portion TPEL of the light emitting layer EL and the second portion SPEL of the light emitting layer EL may overlap each other on a plane.

The third portion TPCE of the cathode electrode CE may be disposed at a position adjacent to the undercut area UCA. For example, the third portion TPCE of the cathode electrode CE may be positioned on the third portion TPEL of the light emitting layer EL. While the third portion TPCE of the cathode electrode CE is spaced apart from the second portion SPCE of the cathode electrode CE, the third portion TPCE of the cathode electrode CE and the second portion SPCE of the cathode electrode CE may overlap each other on a plane.

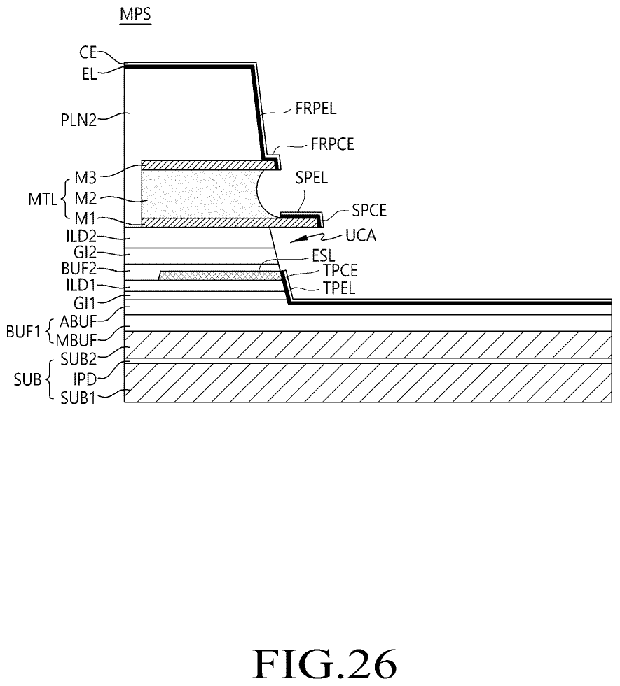

FIG. 26 is an exemplary cross-sectional view of the moisture-preventing structure MPS illustrated in FIGS. 15 to 17. Hereinafter, in describing the embodiments illustrated in FIG. 26, what is not particularly described otherwise may be the same as those described above with reference to FIGS. 1 to 25.

Referring to FIG. 26, the moisture-preventing structure MPS may include a plurality of insulation films, an undercut area UCA, a metal layer MTL, and an etch stop layer ESL. The plurality of insulation films and the metal layer MTL illustrated in FIG. 26 may have the same configuration as the plurality of insulation films and the metal layer MTL illustrated in FIG. 24, and thus are not repeatedly described.

Referring to FIG. 26, the undercut area UCA may be formed in an area including insulation films including an active buffer layer ABUF to a second interlayer insulation film ILD2 and an etch stop layer ESL. For example, the etch stop layer ESL may be disposed between the first interlayer insulation film ILD1 and the second buffer layer BUF2 positioned under the metal layer MTL. The etch stop layer ESL may include the same material as the metal pattern TM. For example, the etch stop layer ESL may be formed of a Mo/Ti double layer or a Mo single layer. The light emitting layer EL may be disconnected at the undercut area UCA. Unlike the etch stop layer ESL illustrated in FIG. 24 or 25, the etch stop layer ESL may not extend in a first direction (e.g., a lateral direction) and may be disposed between the insulation films. In other words, in the etching process, the etch stop layer ESL may be over-etched to be etched and removed together with insulation films disposed under the etch stop layer ESL.

Referring to FIG. 26, the third portion TPEL of the light emitting layer EL may be disposed at a position adjacent to the undercut area UCA. For example, the third portion TPEL of the light emitting layer EL may cover the side surface of the second buffer layer BUF2 and the side surface of the etch stop layer ESL and may cover the side surfaces of the insulation films including the first interlayer insulation film ILD1, the first gate insulation film GI1, and the first buffer layer BUF1 and the upper surface of the first buffer layer BUF1. The third portion TPEL of the light emitting layer EL may be spaced apart from the second portion SPEL of the light emitting layer EL, and the third portion TPEL of the light emitting layer EL and the second portion SPEL of the light emitting layer EL may overlap each other on a plane.

The third portion TPCE of the cathode electrode CE may be disposed at a position adjacent to the undercut area UCA. For example, the third portion TPCE of the cathode electrode CE may be positioned on the third portion TPEL of the light emitting layer EL. While the third portion TPCE of the cathode electrode CE is spaced apart from the second portion SPCE of the cathode electrode CE, the third portion TPCE of the cathode electrode CE and the second portion SPCE of the cathode electrode CE may overlap each other on a plane.

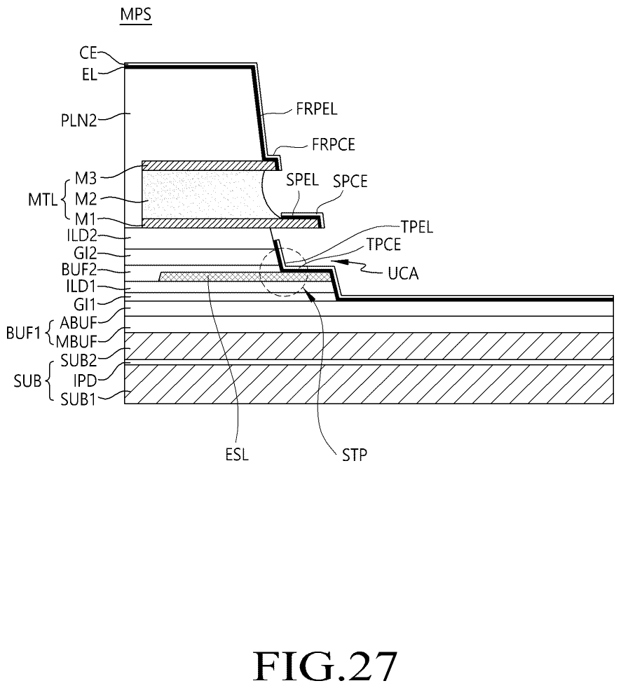

FIG. 27 is an exemplary cross-sectional view of the moisture-preventing structure MPS illustrated in FIGS. 15 to 17. Hereinafter, in describing the embodiments illustrated in FIG. 27, what is not particularly described otherwise may be the same as those described above with reference to FIGS. 1 to 26.

Referring to FIG. 27, the moisture-preventing structure MPS may include an undercut area UCA of at least one of the plurality of insulation films. In the embodiments illustrated in FIG. 27, the undercut area UCA may be formed on the first interlayer insulation film ILD1 to the second interlayer insulation film ILD2. The light emitting layer EL may be disconnected at the undercut area UCA. The plurality of insulation films illustrated in FIG. 27 may have the same configuration as the plurality of insulation films illustrated in FIG. 24, and thus are not repeatedly described.

The moisture-preventing structure MPS illustrated in FIG. 27 may be different from the moisture-preventing structure MPS illustrated in FIG. 24 in terms of the shape of the undercut area UCA. In the moisture-preventing structure MPS illustrated in FIG. 27, the undercut area UCA may include a step portion STP.

The step portion STP may mean a step formed as some insulation films and the etch stop layer ESL are not etched inward of the lower portion of the metal layer MTL in the undercut area UCA. For example, when the second interlayer insulation film ILD2, the second gate insulation film GI2, and the second buffer layer BUF2 are etched inward of the lower portion of the metal layer MTL, and an insulation film such as the first interlayer insulation film ILD1 and the first gate insulation film GI1, and the etch stop layer ESL are not etched inward of the lower portion of the metal layer MTL, the step portion STP may include the etch stop layer ESL, the first interlayer insulation film ILD1, and the first gate insulation film GI1.

The etch stop layer ESL may include the same material as the metal pattern TM. For example, the etch stop layer ESL may be formed of a Mo/Ti double layer or a Mo single layer.

Referring to FIG. 27, the third portion TPEL of the light emitting layer EL may be disposed on the step portion STP to cover side surfaces of the second interlayer insulation film ILD2, the second gate insulation film GI2, and the second buffer layer BUF2 and to cover an upper surface and a side surface of the etch stop layer ESL. The third portion TPEL of the light emitting layer EL may be spaced apart from the second portion SPEL of the light emitting layer EL, and the third portion TPEL of the light emitting layer EL and the second portion SPEL of the light emitting layer EL may overlap each other on a plane.

The third portion TPCE of the cathode electrode CE may be positioned on the third portion TPEL of the light emitting layer EL. While the third portion TPCE of the cathode electrode CE is spaced apart from the second portion SPCE of the cathode electrode CE, the third portion TPCE of the cathode electrode CE and the second portion SPCE of the cathode electrode CE may overlap each other on a plane.

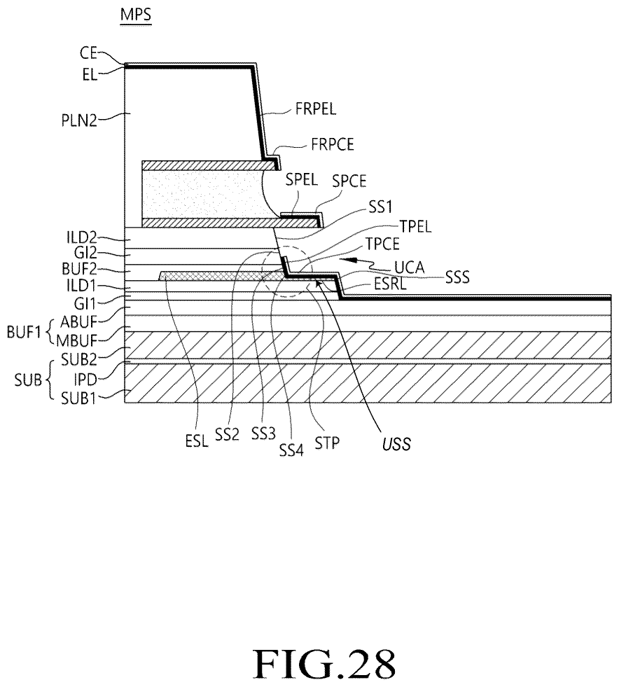

FIG. 28 is an exemplary cross-sectional view of the moisture-preventing structure MPS illustrated in FIGS. 15 to 17. Hereinafter, in describing the embodiments illustrated in FIG. 28, what is not particularly described otherwise may be the same as those described above with reference to FIGS. 1 to 27.

Referring to FIG. 28, the moisture-preventing structure MPS may include a plurality of insulation films, an undercut area UCA, a metal layer MTL, a step portion STP, and an etch stop layer ESL. The plurality of insulation films, the undercut area UCA, and the metal layer MTL illustrated in FIG. 28 may have the same configuration as the plurality of insulation films, the undercut area UCA, and the metal layer MTL illustrated in FIG. 24, and thus are not described repeatedly.

Referring to FIG. 28, the etch stop layer ESL is disposed to extend further in a first direction (e.g., a lateral direction) than some of the insulation films forming the undercut area UCA on the step portion STP, but the extended part may have a relatively small thickness. In other words, in the portion further extending than some of the insulation films, an upper portion of the etch stop layer ESL may be etched in the etching process to form an etch stop residual film ESRL. The etch stop layer ESL may include the same material as the metal pattern TM. For example, the etch stop layer ESL may be formed of a Mo/Ti double layer or a Mo single layer, and the etch stop residual film ESRL may be a Ti residual film of the Mo/Ti double layer or a Mo residual film of the Mo single layer.

Referring to FIG. 28, the third portion TPEL of the light emitting layer EL may be disposed on the step portion STP to cover the side surface SS1 of the second interlayer insulation film ILD2, the side surface SS2 of the second gate insulation film GI2, the side surface SS3 of the second buffer layer BUF2, and the side surface SS4 of the etch stop layer ESL, and to cover an upper surface USS and a side surface SSS of the etch stop residual film ESRL. The third portion TPEL of the light emitting layer EL may be spaced apart from the second portion SPEL of the light emitting layer EL, and the third portion TPEL of the light emitting layer EL and the second portion SPEL of the light emitting layer EL may overlap each other on a plane.

While FIG. 28 does not explicitly show the third portion TPEL of the light emitting layer EL disposed on the step portion STP covering the side surface SS1 of the second interlayer insulation film ILD2, in other embodiments, the third portion TPEL of the light emitting layer EL may cover the side surface SS1 of the second interlayer insulation film ILD2.

The third portion TPCE of the cathode electrode CE may be positioned on the third portion TPEL of the light emitting layer EL. While the third portion TPCE of the cathode electrode CE is spaced apart from the second portion SPCE of the cathode electrode CE, the third portion TPCE of the cathode electrode CE and the second portion SPCE of the cathode electrode CE may overlap each other on a plane.

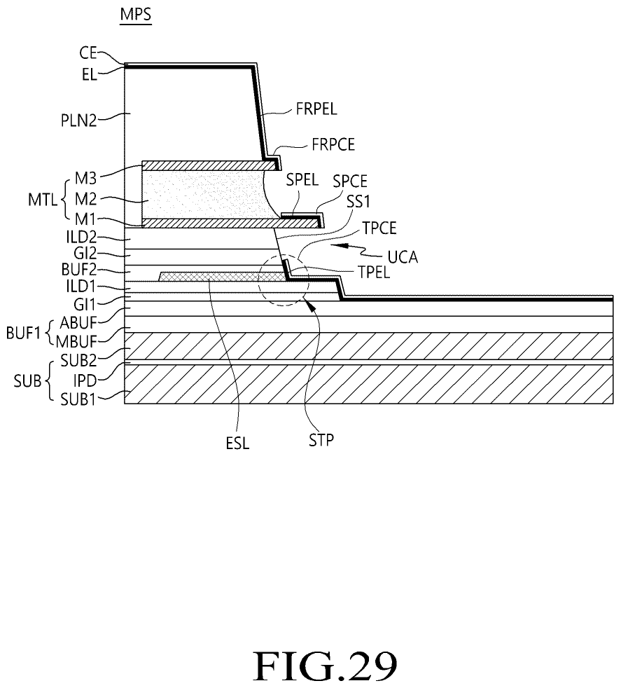

FIG. 29 is an exemplary cross-sectional view of the moisture-preventing structure MPS illustrated in FIGS. 15 to 17. Hereinafter, in describing the embodiments illustrated in FIG. 29, what is not particularly described otherwise may be the same as those described above with reference to FIGS. 1 to 28.

Referring to FIG. 29, the moisture-preventing structure MPS may include a plurality of insulation films, an undercut area UCA, a metal layer MTL, a step portion STP, and an etch stop layer ESL. The plurality of insulation films, the undercut area UCA, and the metal layer MTL illustrated in FIG. 29 may have the same configuration as the plurality of insulation films and the metal layer MTL illustrated in FIG. 24, and thus are not described repeatedly.

Referring to FIG. 29, the undercut area UCA may be formed in an area including the insulation films including the second interlayer insulation film ILD2, the second gate insulation film GI2, and the second buffer layer BUF2, and the etch stop layer ESL. For example, the etch stop layer ESL may be disposed between the first interlayer insulation film ILD1 and the second buffer layer BUF2 positioned under the metal layer MTL. The etch stop layer ESL may include the same material as the metal pattern TM. For example, the etch stop layer ESL may be formed of a Mo/Ti double layer or a Mo single layer. The light emitting layer EL may be disconnected at the undercut area UCA. Unlike the etch stop layer ESL illustrated in FIG. 27 or FIG. 28, the etch stop layer ESL may not extend in a first direction (e.g., a lateral direction) on the step portion STP and may be disposed between the insulation films. In other words, in the etching process, the etch stop layer ESL may be over-etched to be partially etched and removed.

Referring to FIG. 29, the third portion TPEL of the light emitting layer EL may be disposed on the step portion STP to cover side surfaces of the second interlayer insulation film ILD2, the second gate insulation film GI2, the second buffer layer BUF2, and the etch stop layer ESL, and to cover an upper surface and a side surface of the first interlayer insulation film ILD1. The third portion TPEL of the light emitting layer EL may be spaced apart from the second portion SPEL of the light emitting layer EL, and the third portion TPEL of the light emitting layer EL and the second portion SPEL of the light emitting layer EL may overlap each other on a plane.

While FIG. 29 does not explicitly show the third portion TPEL of the light emitting layer EL disposed on the step portion STP covering the side surface SS1 of the second interlayer insulation film ILD2, in other embodiments, the third portion TPEL of the light emitting layer EL may cover the side surface SS1 of the second interlayer insulation film ILD2.

The third portion TPCE of the cathode electrode CE may be positioned on the third portion TPEL of the light emitting layer EL. While the third portion TPCE of the cathode electrode CE is spaced apart from the second portion SPCE of the cathode electrode CE, the third portion TPCE of the cathode electrode CE and the second portion SPCE of the cathode electrode CE may overlap each other on a plane.

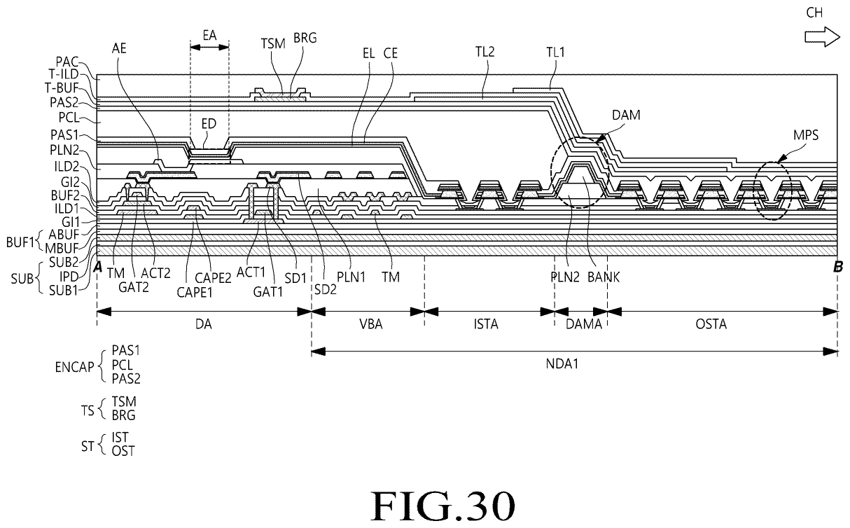

FIG. 30 is an exemplary cross-sectional view of a display device 100 according to embodiments of the disclosure. Hereinafter, in describing the embodiments illustrated in FIG. 30, what is not particularly described otherwise may be the same as those described above with reference to FIGS. 1 to 29.

The display device according to the embodiments illustrated in FIG. 30 is different from the display device illustrated in FIGS. 15 to 17 in that the disconnected portion is not positioned in the outer disconnected portion area OSTA and the inner disconnected portion area ISTA, and the moisture-preventing structure MPS is entirely positioned. Further, the structure of the moisture-preventing structure MPS is also different from the display device illustrated in FIGS. 15 to 17.

Referring to FIG. 30, the display device 100 may include a moisture-preventing structure MPS. The moisture-preventing structure MPS may be disposed in the outer disconnected portion area OSTA and the inner disconnected portion area ISTA. For example, the moisture-preventing structure MPS may be disposed between the display area DA and the dam structure DAM while being disposed between the camera hole CH and the dam structure DAM on a plane.

The moisture-preventing structure MPS may include at least one undercut area UCA among a plurality of insulation films. The moisture-preventing structure MPS may include an undercut area positioned in the insulation film positioned under the plurality of light emitting elements ED. The display device 100 illustrated in FIG. 30 may have the same configuration as that of the display device 100 illustrated in FIG. 13 except that the auxiliary metal layer AML is disposed between the insulation films in which the moisture-preventing structure MPS is positioned in the undercut area UCA.

Referring to FIG. 30, the moisture-preventing structure MPS may include an auxiliary metal layer AML in or under the undercut area UCA. The auxiliary metal layer AML may serve as an etch stop layer ESL in a process of etching metal layers when forming the moisture-preventing structure MPS. In the description of the disclosure, the auxiliary metal layer AML and the etch stop layer ESL may have the same meaning.

The auxiliary metal layer AML may include a metallic material. For example, the auxiliary metal layer AML may include a single layer or multiple layers of any one of molybdenum (Mo), copper (Cu), titanium (Ti), aluminum (Al), chromium (Cr), gold (Au), nickel (Ni), neodymium (Nd), and tungsten (W), or an alloy thereof, but is not limited thereto. The auxiliary metal layer AML may include the same material as the first gate electrode GAT1, the second gate electrode GAT2, or the metal pattern TM. For example, the auxiliary metal layer AML may be formed of a Mo/Ti double layer or a single layer of Mo.

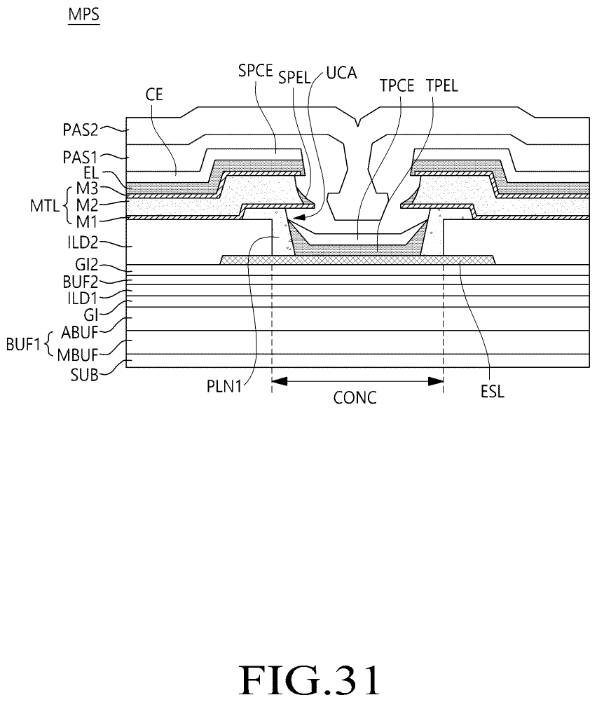

FIG. 31 is an exemplary cross-sectional view of the moisture-preventing structure MPS illustrated in FIG. 30. Hereinafter, in describing the embodiments illustrated in FIG. 31, what is not particularly described otherwise may be the same as those described above with reference to FIGS. 1 to 30.

Referring to FIG. 31, the moisture-preventing structure MPS may include an undercut area UCA. The undercut area UCA may be positioned in an organic insulation film disposed on the substrate SUB and positioned under a plurality of light emitting elements. That the undercut area UCA is positioned in the organic insulation film may mean that at least one organic insulation film is etched to form the undercut area UCA. The organic insulation film in which the undercut area UCA is formed may be, e.g., at least one of the first planarization layer PLN1 and the second planarization layer PLN2. Although FIG. 31 shows embodiments in which the moisture-preventing structure MPS includes the first planarization layer PLN1 and the undercut area UCA is formed in the first planarization layer PLN1, embodiments of the disclosure are not limited to these embodiments. For example, embodiments of the disclosure may include embodiments in which the moisture-preventing structure MPS includes one or more of the first planarization layer PLN1 and the second planarization layer PLN2, and the undercut area UCA is formed in one or more of the first planarization layer PLN1 and the second planarization layer PLN2.

The moisture-preventing structure MPS may include a concave portion CONC of at least one of the plurality of insulation films. For example, the concave portion CONC may be positioned in an inorganic insulation film disposed on the substrate SUB and positioned under a plurality of light emitting elements. That the concave portion CONC is positioned in the inorganic insulation film may mean that one or more of the inorganic insulation films are etched to form the concave portion CONC. The inorganic insulation film may be an inorganic insulation film positioned on the substrate SUB and under the light emitting element. For example, the inorganic insulation film may be one or more of the first buffer layer BUF1 and the second interlayer insulation film ILD2 and the insulation films positioned between the two layers. FIG. 31 illustrates an embodiment in which the second interlayer insulation film ILD2 includes a concave portion CONC, but embodiments of this disclosure are not limited to these embodiments.

The undercut area UCA of the organic insulation film may be positioned in the concave portion CONC. A portion of the etch stop layer ESL disposed on the inorganic insulation film may be exposed by the undercut area UCA of the organic insulation film. For example, the etch stop layer ESL may be exposed by the undercut area UCA of the organic insulation film, and the light emitting layer EL may be positioned on the exposed etch stop layer ESL.

The moisture-preventing structure MPS may include a metal layer MTL positioned on the undercut area UCA. The metal layer MTL may have, e.g., the same structure as the second source-drain electrode. The light emitting layer EL may be disconnected at a side surface of the metal layer MTL. The metal layer MTL illustrated in FIG. 31 may have the same configuration as the metal layer MTL illustrated in FIG. 14, and thus is not repeatedly described.

The moisture-preventing structure MPS may include an etch stop layer ESL positioned in or under the undercut area UCA. The etch stop layer ESL may be an auxiliary metal layer AML. Referring to FIG. 31, the etch stop layer ESL may be disposed between the plurality of insulation films positioned under the metal layer MTL. The etch stop layer ESL may be disposed to be seated in the concave portion CONC. For example, the etch stop layer ESL may be disposed to extend to be seated in the concave portion CONC while being partially disposed between the second gate insulation film GI2 and the second interlayer insulation film ILD2 positioned under the metal layer MTL. An organic insulation film may be disposed on a portion of the etch stop layer ESL disposed in the concave portion CONC. For example, the etch stop layer ESL may be exposed by the undercut area UCA of the organic insulation film, and the light emitting layer EL may be positioned on the exposed etch stop layer ESL.

The etch stop layer ESL may include a metallic material. For example, the etch stop layer ESL may include a single layer or multiple layers of any one of molybdenum (Mo), copper (Cu), titanium (Ti), aluminum (Al), chromium (Cr), gold (Au), nickel (Ni), neodymium (Nd), and tungsten (W), or an alloy thereof, but is not limited thereto. The etch stop layer ESL may include the same material as the second gate electrode GAT2. For example, the etch stop layer ESL may be formed of a Mo/Ti double layer or a Mo single layer.

The etch stop layer ESL may prevent some insulation films, disposed thereunder, from being over-etched in the etching process of forming the concave portion CONC by patterning the plurality of insulation films or patterning the metallic metal such as the anode electrode AE or the metal layer MTL in the process of forming the moisture-preventing structure MPS. For example, in the embodiments illustrated in FIG. 31, the undercut area UCA may be formed in a structure in which a portion of the second interlayer insulation film ILD2 disposed on the etch stop layer ESL is etched, but the etch stop layer ESL is not etched.

Referring to FIG. 31, the light emitting layer EL may have several portions. The light emitting layer EL may include a first portion FPEL, a second portion SPEL, and a third portion TPEL. The first portion FPEL of the light emitting layer EL may be positioned to overlap the emission area EA on a plane. As shown, the first portion FPEL, the second portion SPEL, and the third portion TPEL of the light emitting layer EL may be spaced apart from each other. The first portion FPEL, the second portion SPEL, and the third portion TPEL of the light emitting layer EL may be separated from each other.

Here, the second portion SPEL of the light emitting layer EL may be positioned on the first layer M1 of the metal layer MTL. The first layer M1 of the metal layer MTL may further extend in a first direction (e.g., a lateral direction) than some of the insulation films, such as the second interlayer insulation film ILD2, to form the undercut area UCA. For example, the first layer M1 of the metal layer MTL may extend further than a portion of the insulation films such as the second interlayer insulation film ILD2 to form the undercut area UCA.

The third portion TPEL of the light emitting layer EL may be disposed at a position adjacent to the undercut area UCA. For example, the third portion TPEL of the light emitting layer EL may be positioned under the second portion SPEL of the light emitting layer EL. For example, the third portion TPEL of the light emitting layer EL may be seated on the concave portion CONC. The third portion TPEL of the light emitting layer EL may be disposed on the etch stop layer ESL disposed in the concave portion CONC. The third portion TPEL of the light emitting layer EL may be spaced apart from the second portion SPEL of the light emitting layer EL, and the third portion TPEL of the light emitting layer EL and the second portion SPEL of the light emitting layer EL may overlap each other on a plane.

Further, the cathode electrode CE may have several portions. The cathode electrode CE may include a first portion FTCE, a second portion SPCE, and a third portion TPCE. The cathode electrode CE may be positioned so that the first portion FPCE overlaps the emission area EA on a plane. As shown, the first portion FFCE, the second portion SPCE, and the third portion TPCE of the cathode electrode CE may be spaced apart from each other. It may also be said that the first portion FPCE, the second portion SPCE, and the third portion TPCE of the cathode electrode CE are separated from each other.

Here, the second portion SPCE of the cathode electrode CE may be positioned on the first layer M1 of the metal layer MTL. For example, the second portion SPCE of the cathode electrode CE may be positioned on a portion of the light emitting layer EL positioned to be spaced apart from the second portion SPEL of the light emitting layer EL. The second portion SPCE of the cathode electrode CE may also be positioned on the third layer M3 of the metal layer MTL. As illustrated in FIG. 31, the second portion SPCE of the cathode electrode CE may not be in direct contact with the second portion SPEL of the light emitting layer EL.

The third portion TPCE of the cathode electrode CE may be disposed at a position adjacent to the undercut area UCA. For example, the third portion TPCE of the cathode electrode CE may be positioned on the third portion TPEL of the light emitting layer EL. While the third portion TPCE of the cathode electrode CE is spaced apart from the second portion SPCE of the cathode electrode CE, the third portion TPCE of the cathode electrode CE and the second portion SPCE of the cathode electrode CE may overlap each other on a plane.

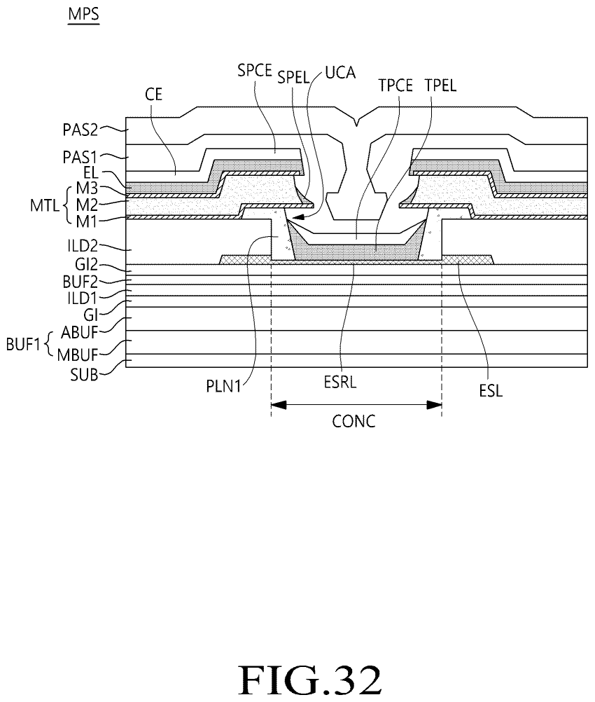

FIG. 32 is an exemplary cross-sectional view of the moisture-preventing structure MPS illustrated in FIG. 30. Hereinafter, in describing the embodiments illustrated in FIG. 32, what is not particularly described otherwise may be the same as those described above with reference to FIGS. 1 to 31.

Referring to FIG. 32, the moisture-preventing structure MPS may include a plurality of insulation films, an undercut area UCA, a metal layer MTL, a concave portion CONC, and an etch stop layer ESL. The plurality of insulation films, the undercut area UCA, the metal layer MTL, and the concave portion CONC illustrated in FIG. 32 may have the same configuration as the plurality of insulation films, the undercut area UCA, the metal layer MTL, and the concave portion CONC illustrated in FIG. 31, and thus are not described repeatedly.

Referring to FIG. 32, the etch stop layer ESL may be disposed between the plurality of insulation films positioned under the metal layer MTL. The etch stop layer ESL may be disposed to be seated in the concave portion CONC. For example, the etch stop layer ESL may be disposed to extend to be seated in the concave portion CONC while being partially disposed between the second gate insulation film GI2 and the second interlayer insulation film ILD2 positioned under the metal layer MTL. The portion extended to allow the etch stop layer ESL to be seated in the concave portion CONC may have a relatively small thickness. In other words, the upper portion of the etch stop layer ESL seated on the concave portion CONC may be partially etched in the etching process to form an etch stop residual film ESRL. In this case, the etch stop residual film ESRL may be a Ti residual film of the Mo/Ti double layer or a Mo residual film of the Mo single layer. An organic insulation film may be disposed on a portion of the etch stop residual film ESRL disposed in the concave portion CONC. For example, the etch stop residual film ESRL may be exposed by the undercut area UCA of the organic insulation film, and the light emitting layer EL may be positioned on the exposed etch stop residual film ESRL.

Referring to FIG. 32, the third portion TPEL of the light emitting layer EL may be disposed at a position adjacent to the undercut area UCA. For example, the third portion TPEL of the light emitting layer EL may be positioned under the second portion SPEL of the light emitting layer EL. For example, the third portion TPEL of the light emitting layer EL may be seated on the concave portion CONC. The third portion TPEL of the light emitting layer EL may be disposed on the etch stop residual film ESRL disposed in the concave portion CONC. The third portion TPEL of the light emitting layer EL may be spaced apart from the second portion SPEL of the light emitting layer EL, and the third portion TPEL of the light emitting layer EL and the second portion SPEL of the light emitting layer EL may overlap each other on a plane.

The third portion TPCE of the cathode electrode CE may be disposed at a position adjacent to the undercut area UCA. For example, the third portion TPCE of the cathode electrode CE may be positioned on the third portion TPEL of the light emitting layer EL. While the third portion TPCE of the cathode electrode CE is spaced apart from the second portion SPCE of the cathode electrode CE, the third portion TPCE of the cathode electrode CE and the second portion SPCE of the cathode electrode CE may overlap each other on a plane.

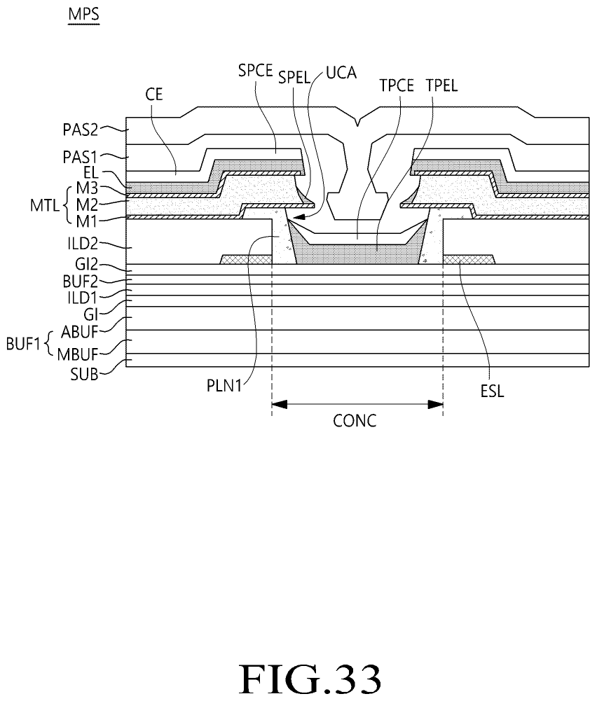

FIG. 33 is an exemplary cross-sectional view of the moisture-preventing structure MPS illustrated in FIG. 30. Hereinafter, in describing the embodiments illustrated in FIG. 33, what is not particularly described otherwise may be the same as those described above with reference to FIGS. 1 to 32.

Referring to FIG. 33, the moisture-preventing structure MPS may include a plurality of insulation films, an undercut area UCA, a metal layer MTL, a concave portion CONC, and an etch stop layer ESL. The plurality of insulation films, the undercut area UCA, the metal layer MTL, and the concave portion CONC illustrated in FIG. 33 may have the same configuration as the plurality of insulation films, the undercut area UCA, the metal layer MTL, and the concave portion CONC illustrated in FIG. 31, and thus are not described repeatedly.

Referring to FIG. 33, the etch stop layer ESL may be disposed between the plurality of insulation films positioned under the metal layer MTL. For example, the etch stop layer ESL may be partially disposed between the second gate insulation film GI2 and the second interlayer insulation film ILD2 positioned under the metal layer MTL. Unlike the etch stop layer ESL illustrated in FIG. 31 or FIG. 32, the etch stop layer ESL may be disposed between the insulation films without being seated on the concave portion CONC. For example, in the etching process, the etch stop layer ESL may be over-etched to be partially etched and removed. In other words, the etch stop layer ESL may not be disposed in the concave portion CONC. The organic insulation film may be disposed on a portion of the second gate insulation film GI2 disposed in the concave portion CONC. For example, the second gate insulation film GI2 may be exposed by the undercut area UCA of the organic insulation film, and the light emitting layer EL may be positioned on the exposed second gate insulation film GI2.

Referring to FIG. 33, the third portion TPEL of the light emitting layer EL may be disposed at a position adjacent to the undercut area UCA. For example, the third portion TPEL of the light emitting layer EL may be positioned under the second portion SPEL of the light emitting layer EL. For example, the third portion TPEL of the light emitting layer EL may be seated on the concave portion CONC. The third portion TPEL of the light emitting layer EL may be disposed on the second buffer layer BUF2 disposed in the concave portion CONC. The third portion TPEL of the light emitting layer EL may be spaced apart from the second portion SPEL of the light emitting layer EL, and the third portion TPEL of the light emitting layer EL and the second portion SPEL of the light emitting layer EL may overlap each other on a plane.

The third portion TPCE of the cathode electrode CE may be disposed at a position adjacent to the undercut area UCA. For example, the third portion TPCE of the cathode electrode CE may be positioned on the third portion TPEL of the light emitting layer EL. While the third portion TPCE of the cathode electrode CE is spaced apart from the second portion SPCE of the cathode electrode CE, the third portion TPCE of the cathode electrode CE and the second portion SPCE of the cathode electrode CE may overlap each other on a plane.

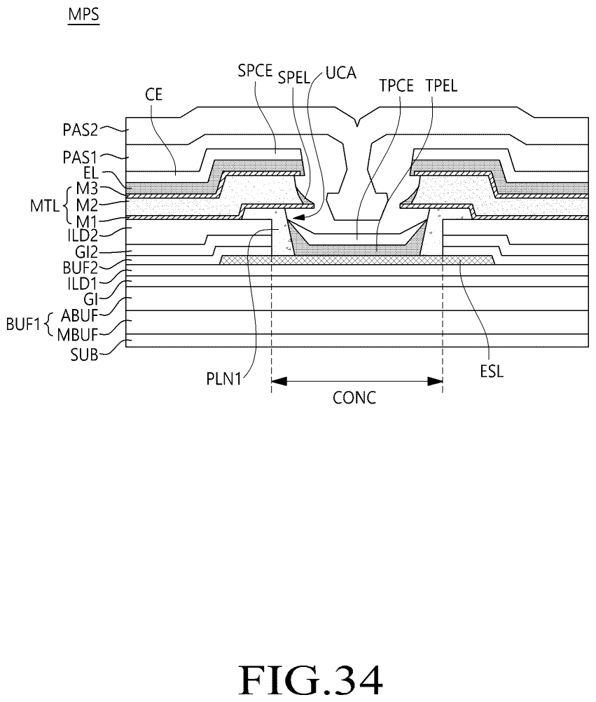

FIG. 34 is an exemplary cross-sectional view of the moisture-preventing structure MPS illustrated in FIG. 30. Hereinafter, in describing the embodiments illustrated in FIG. 34, what is not particularly described otherwise may be the same as those described above with reference to FIGS. 1 to 33.

Referring to FIG. 34, the moisture-preventing structure MPS may include a plurality of insulation films, an undercut area UCA, a metal layer MTL, a concave portion CONC, and an etch stop layer ESL. The plurality of insulation films, the undercut area UCA, and the metal layer MTL illustrated in FIG. 34 may have the same configuration as the plurality of insulation films, the undercut area UCA, and the metal layer MTL illustrated in FIG. 31, and thus are not described repeatedly.

The moisture-preventing structure MPS may include a concave portion CONC of at least one of the plurality of insulation films. For example, the concave portion CONC may be positioned in an inorganic insulation film disposed on the substrate SUB and positioned under a plurality of light emitting elements. That the concave portion CONC is positioned in the inorganic insulation film may mean that one or more of the inorganic insulation films are etched to form the concave portion CONC. The inorganic insulation film may be an inorganic insulation film positioned on the substrate SUB and under the light emitting element. For example, the inorganic insulation film may be one or more of the first buffer layer BUF1 and the second interlayer insulation film ILD2 and the insulation films positioned between the two layers. FIG. 34 illustrates an embodiment in which the second interlayer insulation film ILD2, the second gate insulation film GI2, and the second buffer layer BUF2 include a concave portion CONC, but embodiments of the disclosure are not limited to these embodiments.

The moisture-preventing structure MPS may include an etch stop layer ESL positioned in or under the undercut area UCA. The etch stop layer ESL may be an auxiliary metal layer AML. Referring to FIG. 34, the etch stop layer ESL may be disposed between the plurality of insulation films positioned under the metal layer MTL. The etch stop layer ESL may be disposed to be seated in the concave portion CONC. For example, the etch stop layer ESL may be disposed to extend to be seated in the concave portion CONC while being partially disposed between the first interlayer insulation film ILD1 and the second buffer layer BUF2 positioned under the metal layer MTL. An organic insulation film may be disposed on a portion of the etch stop layer ESL disposed in the concave portion CONC. For example, the etch stop layer ESL may be exposed by the undercut area UCA of the organic insulation film, and the light emitting layer EL may be positioned on the exposed etch stop layer ESL.

The etch stop layer ESL may include a metallic material. For example, the etch stop layer ESL may include a single layer or multiple layers of any one of molybdenum (Mo), copper (Cu), titanium (Ti), aluminum (Al), chromium (Cr), gold (Au), nickel (Ni), neodymium (Nd), and tungsten (W), or an alloy thereof, but is not limited thereto. The etch stop layer ESL may include the same material as the metal pattern TM. For example, the etch stop layer ESL may be formed of a Mo/Ti double layer or a Mo single layer.

The etch stop layer ESL may prevent some insulation films, disposed thereunder, from being over-etched in the etching process of forming the concave portion CONC by patterning the plurality of insulation films or patterning the metallic metal such as the anode electrode AE or the metal layer MTL in the process of forming the moisture-preventing structure MPS. For example, in the embodiments illustrated in FIG. 34, the undercut area UCA may be formed in a structure in which a portion of the second interlayer insulation film ILD2, the second gate insulation film GI2, and the second buffer layer BUF2 disposed on the etch stop layer ESL is etched, but the etch stop layer ESL is not etched.

Referring to FIG. 34, the light emitting layer EL may have several portions. The light emitting layer EL may include a first portion FPEL, a second portion SPEL, and a third portion TPEL. The first portion FPEL of the light emitting layer EL may be positioned to overlap the emission area EA on a plane. As shown, the first portion FPEL, the second portion SPEL, and the third portion TPEL of the light emitting layer EL may be spaced apart from each other. The first portion FPEL, the second portion SPEL, and the third portion TPEL of the light emitting layer EL may be separated from each other.

Here, the second portion SPEL of the light emitting layer EL may be positioned on the first layer M1 of the metal layer MTL. The first layer M1 of the metal layer MTL may further extend in a first direction (e.g., a lateral direction) than some of the insulation films, such as the second interlayer insulation film ILD2, the second gate insulation film GI2, and the second buffer layer BUF2 to form the undercut area UCA. For example, the first layer M1 of the metal layer MTL may further extend than some of the insulation films, such as the second interlayer insulation film ILD2, the second gate insulation film GI2, and the second buffer layer BUF2 to form the undercut area UCA.

The third portion TPEL of the light emitting layer EL may be disposed at a position adjacent to the undercut area UCA. For example, the third portion TPEL of the light emitting layer EL may be positioned under the second portion SPEL of the light emitting layer EL. For example, the third portion TPEL of the light emitting layer EL may be seated on the concave portion CONC. The third portion TPEL of the light emitting layer EL may be disposed on the etch stop layer ESL disposed in the concave portion CONC. The third portion TPEL of the light emitting layer EL may be spaced apart from the second portion SPEL of the light emitting layer EL, and the third portion TPEL of the light emitting layer EL and the second portion SPEL of the light emitting layer EL may overlap each other on a plane.

Further, the cathode electrode CE may have several portions. The cathode electrode CE may include a first portion FTCE, a second portion SPCE, and a third portion TPCE. The cathode electrode CE may be positioned so that the first portion FPCE overlaps the emission area EA on a plane. As shown, the first portion FFCE, the second portion SPCE, and the third portion TPCE of the cathode electrode CE may be spaced apart from each other. It may also be said that the first portion FPCE, the second portion SPCE, and the third portion TPCE of the cathode electrode CE are separated from each other.

Here, the second portion SPCE of the cathode electrode CE may be positioned on the first layer M1 of the metal layer MTL. For example, the second portion SPCE of the cathode electrode CE may be positioned on a portion of the light emitting layer EL positioned to be spaced apart from the second portion SPEL of the light emitting layer EL. The second portion SPCE of the cathode electrode CE may also be positioned on the third layer M3 of the metal layer MTL. As illustrated in FIG. 34, the second portion SPCE of the cathode electrode CE may not be in direct contact with the second portion SPEL of the light emitting layer EL.

The third portion TPCE of the cathode electrode CE may be disposed at a position adjacent to the undercut area UCA. For example, the third portion TPCE of the cathode electrode CE may be positioned on the third portion TPEL of the light emitting layer EL. While the third portion TPCE of the cathode electrode CE is spaced apart from the second portion SPCE of the cathode electrode CE, the third portion TPCE of the cathode electrode CE and the second portion SPCE of the cathode electrode CE may overlap each other on a plane.

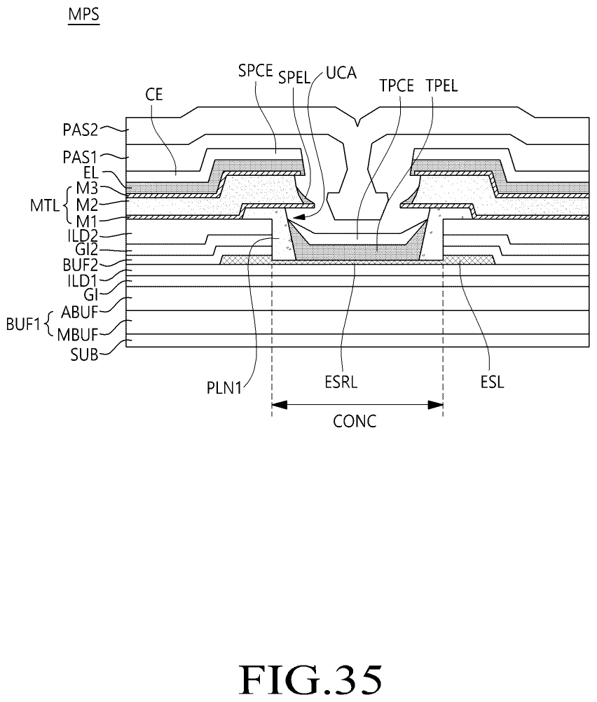

FIG. 35 is an exemplary cross-sectional view of the moisture-preventing structure MPS illustrated in FIG. 30. Hereinafter, in describing the embodiments illustrated in FIG. 35, what is not particularly described otherwise may be the same as those described above with reference to FIGS. 1 to 34.

Referring to FIG. 35, the moisture-preventing structure MPS may include a plurality of insulation films, an undercut area UCA, a metal layer MTL, a concave portion CONC, and an etch stop layer ESL. The plurality of insulation films, the undercut area UCA, the metal layer MTL, and the concave portion CONC illustrated in FIG. 35 may have the same configuration as the plurality of insulation films, the undercut area UCA, the metal layer MTL, and the concave portion CONC illustrated in FIG. 34, and thus are not described repeatedly.

Referring to FIG. 35, the etch stop layer ESL may be disposed between the plurality of insulation films positioned under the metal layer MTL. The etch stop layer ESL may be disposed to be seated in the concave portion CONC. For example, the etch stop layer ESL may be disposed to extend to be seated in the concave portion CONC while being partially disposed between the first interlayer insulation film ILD1 and the second buffer layer BUF2 positioned under the metal layer MTL. The portion extended to allow the etch stop layer ESL to be seated in the concave portion CONC may have a relatively small thickness. In other words, the upper portion of the etch stop layer ESL seated on the concave portion CONC may be partially etched in the etching process to form an etch stop residual film ESRL. In this case, the etch stop residual film ESRL may be a Ti residual film of the Mo/Ti double layer or a Mo residual film of the Mo single layer. An organic insulation film may be disposed on a portion of the etch stop residual film ESRL disposed in the concave portion CONC. For example, the etch stop residual film ESRL may be exposed by the undercut area UCA of the organic insulation film, and the light emitting layer EL may be positioned on the exposed etch stop residual film ESRL.

Referring to FIG. 35, the third portion TPEL of the light emitting layer EL may be disposed at a position adjacent to the undercut area UCA. For example, the third portion TPEL of the light emitting layer EL may be positioned under the second portion SPEL of the light emitting layer EL. For example, the third portion TPEL of the light emitting layer EL may be seated on the concave portion CONC. The third portion TPEL of the light emitting layer EL may be disposed on the etch stop residual film ESRL disposed in the concave portion CONC. The third portion TPEL of the light emitting layer EL may be spaced apart from the second portion SPEL of the light emitting layer EL, and the third portion TPEL of the light emitting layer EL and the second portion SPEL of the light emitting layer EL may overlap each other on a plane.

The third portion TPCE of the cathode electrode CE may be disposed at a position adjacent to the undercut area UCA. For example, the third portion TPCE of the cathode electrode CE may be positioned on the third portion TPEL of the light emitting layer EL. While the third portion TPCE of the cathode electrode CE is spaced apart from the second portion SPCE of the cathode electrode CE, the third portion TPCE of the cathode electrode CE and the second portion SPCE of the cathode electrode CE may overlap each other on a plane.

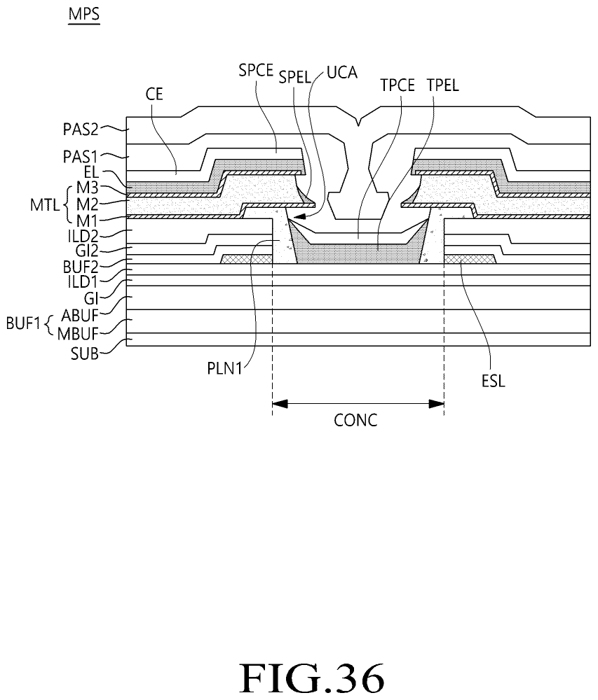

FIG. 36 is an exemplary cross-sectional view of the moisture-preventing structure MPS illustrated in FIG. 30. Hereinafter, in describing the embodiments illustrated in FIG. 36, what is not particularly described otherwise may be the same as those described above with reference to FIGS. 1 to 35.

Referring to FIG. 36, the moisture-preventing structure MPS may include a plurality of insulation films, an undercut area UCA, a metal layer MTL, a concave portion CONC, and an etch stop layer ESL. The plurality of insulation films, the undercut area UCA, the metal layer MTL, and the concave portion CONC illustrated in FIG. 36 may have the same configuration as the plurality of insulation films, the undercut area UCA, the metal layer MTL, and the concave portion CONC illustrated in FIG. 34, and thus are not described repeatedly.

Referring to FIG. 36, the etch stop layer ESL may be disposed between the plurality of insulation films positioned under the metal layer MTL. For example, the etch stop layer ESL may be partially disposed between the first interlayer insulation film ILD1 and the second buffer layer BUF2 positioned under the metal layer MTL. Unlike the etch stop layer ESL illustrated in FIG. 34 or FIG. 35, the etch stop layer ESL may be disposed between the insulation films without being seated on the concave portion CONC. For example, in the etching process, the etch stop layer ESL may be over-etched to be partially etched and removed. In other words, the etch stop layer ESL may not be disposed in the concave portion CONC. The organic insulation film may be disposed on a portion of the first interlayer insulation film ILD1 disposed in the concave portion CONS. For example, the first interlayer insulation film ILD1 may be exposed by the undercut area UCA of the organic insulation film, and the light emitting layer EL may be positioned on the exposed first interlayer insulation film ILD1.

Referring to FIG. 36, the third portion TPEL of the light emitting layer EL may be disposed at a position adjacent to the undercut area UCA. For example, the third portion TPEL of the light emitting layer EL may be positioned under the second portion SPEL of the light emitting layer EL. For example, the third portion TPEL of the light emitting layer EL may be seated on the concave portion CONC. The third portion TPEL of the light emitting layer EL may be disposed on the second buffer layer BUF2 disposed in the concave portion CONC. The third portion TPEL of the light emitting layer EL may be spaced apart from the second portion SPEL of the light emitting layer EL, and the third portion TPEL of the light emitting layer EL and the second portion SPEL of the light emitting layer EL may overlap each other on a plane.

The third portion TPCE of the cathode electrode CE may be disposed at a position adjacent to the undercut area UCA. For example, the third portion TPCE of the cathode electrode CE may be positioned on the third portion TPEL of the light emitting layer EL. While the third portion TPCE of the cathode electrode CE is spaced apart from the second portion SPCE of the cathode electrode CE, the third portion TPCE of the cathode electrode CE and the second portion SPCE of the cathode electrode CE may overlap each other on a plane.

As the display device includes the moisture-preventing structure MPS, the light emitting layer EL may be disconnected two or more times by the moisture-preventing structure MPS. Therefore, it is possible to effectively prevent defects that may occur when external moisture penetrates into the display area through the camera hole.

Embodiments of the disclosure described above are briefly described below.

Embodiments of the disclosure may provide a display device comprising a substrate including a display area where a plurality of light emitting elements including a light emitting layer are positioned, a camera hole positioned in the display area, and a first non-display area positioned between the display area and the camera hole, a dam positioned in the first non-display area, a plurality of insulation films disposed on the substrate, and positioned under the plurality of light emitting elements, and a moisture-preventing structure disposed in the first non-display area, and including an undercut area of at least one of the plurality of insulation films.

In the display device according to embodiments of the disclosure, the light emitting layer may be positioned to extend from the display area to a boundary of the camera hole, and the light emitting layer may be disconnected in the undercut area.

In the display device according to embodiments of the disclosure, the display device may further comprise a disconnected portion positioned in the first non-display area.

In the display device according to embodiments of the disclosure, the disconnected portion may include an inner disconnected portion positioned between the display area and the dam, and an outer disconnected portion positioned between the dam and the camera hole.

In the display device according to embodiments of the disclosure, the moisture-preventing structure may include an inner moisture-preventing structure positioned between the display area and the dam.

In the display device according to embodiments of the disclosure, the moisture-preventing structure may include an outer moisture-preventing structure positioned between the dam and the camera hole.

In the display device according to embodiments of the disclosure, the light emitting layer may be positioned to extend from the display area to a boundary of the camera hole. The moisture-preventing structure may include a metal layer positioned on the undercut area. The light emitting layer is disconnected at a side surface of the metal layer.

In the display device according to embodiments of the disclosure, the metal layer may include a first layer, a second layer positioned on the first layer, and a third layer positioned on the second layer. The second layer may have a shape further recessed than the first layer and the third layer.

In the display device according to embodiments of the disclosure, the metal layer may include a first layer, a second layer positioned on the first layer, and a third layer positioned on the second layer. The first layer may have a shape further protruding than the third layer.

In the display device according to embodiments of the disclosure, the metal layer may include a first layer, a second layer positioned on the first layer, and a third layer positioned on the second layer. The first layer and the third layer may be of the same material, and the second layer may be of a material different from that of the first layer and the third layer.

In the display device according to embodiments of the disclosure, the moisture-preventing structure may include a step portion positioned in the undercut area and positioned under the metal layer.

In the display device according to embodiments of the disclosure, the undercut area may be positioned on an inorganic insulation film disposed on the substrate and positioned under the plurality of light emitting elements.

In the display device according to embodiments of the disclosure, the undercut area may be positioned on an organic insulation film disposed on the substrate and positioned under the plurality of light emitting elements.

In the display device according to embodiments of the disclosure, the moisture-preventing structure may include a concave portion of at least one of the plurality of insulation films. The undercut area may be positioned in the concave portion.

In the display device according to embodiments of the disclosure, the moisture-preventing structure may include a concave portion of at least one of the plurality of insulation films. The undercut area may be positioned on an organic insulation film disposed on the substrate and positioned under the plurality of light emitting elements.

In the display device according to embodiments of the disclosure, the moisture-preventing structure may include a concave portion of at least one of the plurality of insulation films. The concave portion may be positioned on an inorganic insulation film disposed on the substrate and positioned under the plurality of light emitting elements.

In a display device according to embodiments of the disclosure, the moisture-proof structure may include a metal layer positioned on an undercut area, and may further include an auxiliary metal layer disposed below the metal layer and spaced apart from the metal layer.

In the display device according to embodiments of the disclosure, the display device may further comprise an auxiliary metal layer. The moisture-preventing structure may include a concave portion of at least one of the plurality of insulation films. The auxiliary metal layer may be disposed below the concave portion.

A display device according to some embodiments includes:
a display area and a non-display area adjacent to the display area;
a camera hole adjacent to the non-display area, the camera hole spaced apart from the display area from a plan view;
a light emitting element disposed to overlap with the display area from a plan view;
a dam structure between the camera hole and the display area from a plan view or in the non-display area; and
a moisture-preventing structure adjacent to the dam structure, the moisture-preventing structure including a plurality of metal layers.

In some embodiments, the moisture-preventing structure includes an undercut area adjacent to the plurality of metal layers.

In some embodiments, the display device further includes a plurality of insulation films below the plurality of metal layers.

In some embodiments, the plurality of metal layers includes a first metal layer and a second metal layer on the first metal layer.

In some embodiments, a plurality of insulation films includes a first insulation film.

In some embodiments, the first metal layer extends in a first direction further than a portion of the first insulation film to form the undercut area.

In some embodiments, the light emitting element includes a light emitting layer and a first electrode on the light emitting layer.

In some embodiments, the light emitting layer includes a first portion, a second portion, and a third portion. Here, the first portion, the second portion, and the third portion are spaced apart from each other.

In some embodiments, the first portion of the light emitting layer overlaps with the display area from a plan view, and the second portion of the light emitting layer is on the first metal layer.

In some embodiments, the third portion of the light emitting layer is disposed below the undercut area.

In some embodiments, the third portion of light emitting layer and the second portion of the light emitting layer overlap with each other from a plan view, and the first portion of the light emitting layer does not overlap with the second portion and the third portion of the light emitting layer from a plan view.

In some embodiments, the light emitting element includes a light emitting layer and a first electrode on the light emitting layer. Here, the first electrode includes a first portion, a second portion, and a third portion.

In some embodiments, the first portion, the second portion, and the third portion of the first electrode are spaced apart from each other. Here, the first portion of the first electrode overlaps with the display area from a plan view, and the second portion of the first electrode is on the first metal layer.

In some embodiments, the light emitting element includes a light emitting layer and a first electrode on the light emitting layer.

In some embodiments, the first electrode includes a first portion, a second portion, and a third portion, and the first portion, the second portion, and the third portion of the first electrode are spaced apart from each other.

In some embodiments, the first portion of the first electrode overlaps with the display area from a plan view, and the third portion of the first electrode is disposed below the undercut area.

In some embodiments, the third portion of light emitting layer and the second portion of the light emitting layer overlap with each other from a plan view, and the first portion of the light emitting layer does not overlap with the second portion and the third portion of the light emitting layer from a plan view.

In some embodiments, the moisture-preventing structure is disposed between the dam structure and the camera hole from a plan view.

In some embodiments, the dam structure is disposed between the moisture-preventing structure and the camera hole from a plan view.

In some embodiments, the moisture-preventing structure includes a first moisture-preventing structure and a second moisture-preventing structure. The first moisture-preventing structure is disposed between the dam structure and the camera hole from a plan view, and the dam structure is disposed between the first moisture-preventing structure and the second moisture-preventing structure from a plan view.

In the display device according to embodiments of the disclosure, the display device may further comprise an auxiliary metal layer disposed below the plurality of metal layers of the first moisture-preventing structure.

In the display device according to embodiments of the disclosure, the display device may further comprise a second moisture-preventing structure adjacent to the first moisture-preventing structure and an auxiliary metal layer disposed between the second moisture-preventing structure and the first moisture-preventing structure.

In the display device according to embodiments of the disclosure, the auxiliary metal layer may overlap both the second moisture-preventing structure and the first moisture-preventing structure from a plan view.

In the display device according to embodiments of the disclosure, the display device may further comprise a second moisture-preventing structure adjacent to and spaced apart from the first moisture-preventing structure from a plan view and a first auxiliary metal layer and a second auxiliary metal layer spaced apart from the first auxiliary metal layer. The first auxiliary metal layer may overlap with the first moisture-preventing structure and the second auxiliary metal layer may overlap with the second moisture-preventing structure from a plan view.

In the display device according to embodiments of the disclosure, the display device may further comprise at least one insulation layer between the plurality of metal layers and the auxiliary metal layer. The auxiliary metal layer may contact and overlap the at least one insulation layer from a plan view.

In the display device according to embodiments of the disclosure, the display device may further comprise a thin film transistor electrically connected the light emitting element. The thin film transistor may include a gate electrode. The auxiliary metal layer and the gate electrode of the thin film transistor may be made of a same material.

In the display device according to embodiments of the disclosure, the display device may further include a thin film transistor electrically connected to the light emitting element and including an active layer and a metal pattern disposed under the active layer to be spaced apart therefrom. The auxiliary metal layer and the metal pattern may comprise the same material.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate including a display area where a plurality of light emitting elements including a light emitting layer are positioned, a camera hole positioned in the display area, and a first non-display area positioned between the display area and the camera hole;
a dam positioned in the first non-display area;
a plurality of insulation films disposed on the substrate, and positioned under the plurality of light emitting elements; and
a moisture-preventing structure disposed in the first non-display area, the moisture-preventing structure including an undercut area of at least one of the plurality of insulation films.

2. The display device of claim 1, wherein the light emitting layer is positioned to extend from the display area to a boundary of the camera hole, and
wherein the light emitting layer is disconnected in the undercut area.

3. The display device of claim 1, further comprising a disconnected portion positioned in the first non-display area, wherein the disconnected portion includes:
an inner disconnected portion positioned between the display area and the dam; and
an outer disconnected portion positioned between the dam and the camera hole.

4. The display device of claim 1, wherein the moisture-preventing structure includes an inner moisture-preventing structure positioned between the display area and the dam.

5. The display device of claim 1, wherein the moisture-preventing structure includes an outer moisture-preventing structure positioned between the dam and the camera hole.

6. The display device of claim 1, wherein the light emitting layer is positioned to extend from the display area to a boundary of the camera hole,
wherein the moisture-preventing structure includes a metal layer positioned on the undercut area, and
wherein the light emitting layer is disconnected at a side surface of the metal layer.

7. The display device of claim 6, wherein the metal layer includes a first layer, a second layer positioned on the first layer, and a third layer positioned on the second layer,
wherein either the second layer has a shape further recessed than the first layer and the third layer, or the first layer has a shape further protruding than the third layer.

8. The display device of claim 6, wherein the metal layer includes a first layer, a second layer positioned on the first layer, and a third layer positioned on the second layer, and
wherein the first layer and the third layer are of the same material, and the second layer is of a material different from that of the first layer and the third layer.

9. The display device of claim 6, wherein the moisture-preventing structure includes a step portion positioned in the undercut area and positioned under the metal layer.

10. The display device of claim 1, wherein the undercut area is positioned on an insulation film disposed on the substrate and positioned under the plurality of light emitting elements, and
wherein the insulation film is either an inorganic insulation film or an organic insulation film.

11. The display device of claim 1, wherein the moisture-preventing structure includes a concave portion of at least one of the plurality of insulation films, and
wherein the undercut area is positioned in the concave portion.

12. The display device of claim 1, wherein the moisture-preventing structure includes a concave portion of at least one of the plurality of insulation films, and
wherein the undercut area is positioned on an insulation film disposed on the substrate and positioned under the plurality of light emitting elements, and the insulation film is either an inorganic insulation film or an organic insulation film.

13. The display device of claim 1, further comprising an auxiliary metal layer,
wherein the moisture-preventing structure includes a concave portion of at least one of the plurality of insulation films, and
wherein the auxiliary metal layer is disposed below the concave portion.

14. A display device, comprising:
a display area and a non-display area adjacent to the display area;
a camera hole adjacent to the non-display area, the camera hole spaced apart from the display area from a plan view;
a light emitting element disposed to overlap with the display area from a plan view;
a dam structure in the non-display area and
a first moisture-preventing structure adjacent to the dam structure, the first moisture-preventing structure including a plurality of metal layers.

15. The display device of claim 14, further comprising an auxiliary metal layer disposed below the plurality of metal layers of the first moisture-preventing structure.

16. The display device of claim 14, further comprising:
a second moisture-preventing structure adjacent to the first moisture-preventing structure; and
an auxiliary metal layer disposed between the second moisture-preventing structure and the first moisture-preventing structure.

17. The display device of claim 16, wherein the auxiliary metal layer overlaps both the second moisture-preventing structure and the first moisture-preventing structure from a plan view.

18. The display device of claim 14, further comprising:
a second moisture-preventing structure adjacent to and spaced apart from the first moisture-preventing structure from a plan view; and
a first auxiliary metal layer and a second auxiliary metal layer spaced apart from the first auxiliary metal layer,
wherein the first auxiliary metal layer overlaps with the first moisture-preventing structure and the second auxiliary metal layer overlaps with the second moisture-preventing structure from a plan view.

19. The display device of claim 15, further comprising at least one insulation layer between the plurality of metal layers and the auxiliary metal layer, and
wherein the auxiliary metal layer contacts and overlaps the at least one insulation layer from a plan view.

20. The display device of claim 19, further comprising a thin film transistor electrically connected the light emitting element, the thin film transistor including a gate electrode,
wherein the auxiliary metal layer and the gate electrode of the thin film transistor are made of a same material.
